(19) United States
(12) Patent Application Publication
(10) Pub. No.: US 2025/0198047 A1
(43) Pub. Date: Jun. 19, 2025

(54) CRYSTAL GROWTH METHODS AND DEVICES

(71) Applicant: MEISHAN BOYA ADVANCED MATERIALS CO., LTD., Meishan (CN)

(72) Inventors: Yu WANG, Meishan (CN); Weiming GUAN, Meishan (CN)

(73) Assignee: MEISHAN BOYA ADVANCED MATERIALS CO., LTD., Meishan (CN)

(21) Appl. No.: 19/068,009

(22) Filed: Mar. 3, 2025

Related U.S. Application Data
(63) Continuation of application No. PCT/CN2022/118260, filed on Sep. 9, 2022.

(51) Int. Cl. C30B 23/00; C30B 23/02; C30B 23/06; C30B 29/36; C30B 35/00

(52) U.S. Cl. CPC C30B 23/005; C30B 23/025; C30B 23/063; C30B 23/066; C30B 29/36; C30B 35/007

(57) ABSTRACT

Embodiments of the present disclosure provide crystal growth methods and devices. The crystal growth methods include placing a feedstock in a material zone of a growth chamber and placing a seed crystal in a growth zone of the growth chamber. The material zone and the growth zone are separated by a partition, and the partition includes at least one outlet. The crystal growth methods further include growing a crystal based on the seed crystal and the feedstock by a physical vapor transport (PVT) manner.

### CROSS-REFERENCE TO RELATED APPLICATIONS

This application is a continuation of International Patent Application No. PCT/CN2022/118260, filed on Sep. 9, 2022, the contents of which are hereby incorporated by reference.

### TECHNICAL FIELD

The present disclosure relates to the field of crystal growth, and in particular, to crystal growth methods and devices.

### BACKGROUND

Semiconductor crystals (such as silicon carbide single crystals) possess excellent physicochemical properties, making them an important material for manufacturing high-frequency and high-power devices. The Physical Vapor Transport (PVT) manner is a technique used to prepare semiconductor crystals. However, there are still many technical challenges in the process of producing silicon carbide crystals using the PVT method. For example, low purity of the feedstock components or an unsatisfactory seed crystal surface can affect the crystal quality; porosities tend to form easily during a process of bonding crystals, leading to planar hexagonal defects in the crystal growth process; during the crystal growth process, it is difficult to control temperature conditions or the sublimation of the feedstock, leading to defects such as dislocations, micro-tubes, and polymorphism in the crystal; and the utilization rate of silicon carbide powder is low.

Therefore, there is a need to provide crystal growth methods and devices to improve the quality and efficiency of crystal preparation.

### SUMMARY

One of the embodiments of the present disclosure provides a crystal growth method. The crystal growth method includes placing a feedstock in a material zone of a growth chamber and placing a seed crystal in a growth zone of the growth chamber. The material zone and the growth zone are separated by a partition, and the partition includes at least one outlet. The crystal growth method further includes growing a crystal based on the seed crystal and the feedstock by a physical vapor transport (PVT) manner.

One of the embodiments of the present disclosure provides a crystal growth device including a growth chamber and a heating assembly. The growth chamber includes a material zone and a growth zone. The material zone is configured to place a feedstock, the growth zone is configured to place a seed crystal. The material zone and the growth zone are separated by a partition, and the partition includes at least one outlet. The heating assembly is configured to heat the growth chamber for growing a crystal based on the seed crystal and the feedstock by a PVT manner.

One of the embodiments of the present disclosure provides a coating apparatus, comprising a coating chamber and a coating rack. The coating rack is provided with a plurality of trays, and the plurality of trays are configured to hold a seed crystal. The coating apparatus further comprises a driving assembly, and the driving assembly is connected to the coating rack and is configured to drive the coating rack to rotate. The coating apparatus further comprises a heating assembly configured to provide heat required for coating. The coating apparatus further comprises an air inlet configured to introduce coating gas into the coating chamber and an air outlet configured to discharge gas from the coating chamber, and an air evacuating assembly connected to the air outlet and configured to evacuate air from the coating chamber.

One of the embodiments of the present disclosure provides an apparatus for bonding a seed crystal, comprising a bonding chamber; a vacuum assembly configured to vacuum the bonding chamber; an upper transmission assembly connected to a top end of the bonding chamber; a lower transmission assembly connected to a bottom end of the bonding chamber; a heating assembly; and a pressing assembly configured to bond the seed crystal to a chamber lid in conjunction with the upper transmission assembly, the lower transmission assembly, and the heating assembly.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering denotes the same structure, where:

FIG. 1 is a schematic diagram of an exemplary crystal growth system according to some embodiments of the present disclosure;

FIG. 2 is a schematic diagram illustrating an exemplary computing device according to some embodiments of the present disclosure;

FIG. 3 is a flowchart illustrating a process of a crystal growth method according to some embodiments of the present disclosure;

FIG. 4 is a flowchart illustrating a process of preparing a feedstock according to some embodiments of the present disclosure;

FIG. 5 is a flowchart illustrating a process of performing pre-treatment on a feedstock and a seed crystal according to some embodiments of the present disclosure;

FIG. 6 is a flowchart illustrating a process of coating a seed crystal according to some embodiments of the present disclosure;

FIG. 7 is a schematic diagram illustrating evaporation of a back surface of a seed crystal according to some embodiments of the present disclosure;

FIG. 8 is a flowchart illustrating a process of coating a seed crystal according to some embodiments of the present disclosure;

FIG. 9 is a schematic diagram illustrating an exemplary structure of a coating apparatus according to some embodiments of the present disclosure;

FIG. 10 is a flowchart illustrating a process of bonding a seed crystal according to some embodiments of the present disclosure;

FIG. 11A is a schematic diagram illustrating an exemplary structure of an apparatus for bonding a seed crystal according to some embodiments of the present disclosure;

FIG. 11B is a schematic diagram illustrating a seed crystal after bonding according to some embodiments of the present disclosure;

FIG. 12A is a schematic diagram illustrating an exemplary structure of an apparatus for bonding a seed crystal according to some embodiments of the present disclosure;

FIG. 12B is a schematic diagram illustrating a seed crystal after bonding according to some embodiments of the present disclosure;

FIG. 13 is a flowchart illustrating a process of bonding a seed crystal according to some embodiments of the present disclosure;

FIG. 14A is a schematic diagram illustrating an exemplary rolling operation according to some embodiments of the present disclosure;

FIG. 14B is a schematic diagram illustrating an exemplary rolling operation according to some embodiments of the present disclosure;

FIG. 15 is a flowchart illustrating a process of a crystal growth method according to some embodiments of the present disclosure;

FIG. 16A is a schematic diagram illustrating an exemplary structure of a crystal growth device according to some embodiments of the present disclosure;

FIG. 16B is a schematic diagram illustrating an exemplary structure of a crystal growth device according to some embodiments of the present disclosure;

FIG. 16C is a schematic diagram illustrating an exemplary structure of a crystal growth device according to some embodiments of the present disclosure;

FIG. 17 is a schematic diagram illustrating an exemplary temperature distribution of a crystal growth device according to some embodiments of the present disclosure;

FIG. 18 is a schematic diagram illustrating exemplary arrangement of temperature measurement assemblies according to some embodiments of the present disclosure;

FIG. 19A is a schematic diagram illustrating an exemplary structure of a monitoring assembly according to some embodiments of the present disclosure;

FIG. 19B is a schematic diagram illustrating an exemplary structure of a monitoring assembly according to some embodiments of the present disclosure;

FIG. 20 is a flowchart illustrating a process of a crystal growth method according to some embodiments of the present disclosure;

FIG. 21 is a flowchart illustrating a process of a crystal growth method according to some embodiments of the present disclosure;

FIG. 22 is a flowchart illustrating a process of a crystal growth method according to some embodiments of the present disclosure;

FIG. 23 is a flowchart illustrating a process of recovering a residual of a feedstock according to some embodiments of the present disclosure; and

FIG. 24 is a flowchart illustrating a process of recovering a residual of a feedstock according to some embodiments of the present disclosure.

Reference numerals in figures: 100, crystal growth system; 101, processing device; 102, control device; 103, temperature measurement assembly; 103-1, temperature sensor; 103-2, thermal insulation layer; 103-3, cooling assembly; 104, monitoring assembly; 104-1, ultrasonic thickness gauge; 104-11, ultrasonic probe; 104-2, cooling device; 104-3, graphite rod; 105, pressure measurement assembly; 106, coating apparatus; 106-1, coating chamber; 106-11, tube; 106-12, baffle; 106-2, coating rack; 106-3, heating assembly; 106-4, air inlet; 106-5, air outlet; 106-7, insulation cotton; 106-8, insulation layer; 107, apparatus for bonding a seed crystal; 107-1, bonding chamber; 107-2, vacuum assembly; 107-3, upper transmission assembly; 107-4, lower transmission assembly; 107-5, heating assembly; 107-6, pressing assembly; 107-61, suction cup; 107-62, support table; 107-7, pressure sensing assembly; 107-8, support assembly; 107-9, bonding table; 107-10, pressure roller; 108, crystal growth device; 108-1, growth chamber; 108-11, growth zone; 108-111, chamber cover; 108-12, material zone; 108-2, partition; 108-21, outlet; 108-3, heating assembly; 108-31, first heating assembly; 108-32, second heating assembly; 108-33, third heating assembly; 108-4, insulation assembly; 109, storage device; 110, interaction assembly; 110-1, display apparatus; and 110-2, interaction apparatus.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system,” “device,” “unit,” and/or “module” as used herein are a way to distinguish between different components, elements, parts, sections, or assemblies at different levels. However, the words may be replaced by other expressions if other words accomplish the same purpose.

As shown in the present disclosure and the claims, unless the context clearly suggests an exception, the words “a,” “an,” “one,” and/or “the” do not refer specifically to the singular, but may also include the plural. Generally, the terms “including” and “comprising” suggest only the inclusion of clearly identified steps and elements that do not constitute an exclusive list, and the method or apparatus may also include other steps or elements.

Flowcharts are used in the present disclosure to illustrate operations performed by a system in accordance with embodiments of the present disclosure. It should be appreciated that the preceding or following operations are not necessarily performed in an exact sequence. Instead, steps can be processed in reverse order or simultaneously. Also, it is possible to add other operations to these processes or remove a step or steps from them.

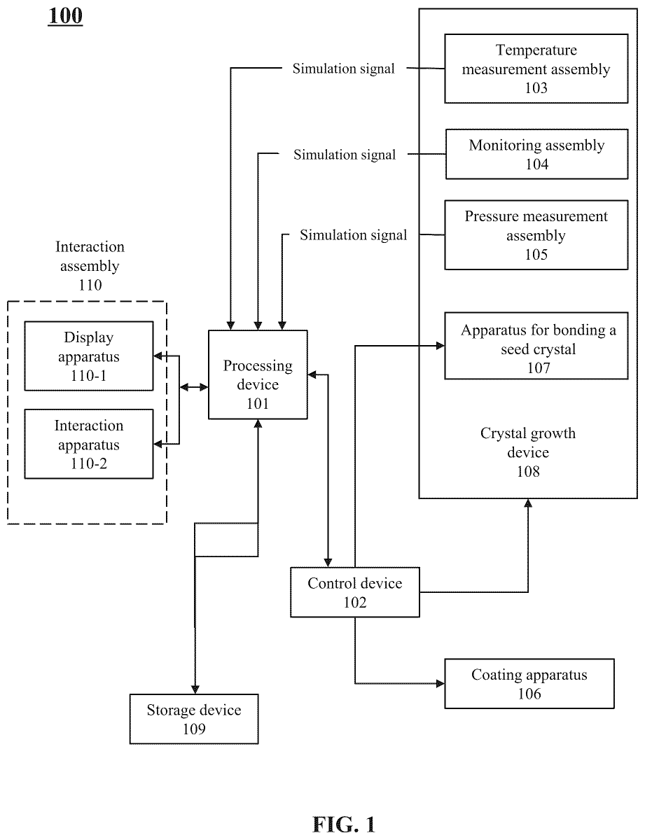

FIG. 1 is a schematic diagram illustrating an exemplary crystal growth system according to some embodiments of the present disclosure.

In some embodiments, a crystal growth system 100 prepares a variety of crystals (e.g., silicon carbide (SiC) crystals, aluminum nitride (AIN) crystals, zinc selenide (ZnSe) crystals, cadmium sulfide (CdS) crystals, zinc telluride (ZnTe), or the like) by a physical vapor transport (PVT) manner.

In some embodiments, as shown in FIG. 1, the crystal growth system 100 includes a processing device 101, a control device 102, a temperature measurement assembly 103, a monitoring assembly 104, a pressure measurement assembly 105, a coating apparatus 106, an apparatus 107 for bonding a seed crystal, a crystal growth device 108, a storage device 109, and an interaction assembly 110.

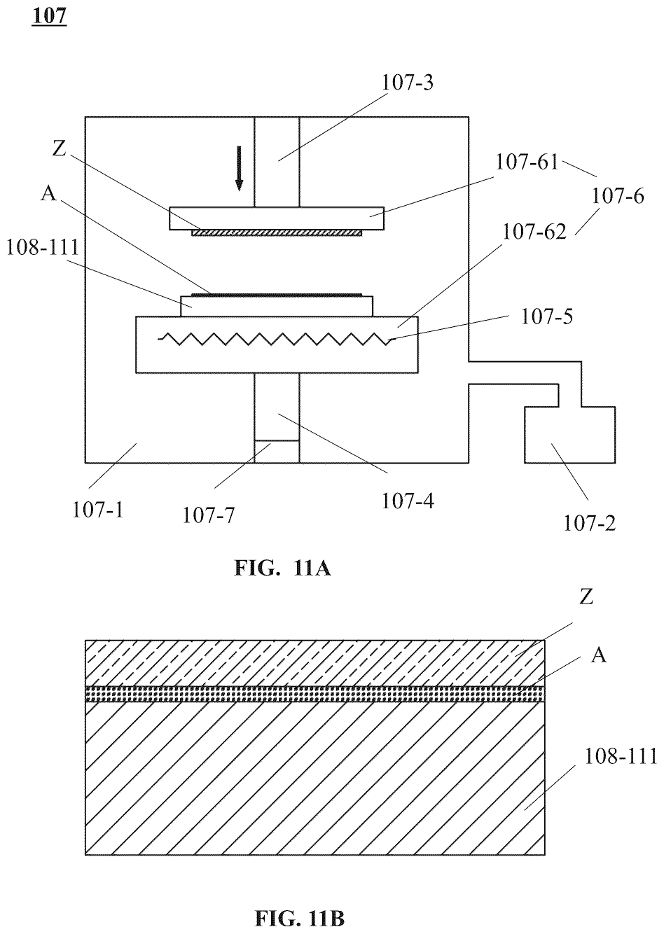

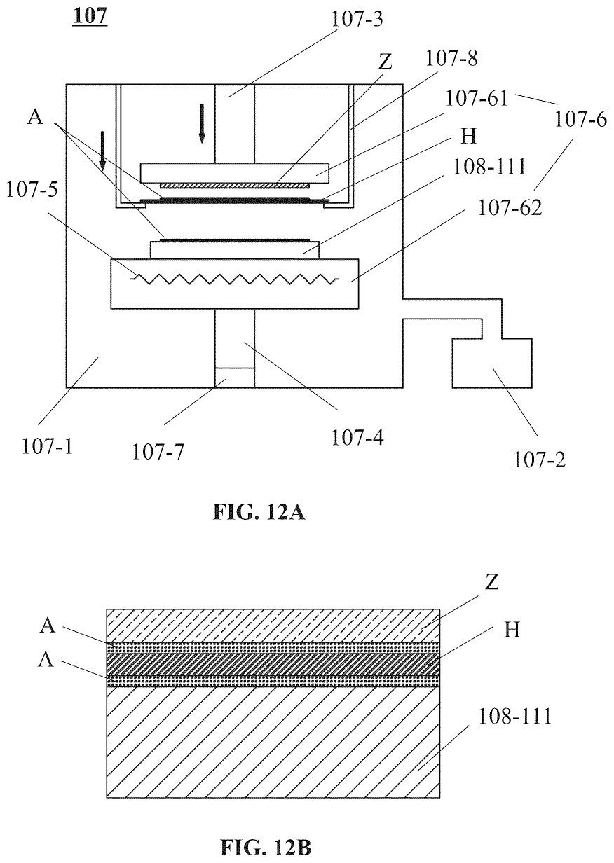

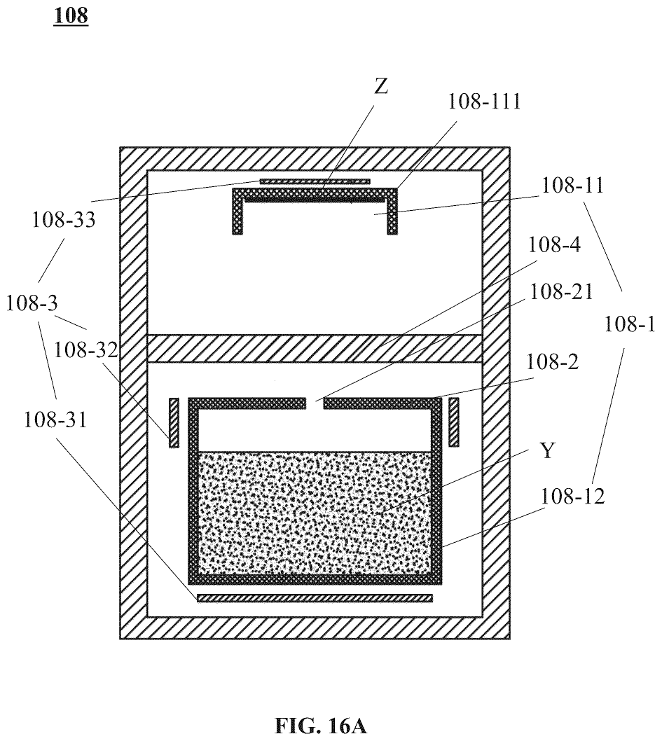

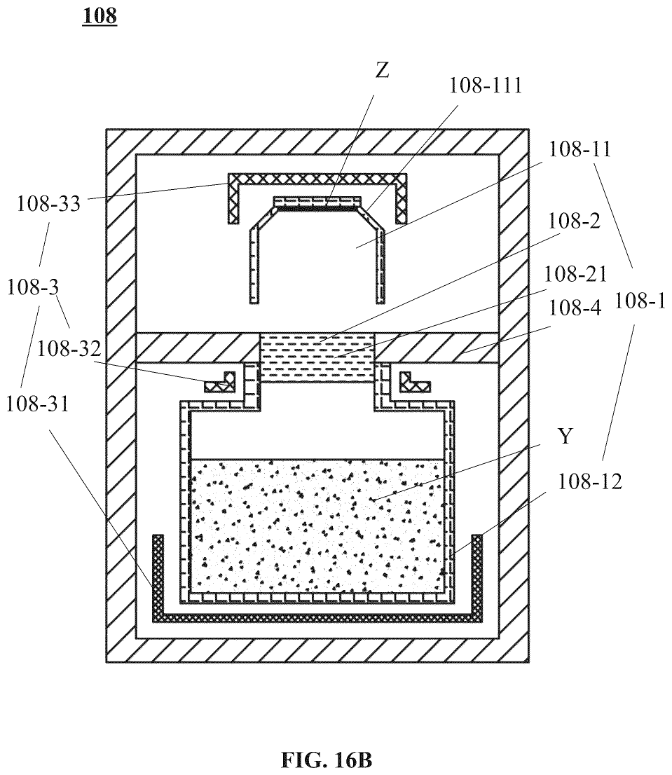

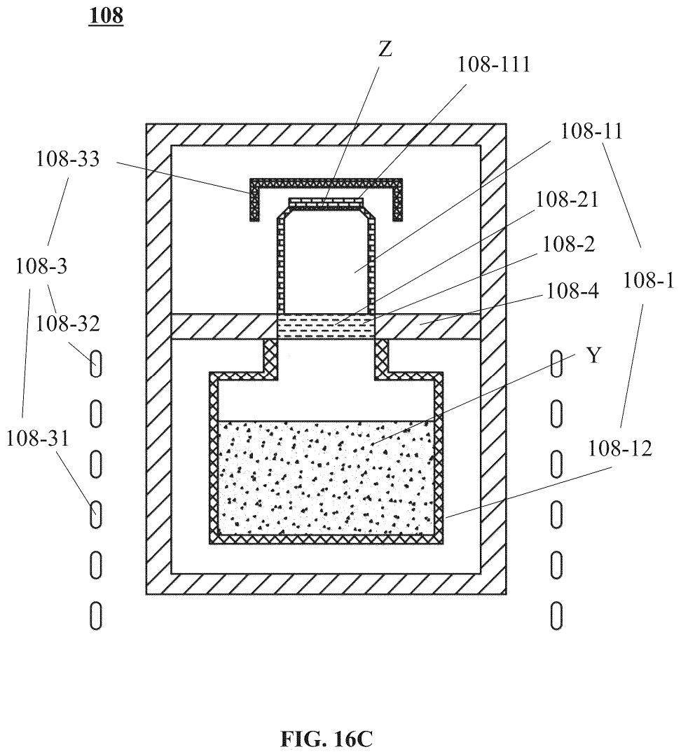

The processing device 101 may be configured to process a variety of data and/or information involved during growing a crystal. In some embodiments, the processing device 101 obtains temperature information within a growth chamber using the temperature measurement assembly 103 and adjusts a position, shape, distribution, area, etc., or any combination thereof, of at least one outlet (e.g., an outlet 108-21 as shown in FIG. 16A to FIG. 16C for transport of a vapor phase component) based on the temperature information. In some embodiments, the processing device 101 monitors a situation of growing the crystal using the monitoring assembly 104 and adjusts a heating parameter of a heating assembly (e.g., a heating assembly 108-3 as shown in FIG. 16A to FIG. 16C) and/or the position, shape, distribution, area, etc. of the at least one outlet, or any combination thereof, based on the situation of growing the crystal. In some embodiments, the processing device 101 monitors the situation of growing the crystal using the monitoring assembly 104 and adjusts the heating parameter of the heating assembly (e.g., the heating assembly 108-3 shown in FIG. 16A to FIG. 16C) and/or the position, shape, distribution, area, etc., of the at least one outlet, or any combination thereof, during a next process of growing a crystal based on a current situation of growing the crystal. In some embodiments, the processing device 101 obtains a pressure applied by a pressing assembly (e.g., a pressing assembly 107-7 in FIG. 11A and FIG. 12A) of the apparatus 107 for bonding a seed crystal using a pressure sensing assembly (e.g., a pressure sensing assembly 107-6 as shown in FIG. 11A and FIG. 12A) and adjusts the pressure applied accordingly.

In some embodiments, the processing device 101 sends a control instruction to the control device 102, and the control device 102 controls the process of growing a crystal based on the control instruction.

In some embodiments, the processing device 101 includes an industrial control computer. In some embodiments, the processing device 101 acts as an upper-level control and monitoring device or an upper-level processing device.

The control device 102 may be configured to control a variety of operations (e.g., seed crystal coating, seed crystal bonding, crystal growth, etc.) involved in the process of growing the crystal. In some embodiments, the control device 102 receives the control instruction from the processing device 101 and controls the process of growing the crystal based on the control instruction.

In some embodiments, the control device 102 includes a programmable logic controller (PLC). In some embodiments, the control device 102 acts as a lower-level real-time control device.

In some embodiments, the processing device 101 and/or the control device 102 includes a central processing unit (CPU), an application-specific integrated circuit (ASIC), an application-specific instruction set processor (ASIP), an image processing unit (GPU), a physical operations processing unit (PPU), a digital signal processor (DSP), a field programmable gate array (FPGA), a programmable logic device (PLD), a controller, a microcontroller unit, a reduced instruction set computer (RISC), a microprocessor, etc., or any combination thereof. In some embodiments, the processing device 101 and the control device 102 may be integrated into a single device. In some embodiments, the control device 102 may be part of the processing device 101. In some embodiments, the functions of the processing device 101 and the control device 102 may be shared or performed together.

The temperature measurement assembly 103 may be configured to detect the temperature of side walls and/or the top of the growth chamber and send a temperature measurement signal to the processing device 101. In some embodiments, the temperature measurement assembly 103 includes a thermocouple sensor, a thermistor sensor, an infrared thermometer, an optical pyrometer, or a colorimetric pyrometer.

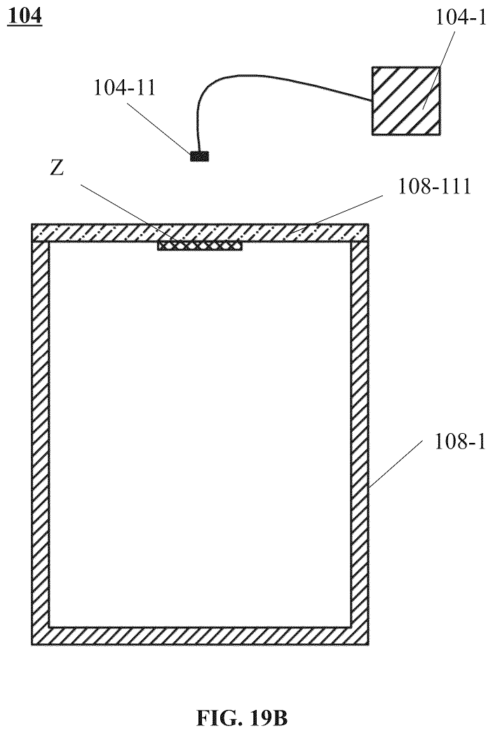

The monitoring assembly 104 may be configured to monitor the situation of growing the crystal and send a monitoring signal to the processing device 101. In some embodiments, the situation of growing the crystal growth includes at least one of thickness, a growth rate, or a defect of a growing crystal. In some embodiments, the monitoring assembly 104 includes a contact monitoring assembly (e.g., an ultrasonic thickness gauge 104-1 in FIG. 19A) or a non-contact monitoring assembly (e.g., an air-coupled ultrasonic nondestructive testing, electromagnetic acoustic transducer (EMAT) nondestructive testing, electrostatically coupled ultrasonic nondestructive testing, and laser ultrasonic nondestructive testing).

The pressure measurement assembly 105 may be configured to monitor the pressure of the apparatus 107 for bonding a seed crystal and send the monitoring signal to the processing device 101. In some embodiments, the pressure measurement assembly 105 includes a pressure sensor. For example, a piezoelectric pressure sensor, a piezoresistive pressure sensor, a capacitive pressure sensor, an electromagnetic pressure sensor, a vibrating string pressure sensor, or the like.

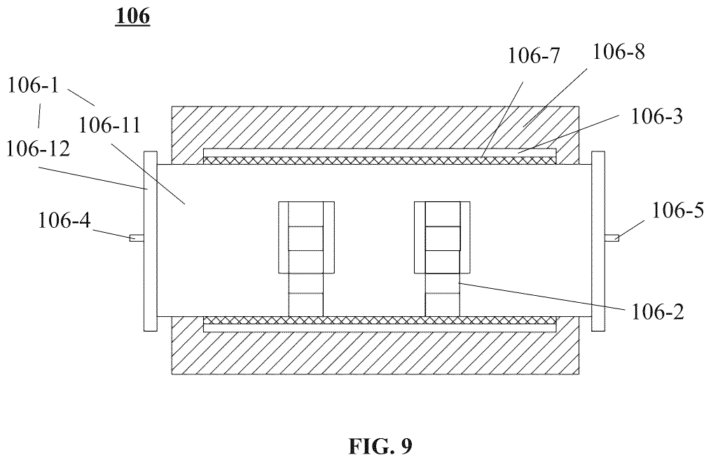

The coating apparatus 106 may be configured to perform coating on the seed crystal. In some embodiments, the coating apparatus 106 includes a coating chamber, a coating rack, a driving assembly, an air evacuating assembly, a heating assembly, an air inlet, an air outlet, or the like. More description of the coating apparatus 106 can be found in FIG. 9 and related descriptions thereof, and will not be repeated herein.

The apparatus 107 for bonding a seed crystal may be configured to perform bonding on the seed crystal. In some embodiments, the apparatus 107 for bonding a seed crystal includes a bonding chamber, a vacuum assembly, an upper transmission assembly, a lower transmission assembly, a heating assembly, a pressing assembly, a support assembly, or the like. More descriptions of the apparatus 107 for bonding a seed crystal can be found in FIG. 11A, FIG. 12A, and related descriptions thereof, and will not be repeated herein.

The crystal growth device 108 may be configured to perform an operation of crystal growth. In some embodiments, the crystal growth device 108 includes the growth chamber, the heating assembly, or the like. More description of the crystal growth device 108 can be found in FIG. 16A to FIG. 16C and related descriptions thereof, and will not be repeated herein.

Taking a specific process of growing a crystal as an example, the control device 102 controls the coating apparatus 106 to coat on a back surface of a seed crystal. In some embodiments, the control device 102 controls the apparatus 107 for bonding a seed crystal to bond the seed crystal (or the coated seed crystal) to a chamber lid or a seed crystal tray. The pressure sensing assembly is configured to detect the applied pressure of a pressing assembly of the apparatus 107 for bonding a seed crystal and feedback the applied pressure to the processing device 101. The processing device 101 is configured to send a control instruction to the control device 102, and the control device 102 accordingly controls the applied pressure of the apparatus 107 for bonding a seed crystal. In some embodiments, the control device 102 controls the crystal growth device 108 to grow a crystal. The temperature measurement assembly 103 is configured to detect the temperature of side walls and/or the top of a growth chamber and feedback the temperature to the processing device 101. The processing device 101 is configured to send a control instruction to the control device 102, and the control device 102 controls and adjusts a position, shape, distribution, area, etc. of at least one outlet. The monitoring assembly 104 is configured to monitor a situation of growing the crystal and feedback the situation to the processing device 101. The processing device 101 is configured to send the control instruction to the control device 102, and the control device is configured to control and adjust a heating parameter of a heating assembly and/or a position, shape, distribution, area, etc. of the at least one outlet.

The storage device 109 may be configured to store a variety of data and/or information involved in the process of growing the crystal. In some embodiments, the storage device 109 may store parameters (e.g., temperature, the situation of growing the crystal), the control instruction, or the like during the process of growing the crystal. In some embodiments, the storage device 109 is directly connected to or in communication with one or more components (e.g., the processing device 101, the control device 102, the temperature measurement assembly 103, the monitoring assembly 104, the pressure measurement assembly 105, the coating apparatus 106, the apparatus 107 for bonding a seed crystal, the crystal growth device 108, the storage device 109, the interaction assembly 110, etc.) in the crystal growth system 100. One or more of the components of the crystal growth system 100 may access the data and/or instructions stored in the storage device 109 via a network or directly. In some embodiments, the storage device 109 may be part of the processing device 101 and/or the control device 102. Data (e.g., pressure control parameters, outlet control parameters, etc.) related to the process of growing the crystal may be recorded in real-time in the storage device 109.

In some embodiments, the storage device 109 may store data and/or instructions used by the processing device 101 to execute or use to accomplish the exemplary methods described in the present disclosure. In some embodiments, the storage device 109 includes mass memory, removable memory, volatile read-write memory, read-only memory (ROM), or the like, or any combination thereof. In some embodiments, the storage device 109 may be implemented on a cloud platform. In some embodiments, the cloud platform includes a private cloud, a public cloud, a hybrid cloud, a community cloud, a distributed cloud, an on-premises cloud, a multi-tiered cloud, etc., or any combination thereof.

The interaction assembly 110 may be used to interact with a user or other assemblies in the crystal growth system 100. In some embodiments, the interaction assembly 110 includes a display apparatus 110-1 and an interaction apparatus 110-2. The display apparatus 110-1 includes a digital tube display, a two-dimensional display, a three-dimensional display, or the like. The interaction apparatus 110-2 includes a mouse, a keyboard, a voice input device, etc.

In some embodiments, the processing device 101 engages in human-computer interaction with an operator (e.g., a crystal preparation engineer) using the display apparatus 110-1 and/or the interaction apparatus 110-2. The operator may query an actual situation of growing a crystal, pressure control parameters, outlet control parameters (e.g., position, shape, distribution, or area of an outlet), or the like using the display apparatus 110-1.

It should be noted that the above description of the crystal growth system 100 is provided only for descriptive convenience, and does not limit the present disclosure to the scope of the embodiments. It will be appreciated that, for a person skilled in the art, after understanding the principle of the system, it may be possible to make a variety of changes to the system and its components without departing from the principle of the system. For example, the temperature measurement assembly 103, the monitoring assembly 104, the pressure measurement assembly 105, and the apparatus 107 for bonding a seed crystal may be components that are independent of the crystal growth device 108, i.e., assemblies of the crystal growth device 108 may not include the temperature measurement assembly 103, the monitoring assembly 104, the pressure measurement assembly 105, and the apparatus 107 for bonding a seed crystal.

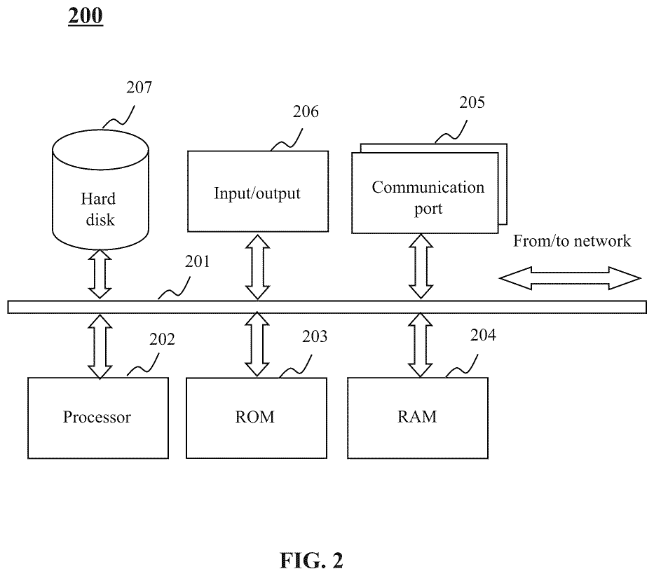

FIG. 2 is a schematic diagram illustrating an exemplary computing device according to some embodiments of the present disclosure.

In some embodiments, the processing device 101, the control device 102, and/or the storage device 109 are implemented on the computing device 200 and configured to perform functions disclosed in the present disclosure.

The computing device 200 includes any of the components used to implement the system described herein. For example, a programmable logic controller (PLC) is implemented on the computing device 200 by its hardware, software program, firmware, or a combination thereof. For convenience, only one computer is illustrated in the figure. However, the computational functions related to feed control described in the present disclosure can be implemented in a distributed manner, using a set of similar platforms to distribute the processing load of the system.

The computing device 200 includes a communication port 205 connected to a network for enabling data communication. The computing device 200 includes a processor 202 (e.g., a CPU) that may execute program instructions in the form of one or more processors. Exemplary computer platforms include an internal bus 201, different forms of program memory and data memory, for example, a hard disk 207, read-only memory (ROM) 203, or random-access memory (RAM) 204, for storing a variety of data files processed and/or transmitted by the computer. The computing device may also include program instructions executed by the processor 202 stored in the read-only memory 203, the random-access memory 204, and/or other types of non-transitory storage media. The methods and/or processes of the present disclosure may be implemented as program instructions. The computing device 200 also includes an input/output component 206 to support input/output between the computer and other components. The computing device 200 may also receive programs and data from the present disclosure via network communications.

For ease of understanding, only one processor is drawn exemplarily in FIG. 2. It should be noted, however, that the computing device 200 of the present disclosure may include multiple processors, and operations and/or methods described in the present disclosure as being implemented by a single processor may also be jointly or independently implemented by multiple processors to be implemented. For example, if the processor of the computing device 200 described in the present disclosure performs operation A and operation B, it should be understood that operation A and operation B may also be performed by two or more different processors in the computing device 200, either jointly or separately (e.g., a first processor performs operation A and a second processor performs operation B or a first processor and a second processor jointly perform operation A and operation B).

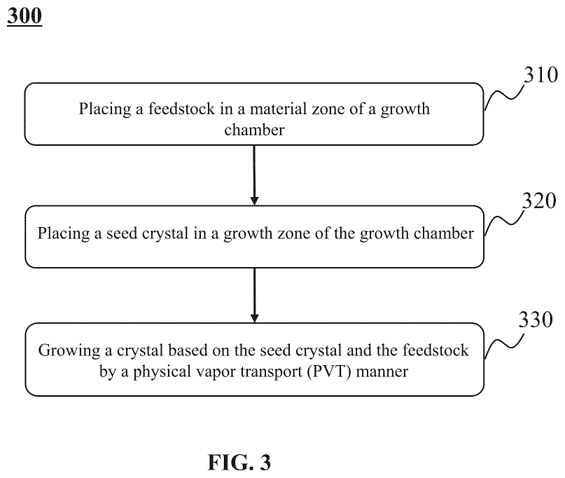

FIG. 3 is a flowchart illustrating a crystal growth method according to some embodiments of the present disclosure. In some embodiments, a process 300 may be performed by a processing device (e.g., the processing device 101) and/or a control device (e.g., the control device 102). For example, the process 300 may be stored in a storage device (e.g., a storage unit of a storage device, a processing device, and/or a control device) in the form of a program or instruction, and the process 300 may be implemented when the processor 202 executes the program or instruction. In some embodiments, the process 300 may be performed manually or semi-automatically by an operator. In some embodiments, the process 300 may be accomplished utilizing one or more of the additional operations not described below, and/or not by one or more of the operations discussed below. Additionally, the order of the operations as shown in FIG. 3 is not limiting.

In step 310, placing a feedstock in a material zone of a growth chamber.

In some embodiments, the feedstock may be a raw material required for growing a crystal. In some embodiments, the feedstock may be a powder, a block, a pellet, or the like. In some embodiments, the purity of the feedstock is greater than or equal to 90.00%. In some embodiments, the purity of the feedstock is greater than or equal to 92.00%. In some embodiments, the purity of the feedstock is greater than or equal to 95.00%. In some embodiments, the purity of the feedstock is greater than or equal to 99.00%. In some embodiments, the purity of the feedstock is greater than or equal to 99.9%. In some embodiments, the purity of the feedstock is greater than or equal to 99.99%. In some embodiments, the purity of the feedstock is greater than or equal to 99.999%.

The following is an example of preparing a silicon carbide crystal.

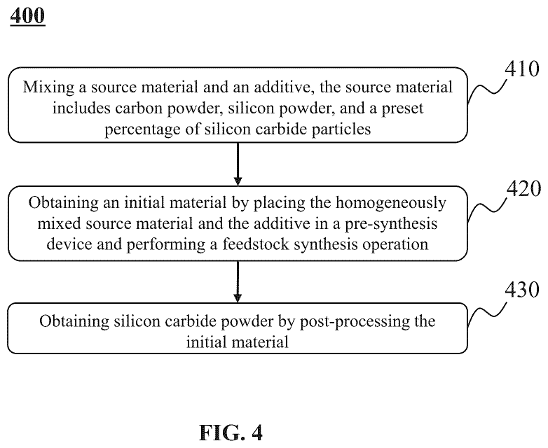

In some embodiments, the feedstock includes silicon carbide powder. More descriptions regarding the preparation of the silicon carbide powder can be found elsewhere in the present disclosure (e.g., FIG. 4 and its related description) and will not be repeated herein.

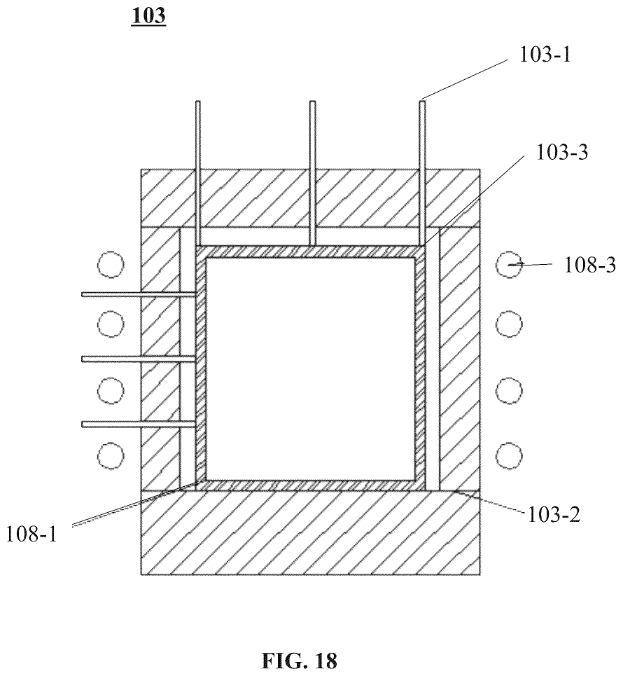

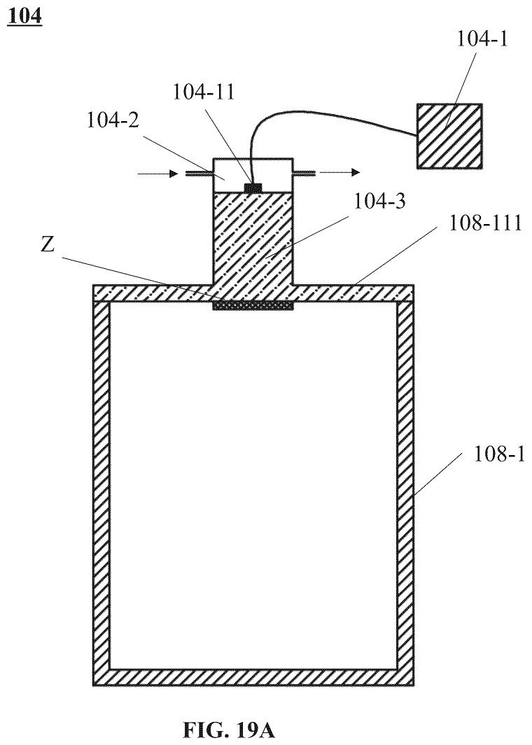

In some embodiments, the growth chamber may be a site for growing the silicon carbide crystal. More descriptions regarding the growth chamber can be found elsewhere in the present disclosure (e.g., FIG. 16A to FIG. 16C, FIG. 18 and their related descriptions) and will not be repeated herein.

In some embodiments, the material zone may be a site to place the silicon carbide powder. In some embodiments, the material zone may be located below the growth chamber.

In some embodiments, the feedstock may be manually placed in the material zone of the growth chamber, which makes the process flexible, simple to equip, and less costly. In some embodiments, a robotic arm may be controlled by a processing device and/or a control device to place the feedstock in the material zone of the growth chamber. In some embodiments, the robotic arm may automatically pick up the feedstock according to a set program to place it in the material zone of the growth chamber, which can reduce labor costs, and enable precise and easy material handling.

In step 320, placing a seed crystal in a growth zone of the growth chamber.

In some embodiments, the seed crystal is a small silicon carbide crystal with high crystalline quality and few crystalline defects, which can be understood as a seed for growing the silicon carbide crystal.

In some embodiments, the growth zone may be a site for growing the silicon carbide crystal based on the seed crystal. In some embodiments, the growth zone may be located above the growth chamber.

In some embodiments, the material zone and the growth zone may be separated by a partition. In some embodiments, during the process of growing a crystal, in order to minimize the impact on the temperature of the growth zone when controlling the temperature of the material zone and maintain the stability of the crystal growth environment, the partition may be made of high-temperature resistant insulating material. For example, the material may be graphite, porous graphite, or the like. In some embodiments, the partition includes at least one outlet. In some embodiments, the feedstock in the material zone is sublimated into a vapor phase component by high-temperature heating, and the vapor phase component enters the growth zone through the outlet on the partition to grow the silicon carbide crystal on a surface of the seed crystal.

By separating the material zone and the growth zone through the partition, the temperatures of the material zone, the vicinity of the partition, and the growth zone can be individually controlled, thereby effectively regulating the process of growing the crystal. Moreover, the partition adopts the high-temperature-resistant insulation material, which makes the temperature of the material zone less influential to the temperature of the growth zone, thus ensuring the stability of the crystal growth environment. Additionally, by adjusting a position, shape, distribution, area, etc. of at least one outlet on the partition, the carbon-silicon molar ratio, the transport path, the transport speed, etc. of the vapor phase component of the feedstock can be adjusted, which effectively regulates an interface of growing the crystal, significantly reducing the probability of dislocation, reducing crystal defects, and improving the quality of the grown crystal.

In some embodiments, the seed crystal is bonded to the growth zone of the growth chamber manually. Bonding the seed crystal manually is a process with low cost that is flexible in operation and simple in equipment. In some embodiments, the robotic arm is controlled to bond the seed crystal to the growth zone of the growth chamber by the processing device and/or the control device. In some embodiments, the robotic arm automatically picks up the seed crystal according to a set program to bond it to the growth zone of the growth chamber, which can reduce labor costs and enable precise and easy material handling.

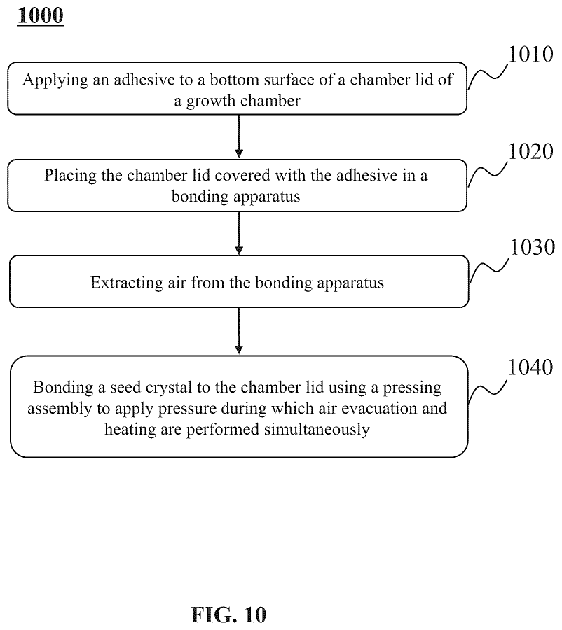

In some embodiments, the seed crystal is bonded to a chamber lid or a seed crystal tray of the growth chamber through the apparatus 107 for bonding a seed crystal. More descriptions regarding bonding the seed crystal can be found elsewhere in the present disclosure (e.g., FIG. 10 to FIG. 14B and their related descriptions) and will not be repeated herein.

In some embodiments, porosity detection on the bonding of the seed crystal is performed using an ultrasonic detection apparatus during the process of bonding the seed crystal and/or after the seed crystal has been bonded to the chamber lid or the seed crystal tray. In some embodiments, the ultrasonic detection apparatus includes an ultrasonic flaw detector.

In some embodiments, the porosity detection refers to detecting the state of the porosity in the seed crystal during the process of bonding the seed crystal and/or after the seed crystal has been bonded. In some embodiments, a result of the porosity detection includes at least one of a porosity position, a porosity size, a porosity shape, or a porosity density.

In some embodiments, the ultrasonic detection device (e.g., the ultrasonic flaw detector) emits ultrasonic waves through a seed crystal growth surface into the interior of the seed crystal, transmitting the waves from the seed crystal growth surface into the seed crystal that is in a bonding process or has already been bonded. Since the propagation speed and amplitude of ultrasonic waves differ in bubbles (or “porosities”) compared to a bonding region, the ultrasonic detection apparatus can determine porosity positions, porosity sizes, porosity shapes, or porosity density of porosities on the seed crystal during or after the bonding process by analyzing the received ultrasonic waves' reflection time, amplitude, and other factors. In some embodiments, a pressure during the process of bonding the seed crystal can be adjusted based on the porosity detection result. In some embodiments, if a porosity density greater than a porosity density threshold (e.g., 8/cm²) is detected during the process of bonding the seed crystal, an applied pressure of a pressing assembly can be increased and/or an evacuating power of an air evacuating assembly can be increased to reduce the pressure within the bonding apparatus to expel the porosities. In some embodiments, if the porosity density less than the porosity density threshold is detected during the process of bonding the seed crystal, the applied pressure of the pressuring assembly and/or the pressure within the bonding apparatus can be maintained to continue a pressing operation. In some embodiments, if a localized porosity density of the seed crystal greater than the porosity density threshold is detected during the process of bonding the seed crystal, the applied localized pressure of the pressing assembly can be adjusted to expel the localized porosities. The quality of the seed crystal bonding can be improved by adjusting the applied pressure and/or the applied localized pressure of the pressing assembly and/or the pressure within the bonding apparatus during the bonding process based on the porosity detection result. In some embodiments, if the porosity density greater than the porosity density threshold is detected after the seed crystal has been bonded, the seed crystal can be removed and re-bonded to improve the quality of the seed crystal bonding.

In step 330, growing the crystal based on the seed crystal and the feedstock by a physical vapor transport (PVT) manner.

In some embodiments, a silicon carbide feedstock in the material zone is sublimated through high temperature heating to a vapor phase component (e.g., Si, Si₂C, SiC₂, etc.), then the vapor phase component is driven by a temperature gradient and/or a concentration gradient through the at least one outlet on the partition into the growth zone at a relatively low temperature and transported to the seed crystal, then the vapor phase component nucleates, grows up and crystallizes to form the silicon carbide (SiC) crystal.

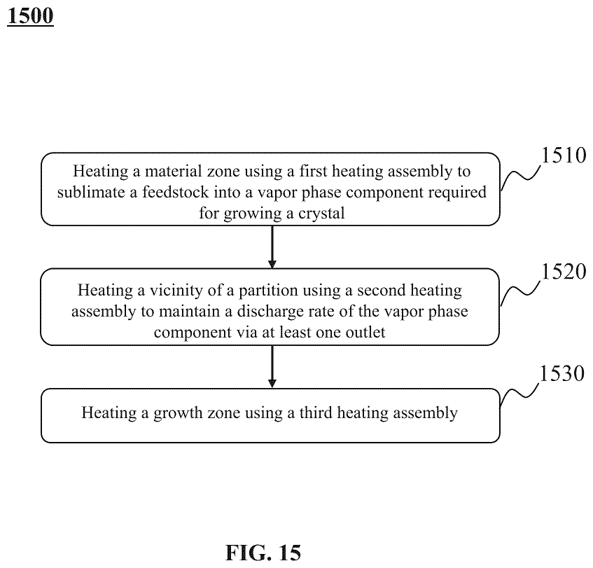

In some embodiments, during the process of growing the crystal by the physical vapor transport manner, the growth chamber is heated by a heating assembly to achieve the sublimation of the feedstock, the transport of the vapor phase component, or the like. More descriptions regarding heating the growth chamber by the heating assembly can be found elsewhere in the present disclosure (e.g., FIG. 15 and its related description) and will not be repeated herein.

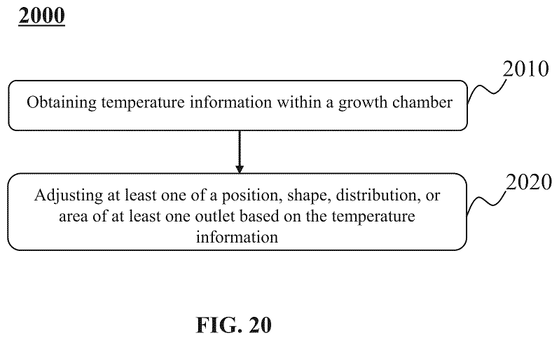

In some embodiments, a position of the at least one outlet can be adjusted in an axial direction or radial direction during the process of growing the crystal by the physical vapor transport manner. By adjusting the position of the at least one outlet, a more uniform distribution of vapor phase components on a crystal growth surface can be achieved, leading to a flatter crystal, reducing crystal defects, and improving the quality of the crystal. More descriptions regarding adjusting the position of the at least one outlet in the axial direction or the radial direction can be found elsewhere in the present disclosure (e.g., FIG. 20 and its related description) and will not be repeated herein.

In some embodiments, during the process of growing the crystal by the physical vapor transport manner, temperature information within the growth chamber can be obtained; and based on the temperature information, at least one of the position, shape, distribution, or area of the at least one outlet can be adjusted. In some embodiments, during the process of growing the crystal by the physical vapor transport manner, the temperature information within the growth chamber can be obtained; and based on the temperature information, a position, shape, distribution, or area of the at least one outlet can be adjusted during a next process of growing a crystal. More descriptions regarding adjusting at least one of the position, shape, distribution, or area of the at least one outlet based on the temperature information can be found elsewhere in the present disclosure (e.g., FIG. 20 and its related description) and will not be repeated herein.

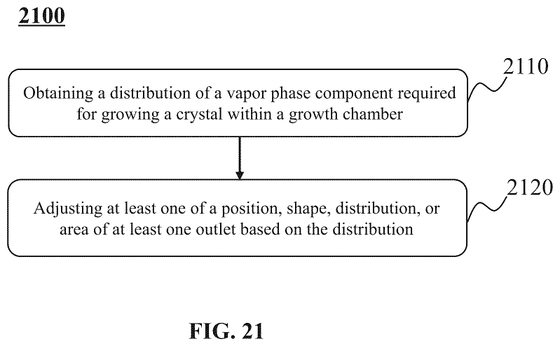

In some embodiments, during the process of growing the crystal by the physical vapor transport manner, a distribution of vapor phase components within the growth chamber can be obtained; and based on the distribution, at least one of the position, shape, distribution, or area of the at least one outlet can be adjusted. In some embodiments, during the process of growing the crystal by the physical vapor transport manner, the distribution of the vapor phase components within the growth chamber can be obtained; and based on the distribution, a position, shape, distribution, or area of at least one outlet can be adjusted during a next process of growing a crystal. More descriptions regarding adjusting at least one of the position, shape, distribution, or area of the at least one outlet based on the distribution can be found elsewhere in the present disclosure (e.g., FIG. 21 and its related description) and will not be repeated herein.

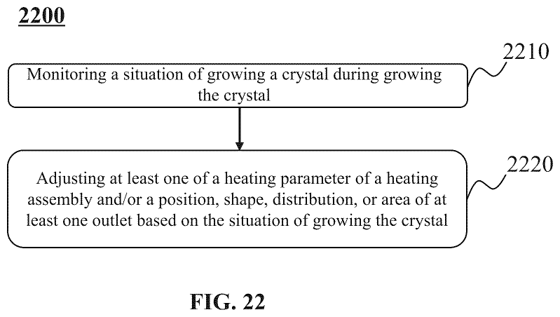

In some embodiments, during the process of growing the crystal, a situation of growing the crystal can be monitored; and based on the situation of growing the crystal, at least one of a heating parameter of the heating assembly and/or the position, shape, distribution, or area of the at least one outlet can be adjusted. In some embodiments, during the process of growing the crystal, the situation of growing the crystal can be monitored; and based on the situation of growing the crystal, heating parameter of the heating assembly and/or a position, shape, distribution, or area of at least one outlet can be adjusted during a next process of growing a crystal growth. More descriptions regarding adjusting the heating parameter of the heating assembly and/or at least one of the position, shape, distribution, or area of the at least one outlet based on the situation of growing the crystal can be found elsewhere in the present disclosure (e.g., FIG. 22 and its related descriptions) and will not be repeated herein.

It should be noted that the foregoing descriptions of the process are for the purpose of exemplification and illustration only, and do not limit the scope of application of the present disclosure. For a person skilled in the art, various corrections and changes can be made to the process under the guidance of the present disclosure. However, these corrections and changes remain within the scope of the present disclosure. For example, the process 300 includes a storage step in which the processing device and/or the control device store the information and/or data involved in the process 300 (e.g., the position, shape, distribution, area, etc., of the at least one outlet, etc.) in a storage device (e.g., the storage device 109).

During the process of growing the silicon carbide crystal, the quality and purity of the silicon carbide feedstock are crucial, and silicon carbide feedstocks available in the market are generally low in purity, with an impurity content of more than 5 ppm. However, a high impurity content tends to affect the subsequent growth of the silicon carbide crystal, which is mainly manifested as follows: (1) affecting the resistivity regulation of the silicon carbide crystals; (2) affecting the color as well as the color homogeneity of the silicon carbide crystals; (3) affecting the nucleation energy and crystal morphology stability of the silicon carbide crystals; (4) seriously corroding the crucible and changing the composition ratio during a process of growing the crystals. Accordingly, embodiments of the present disclosure provide a method for preparing a silicon carbide feedstock with a low impurity concentration.

FIG. 4 is a flowchart illustrating a process of preparing a feedstock according to some embodiments of the present disclosure. In some embodiments, a process 400 is accomplished utilizing one or more of the additional operations not described below, and/or not by one or more of the operations discussed below. Additionally, the order of the operations as shown in FIG. 4 is not limiting.

In step 410, mixing a source material and an additive.

In some embodiments, the source material is an initial material of a feedstock used to prepare a crystal. In some embodiments, the source material includes carbon powder, silicon powder, and a preset percentage of silicon carbide particles.

In some embodiments, the carbon powder is high-purity carbon powder with an ash content of less than 5 ppm. In some embodiments, the carbon powder is high-purity carbon powder with an ash content of less than 4 ppm. In some embodiments, the carbon powder is high-purity carbon powder with an ash content of less than 3 ppm. In some embodiments, the carbon powder is high-purity carbon powder with an ash content of less than 2 ppm. In some embodiments, the carbon powder is high-purity carbon powder with an ash content of less than 1 ppm. In some embodiments, the silicon powder is a high-purity silicon powder of grade 3N. In some embodiments, the silicon powder is a high-purity silicon powder of grade 4N. In some embodiments, the silicon powder is a high-purity silicon powder of grade 5N. In some embodiments, the silicon powder is a high-purity silicon powder of grade 6N. In some embodiments, the silicon powder is a high-purity silicon powder of 7N.

In some embodiments, particle sizes of the carbon powder, the silicon powder, and/or the silicon carbide particles need to meet certain requirements to allow for homogeneous mixing of the source material as well as an adequate reaction of a feedstock synthesis operation.

In some embodiments, the particle size of the carbon powder is in a range of 0.01 μm to 2 mm. In some embodiments, the particle size of the carbon powder is in a range of 0.03 μm to 1.8 mm. In some embodiments, the particle size of the carbon powder is in a range of 0.05 μm to 1.5 mm. In some embodiments, the particle size of the carbon powder is in a range of 0.08 μm to 1.0 mm. In some embodiments, the particle size of the carbon powder is in a range of 0.1 μm to 800 μm. In some embodiments, the particle size of the carbon powder is in a range of 0.3 μm to 500 μm. In some embodiments, the particle size of the carbon powder is in a range of 0.5 μm to 300 μm. In some embodiments, the particle size of the carbon powder is in a range of 1 μm to 200 μm. In some embodiments, the particle size of the carbon powder is in a range of 5 μm to 150 μm. In some embodiments, the particle size of the carbon powder is in a range of 10 μm to 128 μm. In some embodiments, the particle size of the carbon powder is in a range of 30 μm to 100 μm. In some embodiments, the particle size of the carbon powder is in a range of 50 μm to 80 mm. In some embodiments, the particle size of the carbon powder is in a range of 60 μm to 70 μm.

In some embodiments, the particle size of the silica powder is in a range of 0.01 mm to 5 mm. In some embodiments, the particle size of the silica powder is in a range of 0.1 mm to 4.5 mm. In some embodiments, the particle size of the silica powder is in a range of 0.3 mm to 4.0 mm. In some embodiments, the particle size of the silica powder is in a range of 0.5 mm to 3.5 mm. In some embodiments, the particle size of the silica powder is in a range of 0.7 mm to 3.0 mm. In some embodiments, the particle size of the silica powder is in a range of 1 mm to 2.5 mm. In some embodiments, the particle size of the silica powder is in a range of 1.3 mm to 2.0 mm. In some embodiments, the particle size of the silica powder is in a range of 1.5 mm to 1.8 mm. In some embodiments, the particle size of the silica powder is in a range of 1.6 mm to 1.7 mm.

In some embodiments, the particle size of the silicon carbide particles is in a range of 10 mesh to 120 mesh. In some embodiments, the particle size of the silicon carbide particles is in a range of 16 mesh to 100 mesh. In some embodiments, the particle size of the silicon carbide particles is in a range of 20 mesh to 80 mesh. In some embodiments, the particle size of the silicon carbide particles is in a range of 25 mesh to 60 mesh. In some embodiments, the particle size of the silicon carbide particles is in a range of 30 mesh to 50 mesh. In some embodiments, the particle size of the silicon carbide particles is in a range of 35 mesh to 45 mesh. In some embodiments, the particle size of the silicon carbide particles is in a range of 35 mesh to 40 mesh.

In some embodiments, the preset percentage is a ratio of the silicon carbide particles to the total weight of the carbon powder and the silicon powder. In some embodiments, the preset percentage is in a range of 1% to 30% of the total weight of the carbon powder and the silicon powder. In some embodiments, the preset percentage is in a range of 3% to 28% of the total weight of the carbon powder and the silicon powder. In some embodiments, the preset percentage is in a range of 5% to 26% of the total weight of the carbon powder and the silicon powder. In some embodiments, the preset percentage is in a range of 7% to 24% of the total weight of the carbon powder and the silicon powder. In some embodiments, the preset percentage is in a range of 10% to 22% of the total weight of the carbon powder and the silicon powder. In some embodiments, the preset percentage is in a range of 13% to 20% of the total weight of the carbon powder and the silicon powder. In some embodiments, the preset percentage is in a range of 15% to 18% of the total weight of the carbon powder and the silicon powder. In some embodiments, the preset percentage is in a range of 16% to 17% of the total weight of the carbon powder and the silicon powder.

In some embodiments, the additive includes polytetrafluoroethylene.

In some embodiments, the additive is added in a ratio to the source material. In some embodiments, the mass ratio of the carbon power:silica powder:polytetrafluoroethylene is 1:2:(0.01 to 0.5). In some embodiments, the mass ratio of the carbon powder:silica powder:polytetrafluoroethylene is 1:2:(0.03 to 0.4). In some embodiments, the mass ratio of the carbon powder:silica powder:polytetrafluoroethylene is 1:2:(0.05 to 0.3). In some embodiments, the mass ratio of the carbon powder:silica powder:polytetrafluoroethylene is 1:2 (0.08 to 0.2). In some embodiments, the mass ratio of the carbon powder:silica powder:polytetrafluoroethylene is 1:2:(0.1 to 0.15). In some embodiments, the mass ratio of the carbon powder:silica powder:polytetrafluoroethylene is 1:2:(0.12 to 0.14).

In some embodiments, a powder mixing apparatus is configured to mix the source material and the additive. In some embodiments, the powder mixing apparatus includes a double screw conical mixer, a horizontal gravity mixer, a horizontal plow blade mixer, a horizontal screw belt mixer, or the like, or any combination thereof. In some embodiments, a mortar (e.g., an agate mortar) is configured to mix the source material and the additive.

In step 420, obtaining an initial material by placing the homogeneously mixed source material and the additive in a pre-synthesis device and performing the feedstock synthesis operation.

In some embodiments, the pre-synthesis device is a site capable of providing a certain temperature, pressure, and/or atmosphere for synthesizing the feedstock. In some embodiments, the homogeneously mixed source material and the additive are placed in a crucible, and the crucible containing the source material and the additive is then placed in the pre-synthesis device to perform the feedstock synthesis operation. In some embodiments, the crucible includes a tantalum carbide crucible, a high-purity graphite crucible internally coated with a tantalum carbide coating, a high-purity graphite crucible, or the like. Compared with the use of a conventional carbon crucible, using the tantalum carbide crucible or the crucible internally coated with a tantalum carbide coating avoids the contamination of the feedstock by impurities such as B, Al, etc., in the carbon crucible during the synthesis of the feedstock, and improves the purity of the feedstock.

In some embodiments, the feedstock synthesis operation includes a first phase and a second phase. In some embodiments, the first stage is a reaction stage and the second stage is a sublimation recrystallization stage.

In some embodiments, a reaction temperature of the reaction stage is in a range of 1200° C. to 1600° C. In some embodiments, the reaction temperature of the reaction stage is in a range of 1250° C. to 1550° C. In some embodiments, the reaction temperature of the reaction stage is in a range of 1300° C. to 1500° C. In some embodiments, the reaction temperature of the reaction stage is in a range of 1350° C. to 1450° C. In some embodiments, the reaction temperature of the reaction stage is in a range of 1370° C. to 1430° C. In some embodiments, the reaction temperature of the reaction stage is in a range of 1390° C. to 1410° C.

Since higher pressure is favorable for suppressing the vapor phase transport of the feedstock, the feedstock can react in situ to generate SiC crystal nuclei. On the other hand, lower pressure is beneficial for eliminating impurities. Therefore, the reaction pressure during the reaction stage can be set within a wide range. In some embodiments, the reaction pressure of the reaction stage is in a range of 10⁻⁵ Pa to 101 kPa. In some embodiments, the reaction pressure of the reaction stage is in a range of 104 Pa to 90 kPa. In some embodiments, the reaction pressure of the reaction stage is in a range of 10⁻³ Pa to 80 kPa. In some embodiments, the reaction pressure of the reaction stage is in a range of 10⁻² Pa to 70 kPa. In some embodiments, the reaction pressure of the reaction stage is in a range of 0.1 Pa to 60 kPa. In some embodiments, the reaction pressure of the reaction stage is in a range of 1 Pa to 50 kPa. In some embodiments, the reaction pressure of the reaction stage is in a range of 10 Pa to 40 kPa. In some embodiments, the reaction pressure of the reaction stage is in a range of 15 Pa to 35 kPa. In some embodiments, the reaction pressure of the reaction stage is in a range of 20 Pa to 30 Pa. In some embodiments, the reaction pressure of the reaction stage is in a range of 22 Pa to 28 Pa. In some embodiments, the reaction pressure of the reaction stage is in a range of 23 Pa to 25 Pa.

In some embodiments, a reaction time of the reaction stage is in a range of 0.5 h to 10 h. In some embodiments, the reaction time of the reaction stage is in a range of 1 h to 9 h. In some embodiments, the reaction time of the reaction stage is in a range of 2 h to 8 h. In some embodiments, the reaction time of the reaction stage is in a range of 3 h to 7 h. In some embodiments, the reaction time of the reaction stage is in a range of 4 h to 6 h. In some embodiments, the reaction time of the reaction stage is in a range of 5 h to 5.5 h.

After the first stage (the reaction stage), usually smaller particles of silicon carbide are produced (e.g., particle size in a range of 40 mesh to 80 mesh). If a silicon carbide feedstock with a small particle is used for growing a crystal, on the one hand, the silicon carbide feedstock has a very small porosity, which is not conducive to the vapor phase transport of the feedstock after it is heated, and a transport channel is easily clogged, which ultimately affects the quality of the crystal due to the insufficient supply of feedstock. On the other hand, fine particles of the silicon carbide in the bottom of the crucible after small particles of silicon carbide are heated and carbonized tend to be transported to a crystal growth surface through the vapor phase transport, forming carbon inclusion defects and lowering the quality of the crystal. Accordingly, the second stage (i.e., the sublimation and recrystallization stage) is required, in which the small particles of silicon carbide are sublimated and then recrystallized on a surface of silicon carbide particles in the source material was added in step 410 to produce the initial material with larger particles (e.g., particle size of 8 mesh to 40 mesh), thereby improving the quality of the subsequent crystal growth.

In some embodiments, a reaction temperature of the sublimation recrystallization stage is in a range of 1600° C. to 2500° C. In some embodiments, the reaction temperature of the sublimation recrystallization stage is in a range of 1650° C. to 2450° C. In some embodiments, the reaction temperature of the sublimation recrystallization stage is in a range of 1700° C. to 2400° C. In some embodiments, the reaction temperature of the sublimation recrystallization stage is in a range of 1750° C. to 2350° C. In some embodiments, the reaction temperature of the sublimation recrystallization stage is in a range of 1800° C. to 2300° C. In some embodiments, the reaction temperature of the sublimation recrystallization stage is in a range of 1850° C. to 2250° C. In some embodiments, the reaction temperature of the sublimation recrystallization stage is in a range of 1900° C. to 2200° C. In some embodiments, the reaction temperature of the sublimation recrystallization stage is in a range of 1950° C. to 2150° C. In some embodiments, the reaction temperature of the sublimation recrystallization stage is in a range of 2000° C. to 2100° C. In some embodiments, the reaction temperature of the sublimation recrystallization stage is in a range of 2030° C. to 2170° C.

In some embodiments, a reaction pressure of the sublimation recrystallization stage is in a range of 10⁻³ Pa to 0.1 MPa. In some embodiments, the reaction pressure of the sublimation recrystallization stage is in a range of 10⁻² Pa to 0.01 MPa. In some embodiments, the reaction pressure of the sublimation recrystallization stage is in a range of 0.1 Pa to 1 kPa. In some embodiments, the reaction pressure of the sublimation recrystallization stage is in a range of 1 Pa to 100 Pa. In some embodiments, the reaction pressure of the sublimation recrystallization stage is in a range of 3 Pa to 90 Pa. In some embodiments, the reaction pressure in the sublimation recrystallization stage is in a range of 5 Pa to 80 Pa. In some embodiments, the reaction pressure of the sublimation recrystallization stage is in a range of 7 Pa to 70 Pa. In some embodiments, the reaction pressure of the sublimation recrystallization stage is in a range of 10 Pa to 60 Pa. In some embodiments, the reaction pressure of the sublimation recrystallization stage is in a range of 20 Pa to 50 Pa. In some embodiments, the reaction pressure in the sublimation recrystallization stage is in a range of 30 Pa to 40 Pa.

In some embodiments, a reaction time of the sublimation recrystallization stage is in a range of 5 h to 60 h. In some embodiments, the reaction time of the sublimation recrystallization stage is in a range of 10h˜55 h. In some embodiments, the reaction time of the sublimation recrystallization stage is in a range of 15 h to 50 h. In some embodiments, the reaction time of the sublimation recrystallization stage is in a range of 20 h to 45 h. In some embodiments, the reaction time of the sublimation recrystallization stage is in a range of 25 h to 40 h. In some embodiments, the reaction time of the sublimation recrystallization stage is in a range of 30 h to 35 h.

In step 430, obtaining silicon carbide powder by post-processing the initial material.

In some embodiments, post-processing the initial material includes one or more of pulverizing, sieving, de-carbonizing, washing, drying, and encapsulating the initial material.

By post-processing the initial material, the silicon carbide feedstock with uniform particle size and high purity can be obtained.

In the present disclosure, the addition of silicon carbide particles to the source material can serve as a crystallization nucleating agent during subsequent feedstock synthesis operations. This causes the small silicon carbide particles generated in the reaction to sublimate and recrystallize on their surfaces, growing into larger silicon carbide particles. As a result, defects in the initial material are reduced, improving the overall quality of the initial material. Additionally, with the addition of polytetrafluoroethylene (PTFE) additive, PTFE decomposes into gas when heated, and since its decomposition temperature is lower than the synthesis temperature of the initial material, the decomposition of PTFE occurs before the synthesis reaction of the initial material begins. Therefore, it does not affect the synthesis of the initial material. Furthermore, when polytetrafluoroethylene (PTFE) decomposes into gas upon heating, it creates spaces within the accumulated source material, which allows the air (particularly nitrogen) inside the accumulated source material to be evacuated by a vacuum pump, thereby improving the purity of the environment during the synthesis of the initial material. As a result, the purity of the final prepared initial material and silicon carbide powder is enhanced.

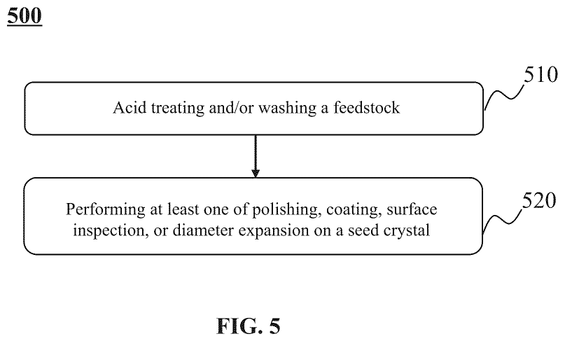

FIG. 5 is a flowchart illustrating a process of pre-processing a feedstock and a seed crystal according to some embodiments of the present disclosure. In some embodiments, a process 500 is accomplished utilizing one or more additional operations not described below, and/or not by one or more operations discussed below. Additionally, the order of the operations as shown in FIG. 5 is not limiting.

In step 510, acid treating a feedstock and/or washing the feedstock.

In some embodiments, an acid solution used for the acid treating includes hydrochloric acid, sulfuric acid, aqua regia, or hydrofluoric acid. By acid treating the feedstock, metal impurities in a silicon carbide feedstock can be removed, and the reaction between the silicon carbide and the metal impurities during the process of growing a crystal can be avoided, which improves the quality of the crystal.

In some embodiments, a solution used for washing includes ultrapure water, pure water, deionized water, or distilled water. In some embodiments, the ultrapure water is used for washing to avoid secondary contamination from impurities in the water during a washing process.

The density of microtubules in a subsequently prepared crystal can be reduced and the quality of the crystal can be improved by performing steps such as the acid treating and/or cleaning on silicon carbide powder.

In step 520, performing at least one of polishing, coating, surface inspection, or diameter expansion on a seed crystal.

In some embodiments, the polishing includes placing the seed crystal on a polishing apparatus, controlling the polishing apparatus to polish the seed crystal for a certain polishing time under a polishing condition, and obtaining the seed crystal after the polishing.

In some embodiments, the polishing condition includes a polishing pressure and a polishing rotation speed.

The polishing pressure being too large tends to cause the polishing process to be unstable or to cause the thickness of the polished seed crystal to be too thin, whereas the polishing pressure being too small tends to cause the roughness or flatness of a polished surface of the polished seed crystal to fail to satisfy the requirements. Therefore, a suitable polishing pressure needs to be satisfied. In some embodiments, the polishing pressure is in a range of 0.05 MPa to 1 MPa. In some embodiments, the polishing pressure is in a range of 0.5 MPa to 0.95 MPa. In some embodiments, the polishing pressure is in a range of 0.1 MPa to 0.9 MPa. In some embodiments, the polishing pressure is in a range of 0.15 MPa to 0.85 MPa. In some embodiments, the polishing pressure is in a range of 0.2 MPa to 0.8 MPa. In some embodiments, the polishing pressure is in a range of 0.25 MPa to 0.75 MPa. In some embodiments, the polishing pressure is in a range of 0.3 MPa to 0.7 MPa. In some embodiments, the polishing pressure is in a range of 0.35 MPa to 0.65 MPa. In some embodiments, the polishing pressure is in a range of 0.4 MPa to 0.6 MPa. In some embodiments, the polishing pressure is in a range of 0.45 MPa to 0.55 MPa. In some embodiments, the polishing pressure is in a range of 0.49 MPa to 0.51 MPa.

The polishing rotation speed being too large tends to result in an unstable polishing process, susceptible to lobes and scratches, or results in too thin a thickness of the polished seed crystal, whereas the polishing rotation speed being too small tends to result in an excessively long polishing time and reduced polishing efficiency. Therefore, a suitable polishing rotation speed needs to be set. In some embodiments, the rotation speed is in a range of 10 r/min to 80 r/min. In some embodiments, the rotation speed is in a range of 15 r/min to 75 r/min. In some embodiments, the rotation speed is in a range of 20 r/min to 70 r/min. In some embodiments, the rotation speed is in a range of 25 r/min to 65 r/min. In some embodiments, the rotation speed is in a range of 30 r/min to 60 r/min. In some embodiments, the rotation speed is in a range of 35 r/min to 55 r/min. In some embodiments, the rotation speed is in a range of 40 r/min to 50 r/min. In some embodiments, the rotation speed is in a range of 43 r/min to 47 r/min.

In some embodiments, the polishing time is in a range of 5 min to 480 min. In some embodiments, the polishing time is in a range of 30 min to 450 min. In some embodiments, the polishing time is in a range of 60 min to 420 min. In some embodiments, the polishing time is in a range of 90 min to 390 min. In some embodiments, the polishing time is in a range of 120 min to 360 min. In some embodiments, the polishing time is in a range of 150 min to 330 min. In some embodiments, the polishing time is in a range of 180 min to 300 min. In some embodiments, the polishing time is in a range of 210 min to 270 min. In some embodiments, the polishing time is in a range of 230 min to 250 min. In some embodiments, the polishing time is in a range of 235 min to 245 min.

In some embodiments, polishing powder is used in a polishing process. In some embodiments, the polishing powder includes rare earth polishing powder, diamond polishing powder (e.g., polycrystalline diamond micro powder, monocrystalline diamond micro powder, nano-diamond micro powder), alumina series micro powder, cerium oxide series micro powder, and coated diamond micro powder.

A particle size of the polishing powder being too large tends to cause scratches on a surface of the seed crystal, while a particle size of the polishing powder being too small tends to cause the roughness and flatness of the surface of the polished seed crystal to fail to meet the requirements. Therefore, a suitable particle size of the polishing powder needs to be set. In some embodiments, the particle size of the polishing powder is in a range of 0.01 μm to 2 μm. In some embodiments, the particle size of the polishing powder is in a range of 0.1 μm to 1.9 μm. In some embodiments, the particle size of the polishing powder is in a range of 0.2 μm to 1.8 μm. In some embodiments, the particle size of the polishing powder is in a range of 0.4 μm to 1.6 μm. In some embodiments, the particle size of the polishing powder is in a range of 0.6 μm to 1.4 μm. In some embodiments, the particle size of the polishing powder is in a range of 0.8 μm to 1.2 μm. In some embodiments, the particle size of the polishing powder is in a range of 1.0 μm to 1.1 μm.

In some embodiments, different types, thicknesses, and/or conditions (e.g., roughness on a surface) of the seed crystal correspond to different polishing conditions, different polishing times, and/or different particle sizes of polishing powder.

By polishing the seed crystal, the degree of surface defects and surface contamination can be reduced, and the generation of new microtubules in a grown crystal can be effectively avoided.

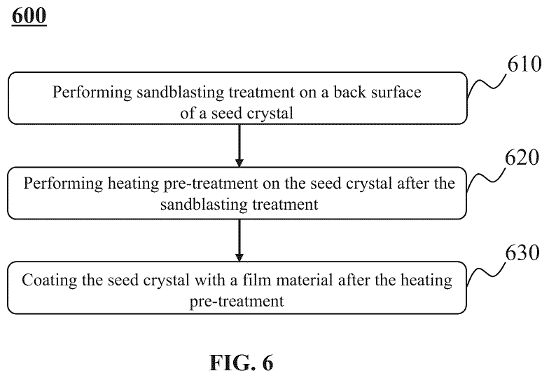

In some embodiments, a back surface of a seed crystal growth surface is coated. In some embodiments, a coating manner includes thermal evaporation, magnetron sputtering, physical vapor deposition, chemical vapor deposition, electron beam evaporation, reaction sintering, plasma coating, molecular beam epitaxy, liquid phase epitaxy, laser deposition, or the like. More descriptions regarding the coating can be found elsewhere in the present disclosure (e.g., FIG. 6 to FIG. 9 and their related descriptions) and will not be repeated herein.

By coating the back surface of the seed crystal growth surface, the density of hexagonal voids within the crystal can be reduced, thus effectively avoiding the increase in the number of microtubules when growing the crystal.

In some embodiments, the surface inspection includes inspecting the surface of the seed crystal for microtubules, the surface of the seed crystal for mechanical damage, the surface of the seed crystal for cleanliness, or the like.

In some embodiments, the surface inspection on the seed crystal can be achieved in a variety of ways. For example, X-ray diffraction, laser scattering, and micro-Raman spectroscopy.

The surface inspection allows for strict monitoring of a surface state of the seed crystal before growing the crystal, effectively avoiding the increase in the number of microtubules when growing the crystal.

In some embodiments, since large-sized seed crystals with low defect density are more difficult to obtain, smaller-sized seed crystals with low defect density are used and their diameter can be extended through a diameter expansion process to obtain the large-sized seed crystals. In some embodiments, the seed crystal is placed in a ring with a diameter larger than a diameter of the seed crystal to allow the seed crystal to grow radially first. In some embodiments, the diameter of the ring is set based on a diameter of a crystal desired during an actual process of growing a crystal. For example, a diameter of a crystal to be grown is 8 inches, and the diameter of the ring is set to be 8 inches as well. In some embodiments, after the diameter of the seed crystal grows to the diameter of the ring, process parameters are controlled to enable the seed crystal to grow axially. In some embodiments, smaller-sized seed crystals with low defect density can also be used to obtain a large-sized ingot through a diameter expansion growth method, and then sliced and processed into large-sized seed crystals of a desired diameter.

An area of regions with low defect density can be increased and the number of microtubules within the prepared crystal can be reduced by performing the diameter expansion on the seed crystal.

The quality of the seed crystal can be improved and the number of microtubules within the prepared crystal can be reduced by performing the polishing, coating, surface inspection, or diameter expansion on the seed crystal before growing the crystal.

FIG. 6 is a flowchart illustrating a process of coating a seed crystal according to some embodiments of the present disclosure. In some embodiments, a process 600 is performed by a processing device (e.g., the processing device 101) and/or a control device (e.g., the control device 102). For example, the process 600 is stored in a storage device (e.g., a storage unit of a storage device, a processing device, and/or a control device) in the form of a program or instruction, and the process 600 is implemented when the processor 202 executes the program or instruction. In some embodiments, the process 600 is accomplished utilizing one or more additional operations not described below, and/or without one or more operations discussed below. Additionally, the order of the operations as shown in FIG. 6 is not limiting.

In step 610, performing sandblasting treatment on a back surface of a seed crystal.

In some embodiments, in order to make the adhesion effect of the seed crystal better after coating, the back surface of the seed crystal is subjected to the sandblasting treatment before coating is performed on the seed crystal to obtain the seed crystal with a certain roughness. In some embodiments, the back surface of the seed crystal is a surface of the seed crystal opposite a seed crystal growth surface.

In some embodiments, the back surface of the seed crystal is subjected to the sandblasting treatment using a blasting material (e.g., adamantine, quartz sand, iron sand, copper ore sand) with particles of 100 mesh to 200 mesh. In some embodiments, the back surface of the seed crystal is subjected to the sandblasting treatment using a blasting material with particles of 110 mesh to 190 mesh. In some embodiments, the back surface of the seed crystal is subjected to the sandblasting treatment using a blasting material with particles of 120 mesh to 180 mesh. In some embodiments, the back surface of the seed crystal is subjected to the sandblasting treatment using a blasting material with particles of 130 mesh to 170 mesh. In some embodiments, the back surface of the seed crystal is subjected to the sandblasting treatment using a blasting material with particles of 140 mesh to 160 mesh. In some embodiments, the back surface of the seed crystal is subjected to the sandblasting treatment using a blasting material with particles of 150 mesh to 155 mesh.

After the sandblasting treatment, if the roughness of the back surface of the seed crystal is too small, the adhesion of a coated film will be poor and easy to come off; if the roughness is too large, it will affect the flatness of the back surface of the seed crystal, and the seed crystal will not be easy to be bonded to a chamber lid or a seed crystal tray. Therefore, the roughness of the back surface of the sandblasted seed crystal should meet certain requirements. In some embodiments, the roughness of the sandblasted seed crystal is in a range of 1 μm to 80 μm. In some embodiments, the roughness of the sandblasted seed crystal is in a range of 5 μm to 75 μm. In some embodiments, the roughness of the sandblasted seed crystal is in a range of 10 μm to 70 μm. In some embodiments, the roughness of the sandblasted seed crystal is in a range of 15 μm to 65 μm. In some embodiments, the roughness of the sandblasted seed crystal is in a range of 20 μm to 60 μm. In some embodiments, the roughness of the sandblasted seed crystal is in a range of 25 μm to 55 μm. In some embodiments, the roughness of the sandblasted seed crystal is in a range of 30 μm to 50 μm. In some embodiments, the roughness of the sandblasted seed crystal is in a range of 35 μm to 45 μm. In some embodiments, the roughness of the sandblasted seed crystal is in a range of 38 μm to 42 μm.

By performing the sandblasting treatment on the back surface of the seed crystal, the back surface of the seed crystal can meet a certain degree of roughness, which is convenient for the subsequent coating of the back surface of the seed crystal and ensures a good coating effect that is less prone to fall off.

In step 620, performing heating pre-treatment on the seed crystal after the sandblasting treatment.

Due to the high temperature of the coating process, the heating pre-treatment can be performed on the seed crystal in advance to prevent issues such as crystal fracture caused by excessive thermal stress due to the large temperature difference between the seed crystal and a film material, or problems with poor adhesion of the coating due to differences in thermal expansion between the seed crystal and the film material.

In some embodiments, a temperature of the heating pre-treatment is in a range of 300° C. to 900° C. In some embodiments, the temperature of the heating pre-treatment is in a range of 400° C. to 800° C. In some embodiments, the temperature of the heating pre-treatment is in a range of 500° C. to 700° C. In some embodiments, the temperature of the heating pre-treatment is in a range of 600° C. to 650° C.

In step 630, coating the seed crystal with a film material after the heating pre-treatment.

In some embodiments, the film material is a substance that is high-temperature stable and chemically stable. In some embodiments, the film material includes one or more of W, Mo, N₂W, and TaC.

When the coating thickness is too large, the adhesion of the film material is poor and is easy to fall off; and when the coating thickness is too small, it is difficult to ensure uniformity of the coating, which affects the coating effect. Therefore, it is necessary to choose the appropriate coating thickness. In some embodiments, the coating thickness is in a range of 1 μm to 200 μm. In some embodiments, the coating thickness is in a range of 5 μm to 175 μm. In some embodiments, the coating thickness is in a range of 10 μm to 150 μm. In some embodiments, the coating thickness is in a range of 25 μm to 125 μm. In some embodiments, the coating thickness is in a range of 50 μm to 100 μm. In some embodiments, the coating thickness is in a range of 60 μm to 90 μm. In some embodiments, the coating thickness is in a range of 75 μm to 85 μm. In some embodiments, the coating thickness is in a range of 80 μm to 85 μm.

In some embodiments, a coating manner includes thermal evaporation, physical vapor deposition, chemical vapor deposition, electron beam evaporation, reaction sintering, plasma coating, molecular beam epitaxy, liquid phase epitaxy, laser deposition, or the like.

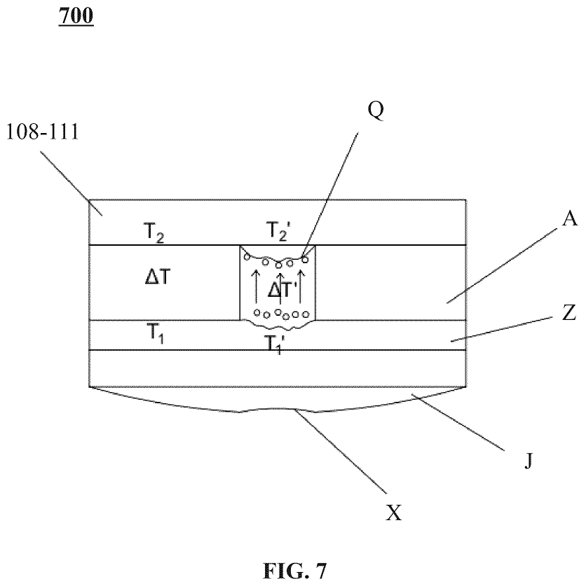

By coating the back surface of the seed crystal, the evaporation process of the back surface of the seed crystal during a process of growing a silicon carbide crystal can be suppressed, and the planar hexagonal defects due to the evaporation of the back surface of the seed crystal can be eliminated efficiently, which increases the quality and the yield of the crystal. Specifically, as shown in FIG. 7, Z denotes the seed crystal, 108-111 denotes the chamber lid, and the seed crystal Z is bonded to the chamber lid 108-111 through an adhesive A. Due to reasons such as poor machining precision of the surface of the chamber lid 108-111, uneven bonding of the adhesive A, and/or the physical and chemical properties of the adhesive A itself, there may be some porosities Q in an interface between the back surface of the seed crystal Z and the chamber lid 108-111. These porosities Q obstruct heat transfer, causing heat to accumulate at the porosities, which in turn leads to the evaporation of the back surface of the seed crystal and affects the subsequent growth of a crystal. For example, assuming that there are no porosities, the temperature at the chamber lid 108-111 is T₂, the temperature at the seed crystal Z is T₁, and a temperature difference between the two is ΔT. Such normal temperature difference does not result in the sublimation of the seed crystal Z. Due to the presence of the porosities Q, the heat transfer is obstructed, causing the heat to accumulate at the porosities Q, which in turn leads to the temperature at the chamber lid 108-111 to be T₂′ and the temperature at the seed crystal Z to be T₁′, where T₂′<T₂ and T₁′>T₁. Consequently, the temperature difference ΔT′ between the two is greater than the normal temperature difference ΔT, which leads to the evaporation of a back surface of the seed crystal Z. The evaporated vapor phase components condense at the porosities Q over time. Over time, due to the obstruction of heat transfer, the accumulation of heat leads to an interface temperature of T₁<T₁′, meaning that the temperature at the growth interface where the porosities Q is located is higher, with a smaller temperature gradient for crystal growth and a slower growth rate. As a result, the growth rate at the growth interface with porosities Q is lower than that at the surrounding growth interface without porosities Q. Since the growth rates at different locations on the same growth interface vary, this leads to the formation of crystal growth defects (such as dislocations, microtubes, or voids). Large areas of vacancy clusters (or porosity clusters) can even cause macroscopic interface depressions X at the crystal growth interface, which severely impacts the quality and yield of a crystal J. Therefore, by coating the back surface of the seed crystal, the hexagonal pores due to evaporation of the back surface during crystal growth can be eliminated, thereby improving the quality and yield of the silicon carbide crystal. In some embodiments, the chamber lid 108-111 can also be replaced with the seed crystal tray. In some embodiments, the seed crystal tray is an assembly that supports the seed crystal.

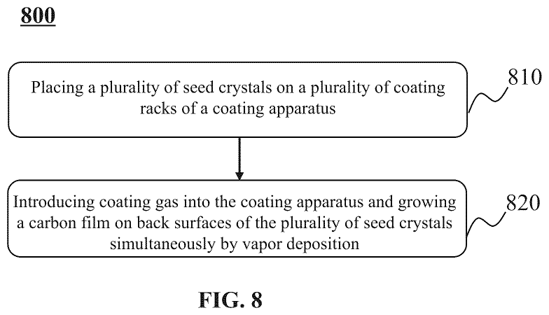

FIG. 8 is a flowchart illustrating a process of coating a seed crystal according to some embodiments of the present disclosure. In some embodiments, a process 800 is performed by a processing device (e.g., the processing device 101) and/or a control device (e.g., the control device 102). For example, the process 800 is stored in a storage device (e.g., a storage unit of a storage device, a processing device, and/or a control device) in the form of a program or instructions, and the process 800 is implemented when the processor 202 executes the program or instructions. In some embodiments, the process 800 is accomplished utilizing one or more additional operations not described below, and/or not by one or more operations discussed below. Additionally, the order of the operations as shown in FIG. 8 is not limiting.

In step 810, placing a plurality of seed crystals on a plurality of coating racks of a coating apparatus.

In some embodiments, a plurality of trays are arranged on the coating racks for placing the seed crystals. In some embodiments, the plurality of seed crystals are placed in the plurality of trays manually, respectively, the process is flexible, simple to equip, and less costly. In some embodiments, the seed crystals are placed on the corresponding trays by a robotic arm controlled by a processing device and/or a control device. In some embodiments, the robotic arm automatically picks up the seed crystals and places them on the corresponding trays according to a set program, which can reduce labor costs and enable precise and easy material handling.

In some embodiments, the plurality of coating racks are arranged within the coating apparatus. More descriptions regarding the coating apparatus can be found elsewhere in the present disclosure (e.g., FIG. 9 and its related description) and will not be repeated herein.

In step 820, introducing coating gas into the coating apparatus and growing a carbon film on back surfaces of the plurality of seed crystals simultaneously by vapor deposition.

In some embodiments, a layer of polyimide film (PI) is pre-applied to a non-coated surface, and the polyimide film is removed after the coating is completed, thereby preventing the non-coated surface from being coated. In some embodiments, the non-coated surface is tightly adhered to the tray by such as electrostatic adsorption, to prevent the non-coated surface from being coated.

In some embodiments, the coating gas includes methane or acetylene.

In some embodiments, a silicon carbide seed crystal is secured to a tray, and a chamber of the coating apparatus is subjected to air evacuation and maintained. In some embodiments, a pressure of the chamber of the coating apparatus after the air evacuation is in a range of 0.001 Pa to 100 Pa. In some embodiments, the pressure of the chamber of the coating apparatus after the air evacuation is in a range of 0.01 Pa to 95 Pa. In some embodiments, the pressure of the chamber of the coating apparatus after the air evacuation is in a range of 0.1 Pa to 90 Pa. In some embodiments, the pressure of the chamber of the coating apparatus after the air evacuation is in a range of 1 Pa to 85 Pa. In some embodiments, the pressure of the chamber of the coating apparatus after the air evacuation is in a range of 10 Pa to 80 Pa. In some embodiments, the pressure of the chamber of the coating apparatus after the air evacuation is in a range of 20 Pa to 75 Pa. In some embodiments, the pressure of the chamber of the coating apparatus after the air evacuation is in a range of 30 Pa to 70 Pa. In some embodiments, the pressure of the chamber of the coating apparatus after the air evacuation is in a range of 40 Pa to 60 Pa. In some embodiments, the pressure of the chamber of the coating apparatus after the air evacuation is in a range of 45 Pa to 55 Pa. In some embodiments, the pressure of the chamber of the coating apparatus after the air evacuation is in a range of 48 Pa to 52 Pa.

In some embodiments, the chamber of the coating apparatus is heated. In some embodiments, a temperature of a heating treatment is in a range of 200° C. to 1000° C. In some embodiments, the temperature of the heating is in a range of 300° C. to 900° C. In some embodiments, the temperature of the heating is in a range of 400° C. to 800° C. In some embodiments, the temperature of the heating is in a range of 500° C. to 700° C. In some embodiments, the temperature of the heating is in a range of 550° C. to 650° C. In some embodiments, the temperature of the heating is in a range of 580° C. to 620° C.

In some embodiments, inert gas is used as a carrier gas while reaction gas (or the coating gas) is introduced into the chamber of the coating apparatus for a certain period, and then the introduction of the reaction gas is stopped and a gas flow rate of the carrier gas is maintained constant.

In some embodiments, the inert gas is Ar or He. In some embodiments, a gas flow rate of the inert gas is in a range of 1 mL/min to 1000 mL/min. In some embodiments, the gas flow rate of the inert gas is in a range of 50 mL/min to 950 mL/min. In some embodiments, the gas flow rate of the inert gas is in a range of 100 mL/min to 900 mL/min. In some embodiments, the gas flow rate of the inert gas is in a range of 200 mL/min to 800 mL/min. In some embodiments, the gas flow rate of the inert gas is in a range of 300 mL/min to 700 mL/min. In some embodiments, the gas flow rate of the inert gas is in a range of 400 mL/min to 600 mL/min. In some embodiments, the gas flow rate of the inert gas is in a range of 450 mL/min to 550mL/min. In some embodiments, the gas flow rate of the inert gas is in a range of 480 mL/min to 520 mL/min.

In some embodiments, a gas flow rate of the reaction gas is in a range of 1 mL/min to 1000 mL/min. In some embodiments, the gas flow rate of the reaction gas is in a range of 50 mL/min to 950 mL/min. In some embodiments, the gas flow rate of the reaction gas is in a range of 100 mL/min to 900 mL/min. In some embodiments, the gas flow rate of the reaction gas is in a range of 200 mL/min to 800 mL/min. In some embodiments, the gas flow rate of the reaction gas is in a range of 300 mL/min to 700 mL/min. In some embodiments, the gas flow rate of the reaction gas is in a range of 400 mL/min to 600 mL/min. In some embodiments, the gas flow rate of the reaction gas is in a range of 450 mL/min to 550 mL/min. In some embodiments, the gas flow rate of the reaction gas is in a range of 480 mL/min to 520 mL/min.

In some embodiments, the period for introducing the reaction gas is in a range of 1 min to 30 min. In some embodiments, the period for introducing the reaction gas is in a range of 4 min to 27 min. In some embodiments, the period for introducing the reaction gas is in a range of 7 min to 24 min. In some embodiments, the period for introducing the reaction gas is in a range of 10 min to 21 min. In some embodiments, the period for introducing the reaction gas is in a range of 13 min to 18 min. In some embodiments, the period for introducing the reaction gas is in a range of 15 min to 16 min.

In some embodiments, the inert gas as the carrier gas may also be introduced before the introduction of the reaction gas until the pressure of the chamber of the coating apparatus reaches a pressure threshold. After maintaining the gas flow rate of the reaction gas for a certain period, the introduction of the reaction gas is stopped, while keeping the gas flow rate of the carrier gas constant.

In some embodiments, the pressure threshold is in a range of 0.01 MPa to 0.1 MPa. In some embodiments, the pressure threshold is in a range of 0.02 MPa to 0.09 MPa. In some embodiments, the pressure threshold is in a range of 0.03 MPa to 0.08 MPa. In some embodiments, the pressure threshold is in a range of 0.04 MPa to 0.07 MPa. In some embodiments, the pressure threshold is in a range of 0.05 MPa to 0.06 MPa.

In some embodiments, the chamber of the coating apparatus is cooled to room temperature after a coating reaction is completed. In some embodiments, to avoid defects or cracking in a grown carbon film, a cooling rate of the chamber can be controlled within a certain range to ensure it cools down to room temperature gradually. In some embodiments, the cooling rate to room temperature is in a range of 1° C./min to 50° C./min. In some embodiments, the cooling rate for cooling to room temperature is in a range of 5° C./min to 45° C./min. In some embodiments, the cooling rate for cooling to room temperature is in a range of 10° C./min to 40° C./min. In some embodiments, the cooling rate for cooling to room temperature is in a range of 15° C./min to 35° C./min. In some embodiments, the cooling rate for cooling to room temperature is in a range of 20° C./min to 30° C./min. In some embodiments, the cooling rate for cooling to room temperature may be in the range of 23° C./min to 27° C./min.

The thickness of the carbon film is affected by a reaction time, a reaction temperature, and a ratio of reaction gases. In some embodiments, the thickness of the carbon film is in a range of 0.1 to 100 μm by controlling the reaction time, the reaction temperature, and the ratio of the reaction gases. In some embodiments, the thickness of the carbon film is in a range of 10 to 90 μm. In some embodiments, the thickness of the carbon film is in a range of 20 to 80 μm. In some embodiments, the thickness of the carbon film is in a range of 30 to 70 μm. In some embodiments, the thickness of the carbon film is in a range of 40 to 60 μm. In some embodiments, the thickness of the carbon film is in a range of 45 to 55 μm.

The carbon film is grown on the back surfaces of a plurality of seed crystals simultaneously by vapor deposition, leading to a high coating efficiency and a better homogeneity of the coating, which in turn results in a better consistency of a grown crystal.

FIG. 9 is a schematic diagram illustrating an exemplary structure of a coating apparatus according to some embodiments of the present disclosure.

In some embodiments, as shown in FIG. 9, the coating apparatus 106 includes a coating chamber 106-1, a coating rack 106-2, a driving assembly (not shown in FIG. 9), an air evacuating assembly (not shown in FIG. 9), a heating assembly 106-3, an air inlet 106-4, and an air outlet 106-5.

In some embodiments, the coating chamber 106-1 is a site for coating a seed crystal. In some embodiments, the coating chamber 106-1 includes a tube 106-11 and two baffles 106-12 (not shown in the figures). In some embodiments, the two baffles 106-12 are sealingly connected to the left end and the right end of the tube 106-11, respectively. In some embodiments, the tube 106-11 is a quartz tube.

In some embodiments, the coating rack 106-2 is a rack made of a high-temperature resistant material. In some embodiments, a lower end of the coating rack 106-2 is rotationally connected to a base, and the base is fixedly connected to a bottom of the coating chamber 106-1. In some embodiments, a count of the coating rack 106-2 is one or more. In some embodiments, when the count of the coating rack 106-2 is a plurality, a plurality of coating racks 106-2 are staggeringly arranged on two sides of an inlet direction of the air inlet 106-4 such that coating gas can be evenly spread to each of the coating racks 106-2.

In some embodiments, a plurality of trays are arranged on the coating racks 106-2. In some embodiments, a tray is used to hold a seed crystal. In some embodiments, the plurality of trays are arranged in sequential layers, one above the other, on the coating rack 106-2. In some embodiments, the plurality of trays are arranged around a center axis of the coating rack 106-2 in each layer on the coating rack 106-2.

In some embodiments, the driving assembly is used to drive the coating rack 106-2 to rotate about the center axis. In some embodiments, the driving assembly includes an air blade. In some embodiments, the air blade is provided on a side surface of the coating rack 106-2, and when coating gas is introduced, the air blade rotates driven by the coating gas, thereby driving the coating rack 106-2 to rotate around the center axis.

In some embodiments, the air evacuating assembly is connected to the air outlet 106-5 for evacuating the coating chamber 106-1. In some embodiments, the air evacuating assembly is a vacuum device (e.g., a vacuum pump).

In some embodiments, the heating assembly 106-3 is disposed on an outer side of the tube 106-11 to provide the heat needed for coating the seed crystal. In some embodiments, an insulation cotton 106-7 is provided between the heating assembly 106-3 and the tube 106-11, such that the heat radiated by the heating assembly 106-3 uniformly heats the seed crystal on the tray of the coating rack 106-2. In some embodiments, the insulation cotton 106-7 includes an insulation material such as alumina, zirconia, or the like. In some embodiments, an insulation layer 106-8 is arranged on an outer side of the heating assembly 106-3 to insulate the coating apparatus 106.

In some embodiments, the air inlet 106-4 is arranged on the baffle 106-12 for introducing the coating gas into the coating chamber 106-1. In some embodiments, the air outlet 106-5 is arranged on another baffle 106-12 for venting air or the coating gas from the coating chamber 106-1. More descriptions regarding the coating gas can be found in the relevant description of FIG. 8 and will not be repeated herein.

In some embodiments, the coating apparatus 160 is not limited to the structure shown in FIG. 9 and may be structurally deformed from the coating apparatus 106 shown in FIG. 9.

In some embodiments, the coating chamber 106-1 is also a closed chamber made of a metallic material (e.g., stainless steel), for example, a cylindrical chamber or a rectangular chamber.

In some embodiments, the driving assembly includes a driving motor. In some embodiments, the lower end of the coating rack 106-2 is in a driven connection with the driving motor to rotate around the center axis driven by the driving motor.

In some embodiments, the heating assembly 106-3 is disposed inside the coating chamber 106-1 to provide heat required for coating the seed crystal. In some embodiments, the insulation layer 106-8 is disposed on the outer side of the coating chamber 106-1 to insulate the coating apparatus 106.

In some embodiments, the air inlet 106-4 is disposed on the coating chamber 106-1 for introducing the coating gas into the coating chamber 106-1. In some embodiments, the air outlet 106-5 is disposed on the coating chamber 106-1 for venting air or the coating gas from the coating chamber 106-1.

By arranging the plurality of coating racks staggeringly and rotating around the center axis of the plurality of coating racks driven by the driving assembly, it is possible to uniformly diffuse the coating gas to seed crystals when coating the seed crystals on the tray, thereby improving the thickness uniformity of the coating on the seed crystals.

FIG. 10 is a flowchart illustrating a process of bonding a seed crystal according to some embodiments of the present disclosure. In some embodiments, a process 100 is performed by a processing device (e.g., the processing device 101) and/or a control device (e.g., the control device 102). For example, the process 1000 is stored in a storage device (e.g., a storage unit of a storage device, a processing device, and/or a control device) in the form of a program or instruction, and the process 1000 is implemented when the processor 202 executes the program or instruction. In some embodiments, the process 1000 is accomplished utilizing one or more of the additional operations not described below, and/or not by one or more of the operations discussed below. Additionally, the order of the operations as shown in FIG. 10 is not limiting.

In step 1010, applying an adhesive (e.g., the adhesive A as shown in FIG. 11A or FIG. 12A) to a bottom surface of a chamber lid (e.g., the chamber lid 108-111 as shown in FIG. 11A or FIG. 12A) of a growth chamber.

In some embodiments, the adhesive (e.g., the adhesive A as shown in FIG. 11A or FIG. 12A) is also applied to a surface of a seed crystal tray. In some embodiments, the adhesive includes a liquid adhesive, an AB adhesive, a synthetic resin, a synthetic rubber, or the like.

In some embodiments, the adhesive is applied manually to the bottom surface of the chamber lid of the growth chamber or the surface of the seed crystal tray. By manually applying the adhesive, the process is flexible, simple, and less expensive. In some embodiments, a robotic arm is controlled to apply the adhesive to the bottom surface of the chamber lid of the growth chamber or the surface of the seed crystal tray by a processing device and/or a control device. In some embodiments, the robotic arm automatically applies the adhesive according to a set program. Applying the adhesive by the robotic arm can reduce labor costs, increase repeatability, and allow for precise and easy material handling. In some embodiments, the adhesive is applied to the bottom surface of the chamber lid of the growth chamber or the surface of the seed crystal tray by controlling a screeding machine, a spraying machine, a dispensing machine, or a scraping machine, etc., through the processing device and/or the control device. Applying the adhesive through the screeding machine, the spraying machine, the dispensing machine, or the scraping machine reduces the complexity of an application operation, increases repeatability, and allows for precise and easy material handling.

In step 1020, placing the chamber lid covered with the adhesive in a bonding apparatus (e.g., the apparatus 107 for bonding a seed crystal as shown in FIG. 11A or FIG. 12A).

In some embodiments, the seed crystal tray coated with the adhesive is also placed within the bonding apparatus (e.g., the apparatus 107 for bonding a seed crystal as shown in FIG. 11A or FIG. 12A). In some embodiments, the chamber lid covered with the adhesive or the seed crystal tray covered with the adhesive is placed in the bonding apparatus manually, which is a flexible, simple, and low-cost process. In some embodiments, the robotic arm is controlled to place the chamber lid covered with the adhesive or the seed crystal tray covered with the adhesive in the bonding apparatus by the processing device and/or the control device. In some embodiments, the robotic arm automatically places the chamber lid covered with the adhesive or the seed crystal tray covered with the adhesive according to a set program. Placing the chamber lid covered with the adhesive or the seed crystal tray covered with the adhesive by the robotic arm can reduce labor costs, improve automation, and be easy to operate.

In step 1030, evacuating air form the bonding apparatus.

In some embodiments, the pressure of the bonding apparatus after the air evacuation is in a range of 0.1 Pa to 10 Pa. In some embodiments, the pressure of the bonding apparatus after the air evacuation is in a range of 0.5 Pa to 10 Pa. In some embodiments, the pressure of the bonding apparatus after the air evacuation is in a range of 1 Pa to 9 Pa. In some embodiments, the pressure of the bonding apparatus after the air evacuation is in a range of 2 Pa to 8 Pa. In some embodiments, the pressure of the bonding apparatus after the air evacuation is in a range of 3 Pa to 7 Pa. In some embodiments, the pressure of the bonding apparatus after the air evacuation is in a range of 4 Pa to 6 Pa. In some embodiments, the pressure of the bonding apparatus after the air evacuation is in a range of 4.5 Pa to 5.5 Pa. In some embodiments, the pressure of the bonding apparatus after the air evacuation is in a range of 5.0 Pa to 5.2 Pa.

In some embodiments, the air evacuation on the bonding apparatus is performed by a vacuum device (e.g., a vacuum pump).

Through the air evacuation, a vacuum environment with little or no gas can be created, which is beneficial for the desorption of gases adsorbed inside the bonding apparatus, the chamber lid or the seed crystal tray, and the adhesive. This helps to eliminate or reduce bubbles within the adhesive, preventing defects such as microtubes and hexagonal voids from forming during subsequent crystal preparation, thereby improving the quality of the crystal.

In step 1040, applying pressure, through a pressing assembly (e.g., the pressing assembly 107-6 shown in FIG. 11A or FIG. 12A) to bond the seed crystal to the chamber lid.

In some embodiments, the seed crystal is also bonded to the seed crystal tray by the pressing assembly (e.g., the pressing assembly 107-6 shown in FIG. 11A or FIG. 12A). In some embodiments, the seed crystal is secured to a suction cup (e.g., a suction cup 107-61 as shown in FIG. 11A or FIG. 12A) of the pressing assembly by adsorption. In some embodiments, an adsorption manner includes high-temperature traceless adhesive bonding, electrostatic adsorption, etc., or any combination thereof.

In some embodiments, as shown in FIG. 11A and FIG. 11B, movement (e.g., up and down movement) of the pressing assembly is controlled by the processing device and/or the control device to bring the seed crystal into contact with the chamber lid or the seed crystal tray, and further pressure is applied to bond the seed crystal and the chamber lid or the seed crystal tray. In some embodiments, after the seed crystal is in contact with the chamber lid or the seed crystal tray, the processing device and/or the control device controls an ultrasonic detection apparatus (e.g., an ultrasonic flaw detector) to inspect the fit quality (e.g., porosity detection, i.e., the presence of porosities, the proportion of the area of the porosities) of the seed crystal and the chamber lid or the seed crystal tray, before applying a pressure to bond the seed crystal and the chamber lid or the seed crystal tray. In some embodiments, the fit quality is considered acceptable if there are no porosities or if the proportion of the area of the porosities is less than a proportion threshold (e.g., less than 2%); otherwise, the fit quality is considered unacceptable. In some embodiments, if the fit quality is acceptable, the movement of the pressing assembly can be controlled by the processing device and/or the control device to apply pressure to bond the seed crystal to the chamber lid or the seed crystal tray. In some embodiments, if the fit quality is unacceptable, the pressing assembly is controlled by the processing device and/or the control device to move along an opposite direction to re-bond the seed crystal to the chamber lid or the seed crystal tray, and the fit quality is tested again until the fit quality is acceptable. More descriptions regarding the porosity detection can be found in the description of step 320, which will not be repeated herein.

In some embodiments, a buffer layer is also provided between the seed crystal and the chamber lid or the seed crystal tray. In some embodiments, as shown in FIG. 12A and FIG. 12B, the adhesive is applied to a top surface of the buffer layer and/or a bottom surface of the seed crystal, the buffer layer is snapped and placed underneath the seed crystal, and the chamber lid or the seed crystal tray covered with the adhesive is placed within the bonding apparatus. In some embodiments, movement (e.g., up and down) of the pressing assembly can be controlled by the processing device and/or the control device to bring the seed crystal and the buffer layer (e.g., a buffer layer H shown in FIG. 12A and FIG. 12B) into contact with the chamber lid, and further pressure can be applied to bond the seed crystal, the buffer layer, and the chamber lid together. In some embodiments, after the seed crystal and the buffer layer are in contact with the chamber lid, before applying the pressure for a bonding operation, the fit quality (e.g., the presence of porosities, the proportion of the area of porosities) of the seed crystal and the buffer layer and the fit quality of the buffer layer and the chamber lid are inspected using the ultrasonic detection apparatus (e.g., the ultrasonic flaw detector) controlled by the processing device and/or the control device. In some embodiments, if the fit quality is considered acceptable, the movement of the pressing assembly can be controlled by the processing device and/or the control device to apply pressure to bond the seed crystal, the buffer layer, and the chamber lid. In some embodiments, if the fit quality is considered unacceptable, the pressing assembly is controlled by the processing device and/or the control device to move along the opposite direction to re-bond the seed crystal and the buffer layer with the chamber lid, and the fit quality of the fit is tested again until the fit quality is considered acceptable. In some embodiments, the chamber lid shown in FIG. 12A and FIG. 12B may also be the seed crystal tray. More descriptions regarding the porosity detection can be found in the description of step 320, which will not be repeated herein.

In some embodiments, both the air evacuation and heating can be performed during the bonding process or the pressing process.

In some embodiments, the applied pressure of the pressing assembly is in a range of 0.01 MPa to 1.5 MPa. In some embodiments, the applied pressure of the pressing assembly is in a range of 0.1 MPa to 1.5 MPa. In some embodiments, the applied pressure of the pressing assembly is in a range of 0.2 MPa to 1.4 MPa. In some embodiments, the applied pressure of the pressing assembly is in a range of 0.3 MPa to 1.3 MPa. In some embodiments, the applied pressure of the pressing assembly is in a range of 0.4 MPa to 1.2 MPa. In some embodiments, the applied pressure of the pressing assembly is in a range of 0.5 MPa to 1.1 MPa. In some embodiments, the applied pressure of the pressing assembly is in a range of 0.6 MPa to 1.0 MPa. In some embodiments, the applied pressure of the pressing assembly is in a range of 0.7 MPa to 0.9 MPa. In some embodiments, the applied pressure of the pressing assembly is in a range of 0.75 MPa to 0.85 MPa.

In some embodiments, the pressure of the bonding apparatus after the air evacuation is in a range of 0.1 Pa to 10 Pa. In some embodiments, the pressure of the bonding apparatus after the air evacuation is in a range of 0.5 Pa to 9.5 Pa. In some embodiments, the pressure of the bonding apparatus after the air evacuation is in a range of 1 Pa to 9 Pa. In some embodiments, the pressure of the bonding apparatus after the air evacuation is in a range of 1.5 Pa to 8.5 Pa. In some embodiments, the pressure of the bonding apparatus after the air evacuation is in a range of 2 Pa to 8 Pa. In some embodiments, the pressure of the bonding apparatus after the air evacuation is in a range of 2.5 Pa to 7.5 Pa. In some embodiments, the pressure of the bonding apparatus after the air evacuation is in a range of 3 Pa to 7 Pa. In some embodiments, the pressure of the bonding apparatus after the air evacuation is in a range of 3.5 Pa to 6.5 Pa. In some embodiments, the pressure of the bonding apparatus after the air evacuation is in a range of 4 Pa to 6 Pa. In some embodiments, the pressure of the bonding apparatus after the air evacuation is in a range of 4.5 Pa to 5.5 Pa.

In some embodiments, if the temperature of the heating is too low, the adhesive is not yet cured or carbonized; and if the temperature of the heating is too high, the viscosity of the adhesive is lower. Therefore, it is necessary to set a suitable range of the temperature of the heating. In some embodiments, the temperature of the heating is in a range of 200° C. to 1200° C. In some embodiments, the temperature of the heating is in a range of 300° C. to 1100° C. In some embodiments, the temperature of the heating is in a range of 400° C. to 1000° C. In some embodiments, the temperature of the heating is in a range of 500° C. to 900° C. In some embodiments, the temperature of the heating is in a range of 600° C. to 800° C. In some embodiments, the temperature of the heating is in a range of 650° C. to 750° C. In some embodiments, the temperature of the heating is in a range of 680° C. to 720° C.

In some embodiments, the time of the heating is in a range of 1 min to 600 min. In some embodiments, the time of the heating is in a range of 50 min to 600 min. In some embodiments, the time of the heating is in a range of 100 min to 550 min. In some embodiments, the time of the heating is in a range of 150 min to 500 min. In some embodiments, the time of the heating is in a range of 200 min to 450 min. In some embodiments, the time of the heating is in a range of 250 min to 400 min. In some embodiments, the time of the heating is in a range of 300 min to 350 min.

Through the air evacuation to remove the porosities inside the adhesive, it ensures that most of the porosities are eliminated before bonding. Further air evacuation and heating can be applied when pressing the seed crystal, which helps to prevent the formation of new porosities during the bonding process. At the same time, the heating ensures the adhesive's bonding strength, thereby improving the bonding effectiveness, preventing defects such as microtubes and hexagonal voids during subsequent crystal growth, and enhancing the quality of the crystal.

FIG. 11A is a schematic diagram illustrating an exemplary structure of an apparatus for bonding a seed crystal according to some embodiments of the present disclosure. FIG. 11B is a schematic diagram illustrating a seed crystal after bonding according to some embodiments of the present disclosure. In FIG. 11A and FIG. 11B, A denotes an adhesive and Z denotes a seed crystal.

In some embodiments, as shown in FIG. 11A and FIG. 11B, the apparatus 107 for bonding a seed crystal includes a bonding chamber 107-1, a vacuum assembly 107-2, an upper transmission assembly 107-3, a lower transmission assembly 107-4, a heating assembly 107-5, and a pressing assembly 107-6.

The bonding chamber 107-1 may be a site for bonding the seed crystal. The vacuum assembly 107-2 may be used to vacuum the bonding chamber 107-1. The upper transmission assembly 107-3 may be connected to the top of the bonding chamber 107-1. The lower transmission assembly 107-4 may be connected to a bottom end of the bonding chamber 107-1. The heating assembly 107-5 may be used to provide the heat required for bonding the seed crystal. The pressing assembly 107-6 may apply pressure to bond the seed crystal Z to the chamber lid 108-111.

In some embodiments, the pressing assembly 107-6 includes the suction cup 107-61 and a support table 107-62. In some embodiments, an upper end of the suction cup 107-61 is connected to the top of the bonding chamber 107-1 through the upper transmission assembly 107-3. In some embodiments, a lower end of the support table 107-62 is connected to the bottom end of the bonding chamber 107-1 through the lower transmission assembly 107-4. In some embodiments, a lower end of the suction cup 107-61 is configured to adsorb the seed crystal Z. In some embodiments, an upper end of the support table 107-62 is configured to place the chamber lid 108-111. In some embodiments, a top surface of the chamber lid 108-111 and/or a bottom surface of the seed crystal Z are covered with the adhesive A.

In some embodiments, the pressing assembly 107-6 bonds the seed crystal Z to the chamber lid 108-111 by acting in association with the upper transmission assembly 107-3, the lower transmission assembly 107-4, and the heating assembly 107-5. In some embodiments, the pressure required for bonding the seed crystal can be provided by the movement of the upper transmission assembly 107-3 and/or the lower transmission assembly 107-4. In some embodiments, the suction cup 107-61 drives the seed crystal Z to move downward through the movement of the upper transmission assembly 107-3, while the support table 107-62 drives the chamber lid 108-111 to move upward through the movement of the lower transmission assembly 107-4, and when the seed crystal Z comes into contact with the adhesive A on the chamber lid 108-111, the upper transmission assembly 107-3 and/or the lower transmission assembly 107-4 continue to move to provide the pressure required for bonding the seed crystal, thereby bonding the seed crystal Z to the chamber lid 108-111.

In some embodiments, the apparatus 107 for bonding a seed crystal further includes the pressure sensing assembly 107-7. In some embodiments, the pressure sensing assembly 107-7 is located in the upper transmission assembly 107-3 and/or the lower transmission assembly 107-4. In some embodiments, the pressure sensing assembly 107-7 is configured to monitor the applied pressure of the pressing assembly 107-6 and adjust the applied pressure accordingly. In some embodiments, with less pressure on the suction cup 107-61 and the support table 107-62 in the pressing assembly 107-6, the upper transmission assembly 107-3 may be lowered and/or the lower transmission assembly may be raised 107-4 to increase the applied pressure; otherwise, the upper transmission assembly 107-3 may be raised and/or the lower transmission assembly 107-4 may be lowered to decrease the applied pressure. The pressure sensing assembly 107-7 is located in the upper transmission assembly 107-3 and/or the lower transmission assembly 107-4 and moves together along the upper transmission assembly 107-3 and/or the lower transmission assembly 107-4.

In some embodiments, the seed crystal Z is adsorbed on a bottom surface of the suction cup 107-61, the chamber lid 108-111 is placed on top of the support table 107-62, the seed crystal Z and the chamber lid 108-111 are concentric and non-contacting along a vertical direction, and the adhesive A is applied on the bottom surface of the seed crystal Z and/or on the top surface of the chamber lid (above the chamber lid 108-111 in FIG. 11A). Through the movement of the upper transmission assembly 107-3, the seed crystal Z on the suction cup 107-61 is driven to move downward, and through the movement of the lower transmission assembly 107-4, the chamber lid 108-111 on the support table 107-62 is driven to move upward. When the seed crystal Z comes into contact with the adhesive A on the chamber lid 108-111, the upper transmission assembly 107-3 and/or lower transmission assembly 107-4 continue to move to apply the pressure required to bond the seed crystal. During the process of bonding the seed crystal, the pressure applied by the pressing assembly 107-6 is monitored by the pressure sensing assembly 107-7, while maintaining the bonding chamber sealed and in a vacuum state.

FIG. 12A is a schematic diagram illustrating an exemplary structure of an apparatus for bonding a seed crystal according to some embodiments of the present disclosure. FIG. 12 B is a schematic diagram illustrating bonding a seed crystal according to some embodiments of the present disclosure, where A denotes an adhesive, Z denotes a seed crystal, and H denotes a buffer layer.

FIG. 12A is similar in structure to the apparatus for bonding a seed crystal shown in FIG. 11A, and more descriptions regarding the bonding chamber 107-1, the vacuum assembly 107-2, the upper transmission assembly 107-3, the lower transmission assembly 107-4, the heating assembly 107-5, the pressing assembly 107-6, and the pressure sensing assembly 107-7 can be found elsewhere in the present disclosure (e.g., FIG. 11A and its related descriptions), and will not be repeated herein.

In some embodiments, the apparatus 107 for bonding a seed crystal further includes a support assembly 107-8, as shown in FIG. 12A. In some embodiments, the support assembly 107-8 includes two L-shaped brackets, which are symmetrically disposed on two sides of the suction cup 107-61 to snap and place the buffer layer H underneath the seed crystal Z.

In some embodiments, the buffer layer H is a material that cushions the bonding between the seed crystal Z and the chamber lid 108-111. In some embodiments, the buffer layer H includes a flexible carbon-based material. For example, the buffer layer H includes a flat flexible carbon-based material with a uniform thickness, such as graphite paper, carbon fiber, or graphene.

Since the buffer layer is a flexible material with a certain amount of deformation, the machining error of the plane of the chamber lid and a back surface of the seed crystal can be matched by placing the buffer layer between the seed crystal and the chamber lid. At the same time, since the buffer layer is denser than the chamber lid made of graphite, it can avoid the penetration of the adhesive, so that the quality of the bonding between the buffer layer and the seed crystal will be superior to the quality of the direct bonding between the seed crystal and the chamber lid made of graphite.

In some embodiments, by placing the buffer layer H above the support assembly 107-8, enabling the seed crystal Z to absorb on a bottom surface of the suction cup 107-61, and placing the chamber lid 108-111 on a top surface of the support table 107-62, the seed crystal Z, the buffer layer H, the chamber lid 108-111 are set concentrically and non-contacting along a vertical direction in sequence. The adhesive A is applied to the bottom surface of the seed crystal Z and/or the top surface of the buffer layer H, as well as to the bottom surface of the buffer layer H and/or above the chamber lid. The movement of the upper transmission assembly 107-3 drives the seed crystal Z on the suction cup 107-61 to move downward, while the movement of the lower transmission assembly 107-4 drives the chamber lid 108-111 on the support platform 107-62 to move upward. When the seed crystal Z comes into contact with the buffer layer H, it is bonded via the adhesive A on the top surface of the buffer layer H. The downward and upward movements of the chamber lid 108-111 cause bonding via the adhesive A above the chamber lid. Continued movement of the upper transmission assembly 107-3 and/or the lower transmission assembly 107-4 provides the necessary pressure for bonding the seed crystal. During the process of bonding the seed crystal, the applied pressure of the pressing assembly 107-6 is monitored by the pressure sensing assembly 107-7, while maintaining the sealing and vacuum state of the chamber cavity after bonding, ensuring that the seed crystal Z, the buffer layer H, and the chamber lid 108-111 are sequentially bonded along the vertical direction.

In some embodiments, the buffer layer H (e.g., graphite paper) and the adhesive A are also processed to be integrally molded to form a solid adhesive. In some embodiments, during the process of bonding the seed crystal, the integrally molded buffer layer H and the adhesive A are placed above the support assembly 107-8, the seed crystal Z is adsorbed on the bottom surface of the suction cup 107-61, and the chamber lid 108-111 is placed on the top surface of the support table 107-62. The seed crystal Z is bonded to the chamber lid 108-111 through the movement of the upper transmission assembly 107-3 and the lower transmission assembly 107-4 using the integrally molded buffer layer H and the adhesive A, as described above. The pressure applied by the pressing assembly 107-6 is monitored by the pressure sensing assembly 107-7 during the process of bonding the seed crystal, and the bonding chamber is maintained sealed and vacuumed, causing the seed crystal Z, the buffer layer H, and the chamber lid 108-111 to be sequentially bonded along the vertical direction.

By processing the buffer layer H and the adhesive A to be integrally molded, issues such as uneven spreading of the liquid adhesive or the formation of porosities during the spreading process can be avoided. This improves the bonding quality of a seed crystal, thereby preventing defects like microtubes and hexagonal voids in a silicon carbide crystal caused by porosities during the process of growing the crystal.

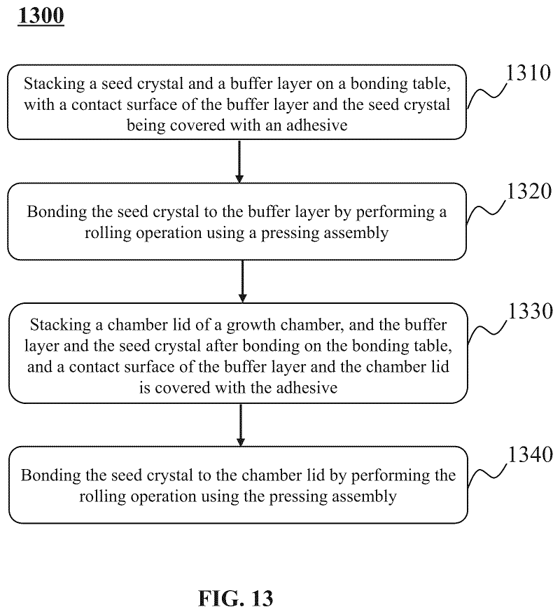

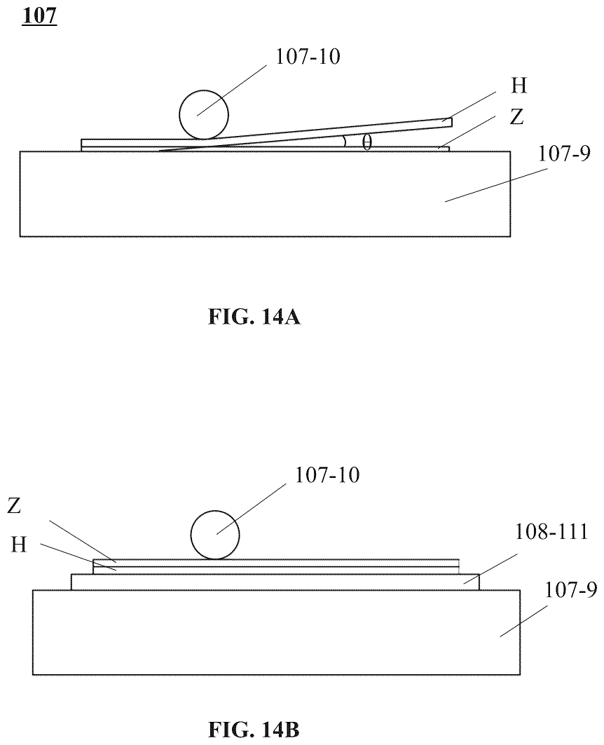

FIG. 13 is a flowchart illustrating a process of bonding a seed crystal according to some embodiments of the present disclosure. FIG. 14A is a schematic diagram illustrating an exemplary rolling operation according to some embodiments of the present disclosure. FIG. 14B is a schematic diagram illustrating an exemplary rolling operation according to some embodiments of the present disclosure. In some embodiments, a process 1300 is performed by a processing device (e.g., the processing device 101) and/or a control device (e.g., the control device 102). For example, the process 1300 is stored in a storage device (e.g., a storage unit of a storage device, a processing device, and/or a control device) in the form of a program or instruction, and the process 1300 may be implemented when the processor 202 executes the program or instruction. In some embodiments, the process 1300 is accomplished utilizing one or more of the additional operations not described below, and/or not by one or more of the operations discussed below. Additionally, the order of the operations as shown in FIG. 13 is not limiting.

In step 1310, stacking a seed crystal and a buffer layer on a bonding table.

In some embodiments, a contact surface of the buffer layer and the seed crystal is covered with an adhesive. In some embodiments, a bottom surface of the buffer layer and a top surface of the seed crystal are in contact. Accordingly, the bottom surface of the buffer layer and/or the top surface of the seed crystal are covered with the adhesive. In some embodiments, a top surface of the buffer layer and a bottom surface of the seed crystal are in contact. Accordingly, the top surface of the buffer layer and/or the bottom surface of the seed crystal are covered with the adhesive.

In some embodiments, a dimension of the buffer layer is set as desired. In some embodiments, the dimension of the buffer layer is greater than or equal to a dimension of the seed crystal. More descriptions regarding the buffer layer can be found elsewhere in the present disclosure (e.g., FIG. 12A, FIG. 12B, and their related descriptions) and will not be repeated herein. In some embodiments, the bonding table is any platform for placing the seed crystal at a level that meets the requirements.

In some embodiments, the buffer layer and the seed crystal are stacked on the bonding table manually. By manually placing the buffer layer and the seed crystal, the process is flexible, simple, and less expensive. In some embodiments, a robotic arm is controlled to place the buffer layer and the seed crystal on the bonding table by a processing device and/or a control device. In some embodiments, the robotic arm automatically places the buffer layer and the seed crystal according to a set program. Placing the buffer layer or the seed crystal covered with the adhesive by the robotic arm is highly automatic and easy to manipulate with reduced costs.

In some embodiments, the adhesive is applied to the contact surface of the buffer layer and/or the seed crystal manually. By manually applying the adhesive, the process is flexible, simple, and less expensive. In some embodiments, the robotic arm is controlled to apply the adhesive to the contact surface of the buffer layer and/or the seed crystal by the processing device and/or the control device. In some embodiments, the robotic arm automatically applies the adhesive according to a set program. Applying the adhesive by the robotic arm reduces labor costs, is highly repeatable, and is precise and easy to manipulate.

In step 1320, bonding the seed crystal to the buffer layer by performing a rolling operation using a pressing assembly.

In some embodiments, the pressing assembly includes a pressure roller. In some embodiments, the seed crystal is bonded to the buffer layer through the rolling operation performed by the pressure roller. In some embodiments, as shown in FIG. 14A, the buffer layer H and the seed crystal Z are stacked on the bonding table 107-9, with the seed crystal Z and the buffer layer H concentrically disposed along a vertical direction and the contact surface of the buffer layer H and the seed crystal Z being covered with the adhesive. The buffer layer H is subjected to a rolling operation by the pressure roller 107-10 to bond the seed crystal Z to the buffer layer H.

In some embodiments, during the rolling process, a first angle (e.g., an angle θ in FIG. 14A) between the buffer layer and an uncontacted portion of the seed crystal, a first pressure exerted by the pressure roller, and/or a first speed of the movement of the pressure roller need to satisfy certain requirements to make the seed crystal and the buffer layer bond tightly after the rolling operation is completed.

In some embodiments, the first angle is in a range of 0.1° to 15°. In some embodiments, the first angle is in a range of 1° to 14°. In some embodiments, the first angle is in a range of 2° to 13°. In some embodiments, the first angle is in a range of 3° to 12°. In some embodiments, the first angle is in a range of 4° to 11°. In some embodiments, the first angle is in a range of 5° to 10°. In some embodiments, the first angle is in a range of 6° to 9°. In some embodiments, the first angle is in a range of 7° to 8°.

In some embodiments, the first pressure is in a range of 0.1 kPa to 25 kPa. In some embodiments, the first pressure is in a range of 2 kPa to 23 kPa. In some embodiments, the first pressure is in a range of 4 kPa to 21 kPa. In some embodiments, the first pressure is in a range of 6 kPa to 19 kPa. In some embodiments, the first pressure is in a range of 8 kPa to 17 kPa. In some embodiments, the first pressure is in a range of 10 kPa to 15 kPa. In some embodiments, the first pressure is in a range of 12 kPa to 13 kPa.

In some embodiments, the first speed is in a range of 0.1 mm/s to 60 mm/s. In some embodiments, the first speed is in a range of 5 mm/s to 55 mm/s. In some embodiments, the first speed is in a range of 10 mm/s to 50 mm/s. In some embodiments, the first speed is in a range of 15 mm/s to 45 mm/s. In some embodiments, the first speed is in a range of 20 mm/s to 40 mm/s. In some embodiments, the first speed is in a range of 25 mm/s to 35 mm/s. In some embodiments, the first speed is in a range of 27 mm/s to 33 mm/s. In some embodiments, the first speed is in a range of 29 mm/s to 31 mm/s.

In step 1330, stacking a chamber lid of a growth chamber, and the buffer layer and the seed crystal after bonding on the bonding table, the buffer layer being located between the chamber lid and the seed crystal.

In some embodiments, a contact surface of the buffer layer and the chamber lid is covered with the adhesive. In some embodiments, the bottom surface of the buffer layer and a top surface of the chamber lid are in contact. In some embodiments, the top surface of the buffer layer and a bottom surface of the chamber lid are in contact.

In some embodiments, the chamber lid of the growth chamber, and the buffer layer and the seed crystal after bonding, are stacked on the bonding table manually, which is flexible, simple, and low-cost. In some embodiments, the robotic arm is controlled by the processing device and/or the control device to place the chamber lid of the growth chamber, and the buffer layer and the seed crystal after bonding on the bonding table. In some embodiments, the robotic arm automatically places the chamber lid of the growth chamber, and the buffer layer and the seed crystal after bonding according to a set program. Placing the chamber lid covered with the adhesive by the robotic arm can reduce labor costs, enhance automation, and improve ease of operation.

In some embodiments, the adhesive is applied to the contact surface of the buffer layer and the chamber lid manually. By manually applying the adhesive, the process is flexible, simple, and less expensive. In some embodiments, the robotic arm is controlled to apply the adhesive to the contact surface of the buffer layer and the chamber lid by the processing device and/or the control device. In some embodiments, the robotic arm automatically applies the adhesive according to a set program. Applying the adhesive by the robotic arm can reduce labor costs, increase repeatability, and provide precision with ease of operation.

In step 1340, bonding the seed crystal to the chamber lid by performing the rolling operation using the pressing assembly.

In some embodiments, the seed crystal is bonded to the chamber lid through the rolling operation on the seed crystal performed by the pressure roller to bond the buffer layer after being bonded with the seed crystal to the chamber lid. In some embodiments, as shown in FIG. 14B, the chamber lid 108-111 of the growth chamber, the buffer layer H and the seed crystal Z after bonding are stacked sequentially on the bonding table 107-9, the chamber lid 108-111, the buffer layer H and the seed crystal Z after bonding are concentrically disposed along the vertical direction. The contact surface of the buffer layer H and/or the chamber lid 108-111 is covered with the adhesive, and the rolling operation is performed on the seed crystal Z by the pressure roller 107-10 to bond the seed crystal Z to the chamber lid 108-111. In some embodiments, during the rolling process, to make the chamber lid and the buffer layer bond tightly after the rolling operation is completed, an angle between the chamber lid and an uncontacted portion between the buffer layer and the chamber lid is defined as a second angle, a pressure applied by the pressure roller is defined as a second pressure, and a movement speed of the pressure roller is defined as a second speed until the rolling operation is completed.

In some embodiments, the second angle is in a range of 0.01° to 0.2°. In some embodiments, the second angle is in a range of 0.03° to 0.18°. In some embodiments, the second angle is in a range of 0.05° to 0.16°. In some embodiments, the second angle is in a range of 0.07° to 0.14°. In some embodiments, the second angle is in a range of 0.09° to 0.12°. In some embodiments, the second angle is in a range of 0.11° to 0.10°. In some embodiments, the second angle is in a range of 0.7° to 0.9°. By setting the second angle in a certain range, it can be ensured that the seed crystal is within a small safe deformation range to evacuate porosities in the adhesive.

In some embodiments, the second pressure may be the same as or close to the first pressure. In some embodiments, the second speed may be the same as or close to the first speed. More descriptions regarding the first pressure and the first speed can be found elsewhere in the present disclosure (e.g., step 1320, FIG. 14A, and their related descriptions) and will not be repeated herein. In some embodiments, the second pressure may be different from the first pressure. In some embodiments, the second speed may be different from the first speed.

Through the rolling operation and by controlling the first angle and/or the second angle, the first pressure and/or the second pressure, and the first speed and/or the second speed during the rolling process, porosities in the adhesive can be sufficiently squeezed to be eliminated and new porosities can be prevented from generation, thereby avoiding defects such as microtubes and hexagonal voids in the grown silicon carbide crystal and improving the quality of the silicon carbide crystal.

In some embodiments, the seed crystal is bonded directly to the chamber lid without the buffer layer between the seed crystal and the chamber lid, i.e., step 1310 and step 1320 can be omitted. In some embodiments, the chamber lid of the growth chamber and the seed crystal are stacked on the bonding table, with the adhesive covered between the chamber lid and the seed crystal. In some embodiments, the seed crystal is bonded to the chamber lid through the rolling operation performed by the pressing assembly. More descriptions regarding the rolling operation can be found in the preceding description and will not be repeated herein.

FIG. 15 is a flowchart illustrating a process of a crystal growth method according to some embodiments of the present disclosure. In some embodiments, a process 1500 is performed by a processing device (e.g., the processing device 101) and/or a control device (e.g., the control device 102). For example, the process 1500 is stored in a storage device (e.g., a storage unit of a storage device, a processing device, and/or a control device) in the form of a program or instruction, and the process 1500 may be implemented when the processor 202 executes the program or instruction. In some embodiments, the process 1500 is accomplished utilizing one or more additional operations not described below, and/or not by one or more operations discussed below. Additionally, the order of the operations as shown in FIG. 15 is not limiting.

In step 1510, heating a material zone using a first heating assembly (e.g., the first heating assembly 108-31 shown in FIG. 16A, the first heating assembly 108-31 shown in FIG. 16B, and the first heating assembly 108-31 shown in FIG. 16C) to sublimate a feedstock into a vapor phase component required for growing a crystal.

In some embodiments, the first heating assembly provides the desired heat to the material zone. In some embodiments, the first heating assembly is located underneath the material zone or on a periphery of a chamber where the material zone is located.

In some embodiments, the first heating assembly includes an induction heating assembly. In some embodiments, the induction heating assembly includes an electromagnetic induction coil, an intermediate frequency power supply, or the like. In some embodiments, the first heating assembly includes a resistance heating assembly. In some embodiments, the resistance heating assembly includes high-resistance graphite, molybdenum silicon rods (MoSi₂), nickel-chromium wires (Ni—Cr), iron chromium aluminum wires (Fe—Cr—Al), nickel-iron wires (Ni—Fe), nickel-copper wires (Ni—Cu), silicon carbide rods (SiC), or the like.

In some embodiments, in the case of preparing a silicon carbide crystal, for example, a vapor phase component includes vapor phase components such as Si, Si₂C, SiC₂, or the like.

In step 1520, heating a vicinity of a partition using a second heating assembly (e.g., the second heating assembly 108-32 shown in FIG. 16A, the second heating assembly 108-32 shown in FIG. 16B, the second heating assembly 108-32 shown in FIG. 16C) to maintain a discharge rate of the vapor phase component via at least one outlet.

In some embodiments, the second heating assembly is located on a side of the partition for heating the vicinity of the partition to maintain the discharge rate of the vapor phase component via the at least one outlet. In some embodiments, the vicinity of the partition refers to a region of a preset range (e.g., 1 mm, 5 mm, 10 mm, etc.) upward or downward along where the partition is located.

In some embodiments, the second heating assembly includes an induction heating assembly. In some embodiments, the induction heating assembly includes an electromagnetic induction coil, an intermediate frequency power supply, or the like. In some embodiments, the second heating assembly includes a resistance heating assembly. In some embodiments, the resistance heating assembly includes high-resistance graphite, molybdenum silicon rods (MoSi₂), nickel-chromium wires (Ni—Cr), iron chromium aluminum wires (Fe—Cr—Al), nickel-iron wires (Ni—Fe), nickel-copper wires (Ni—Cu), silicon carbide rods (SiC), or the like.

In some embodiments, types of the first heating assembly and the second heating assembly may be the same or different.

In some embodiments, the discharge rate refers to a total amount of vapor phase components passing through the outlet per unit time. In some embodiments, the discharge rate reflects how quickly or slowly the vapor phase component passes through the outlet.

Heating the vicinity of the partition using the second heating assembly maintains the discharge rate of the vapor phase component via the outlet, thereby maintaining the stable growth of a crystal growth surface, significantly reducing the probability of dislocation, decreasing the crystalline defects, and improving the quality of the grown crystal. In step 1530, heating a growth zone using a third heating assembly (e.g., the third heating assembly 108-33 shown in FIG. 16A, the third heating assembly 108-33 shown in FIG. 16B, the third heating assembly 108-33 shown in FIG. 16C).

In some embodiments, the third heating assembly provides the heat required for growing the crystal. In some embodiments, the third heating assembly is segmented or individually controlled assembly. In some embodiments, the third heating assembly includes a plurality of sub-heating assemblies. In some embodiments, the plurality of sub-heating assemblies are located around the top of the growth zone at different radial diameters. In some embodiments, heating parameter of the plurality of sub-heating assemblies are separately and independently controlled for independent control of temperatures at different radial diameters. For example, if a localized radial temperature gradient increases, the localized radial temperature gradient is reduced by individually controlling the heating parameter of the plurality of sub-heating assemblies. In some embodiments, the plurality of sub-heating assemblies are a plurality of annular heating resistance components, which gradually decrease in dimension along a radial direction, and the annular heating resistance components are connected in parallel to form the third heating assembly. In some embodiments, the plurality of annular heating resistance components are controlled independently and separately based on the radial temperature gradient, ensuring that the radial temperature gradient is below a preset gradient threshold, thereby reducing thermal stress in the crystal and preventing cracking, leading to growing a high-quality crystal. In some embodiments, the third heating assembly is located above the chamber lid or on the periphery of the chamber where the chamber lid is located.

In some embodiments, the plurality of sub-heating assemblies are located around the periphery of the growth zone at different axial heights. In some embodiments, the heating parameter of the plurality of sub-heating assemblies are controlled separately and independently of each other to achieve independent control of temperatures at different axial heights. For example, if a localized axial temperature gradient increases, the localized axial temperature gradient is decreased by individually controlling the heating parameter of the plurality of sub-heating assemblies. In some embodiments, the plurality of sub-heating assemblies are a plurality of annular induction coils arranged at different axial heights, with the annular induction coils connected in parallel to form the third heating assembly. In some embodiments, the plurality of annular induction coils are independently controlled according to an axial temperature gradient, respectively, so that the axial temperature gradient is less than the preset gradient threshold value, thereby reducing thermal stress in the crystal and preventing cracking, leading to growing the high-quality crystal.

In some embodiments, the third heating assembly includes an induction heating assembly. In some embodiments, the induction heating assembly includes an electromagnetic induction coil, a magnetically conductive object, or the like. In some embodiments, the third heating assembly includes a resistance heating assembly. In some embodiments, the resistance heating assembly includes high-resistance graphite, molybdenum silicon rods (MoSi₂), nickel-chromium wires (Ni—Cr), iron chromium aluminum wires (Fe—Cr—Al), nickel-iron wires (Ni—Fe), nickel-copper wires (Ni—Cu), silicon carbide rods (SiC), or the like.

In some embodiments, heating types of the first heating assembly, the second heating assembly, and/or the third heating assembly may be the same or different.

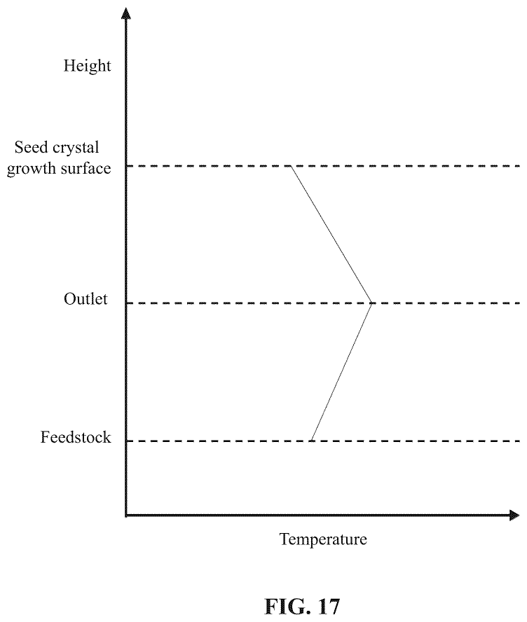

In some embodiments, a temperature in the vicinity of the partition is higher than the temperature of the material zone (or referred to as the “a temperature at the feedstock”) and/or the temperature of the growth zone (or referred to as the “a temperature at a seed crystal”), i.e., the temperature in the vicinity of the partition is >the temperature of the material zone and/or the temperature of the growth zone. Correspondingly, a bi-directional temperature gradient with a high-temperature zone at the partition and a low-temperature zone at the material zone and the growth zone may be formed within a growth chamber. For example, as shown in FIG. 17, a temperature distribution within the growth chamber is highest at an outlet, second highest at the material zone (e.g., at a top surface of a feedstock), and lowest at the growth zone (e.g., at a growth surface). Two reverse temperature gradients, i.e., from the outlet near the partition to the growth surface and from the outlet near the partition to the material zone are formed. In some embodiments, a temperature gradient from the outlet to the growth surface is adjusted by adjusting a heating parameter of the second heating assembly and the temperature in the vicinity of the partition, which in turn maintains the discharge rate of the vapor phase component through the at least one outlet. By forming the bi-directional temperature gradient, the vapor phase component transport can be driven by a concentration gradient under the condition of satisfying the sublimation of the feedstock, which can reduce the power of the first heating assembly to a certain extent and save electrical energy. Besides, the temperature in the vicinity of the partition is the highest, which can inhibit nucleation and crystallization of vapor phase components in the vicinity of the partition. Furthermore, by forming the bi-directional temperature gradient, the discharge rate of the vapor phase component via the outlet can be adjusted to reduce the effect of temperature change on the discharge rate when the temperature of the material zone changes, which is conducive to controlling the stability of a rate of growing the crystal and to maintaining the stable growth of the crystal growth surface.

In some embodiments, the temperature of the material zone is higher than the temperature in the vicinity of the partition, and the temperature in the vicinity of the partition is higher than the temperature in the growth zone, i.e., the temperature in the material zone>the temperature in the vicinity of the partition>the temperature in the growth zone. Correspondingly, a temperature gradient that decreases sequentially in the material zone, at the partition, and in the growth zone can be formed within the growth chamber. In some embodiments, the temperature gradient from the material zone to the outlet, and to the growth surface is adjusted by adjusting the heating parameter of the first heating assembly and the second heating assembly to adjust the temperatures near the material zone and the partition. Since a concentration of the vapor phase component in the material zone is greater than a concentration of the vapor phase component in the vicinity of the partition and/or a concentration of the vapor phase component in the growth zone, the temperature gradient and the concentration gradient from the material zone to the outlet, and to the growth surface can drive the vapor phase component to move toward the growth zone. By forming the temperature gradient and the concentration gradient from the material zone to the growth surface, it is possible to drive the transport of the vapor phase component and regulate the discharge rate of the vapor phase component at the outlet on the partition through the temperature gradient and the concentration gradient under the condition of satisfying the sublimation of the feedstock, which is conducive to controlling the stability of the rate of growing the crystal and maintaining the stable growth of the crystal growth surface.

The material zone, the vicinity of the partition, and the growth zone are heated, respectively, using the first heating assembly, the second heating assembly, and the third heating assembly. Specifically, the first heating assembly can regulate a sublimation rate of the feedstock by controlling the temperature of the feedstock, and after the bottom of the material zone undergoes carbonization, the power of the first heating assembly can be regulated to compensate for the change in heat distribution and carbon to silicon ratio due to carbonization; the second heating assembly can inhibit nucleation and crystallization in the vicinity of the partition, as well as reduce the influence of the temperature regulation of the material zone on the discharge rate, to maintain the discharge rate at the outlet and maintain a stable growth of the crystal growth surface; and the third heating assembly can regulate the temperature gradient between the outlet and the growth zone and regulate the temperature gradient of the seed crystal along the radial direction, which reduces the thermal stress of the crystal growth, and at the same time reduces the temperature influence of the first heating assembly and/or the second heating assembly on the growth zone, and controls the stability of the temperature of the crystal growth surface, thereby reducing the probability of the formation of dislocations, reducing the defects of the crystal, and improving the quality of the grown crystal. Additionally, by setting the material zone and the growth zone separately and controlling the temperatures of the material zone, the vicinity of the partition, and the growth zone individually, it is possible to regulate the temperature gradient between the outlet and the growth zone and the temperature gradient of the seed crystal along the radial direction, thereby reducing the thermal stress of the crystal growth, improves the quality of the crystal, and effectively regulates a growth rate.

FIG. 16A is a schematic diagram illustrating an exemplary structure of a crystal growth device according to some embodiments of the present disclosure. FIG. 16B is a schematic diagram illustrating an exemplary structure of a crystal growth device according to some embodiments of the present disclosure. FIG. 16C is a schematic diagram illustrating an exemplary structure of a crystal growth device according to some embodiments of the present disclosure. Z denotes a seed crystal and Y denotes a feedstock. The crystal growth device is described in detail below in conjunction with FIG. 16A to FIG. 16C.

In some embodiments, the crystal growth device 108 includes the growth chamber 108-1 and the heating assembly 108-3.

In some embodiments, the growth chamber 108-1 includes the growth zone 108-11 and the material zone 108-12, with the growth zone 108-11 being configured to place the seed crystal and the material zone 108-12 being configured to place the feedstock. In some embodiments, the growth zone 108-11 and the material zone 108-12 are separated by the partition 108-2. In some embodiments, the partition 108-2 includes at least one outlet 108-21, and a vapor phase component is transported to the growth zone 108-11 via the at least one outlet 108-21. By providing the outlet 108-21, the vapor phase component generated from the sublimation and decomposition of the feedstock can be reasonably distributed, which further stabilizes and uniformizes a discharge rate of the outlet for deposition and growth of a high-quality crystal with suitable convexity.

In some embodiments, the heating assembly 108-3 is configured to heat the growth chamber 108-1 for growing a crystal based on the seed crystal Z and the feedstock Y by a physical vapor transport manner. In some embodiments, the heating assembly 108-3 includes the first heating assembly 108-31, the second heating assembly 108-32, and the third heating assembly 108-33 for heating the material zone, the vicinity of the partition, and the growth zone, respectively.

In some embodiments, the outlet 108-21 is prepared by mechanical perforation. In some embodiments, the partition 108-2 itself is prepared from a porous material, where voids inside the partition serve as the at least one outlet 108-21. For example, the outlet 108-21 is obtained by mechanically punching holes in the partition 108-2 as shown in FIG. 16A. As another example, as shown in FIG. 16B and FIG. 16C, the partition 108-2 can be porous graphite, with voids on the porous graphite serving as the at least one outlet 108-21. Using the voids on the porous graphite as the at least one outlet 108-21 allows for the passage of the vapor phase components of the feedstock while ensuring the replenishment of the carbon component without contamination. In some embodiments, the partition 108-2 is also a multi-layer grid-like structure (not shown in the figures), where dimensions and/or shapes of through holes in the partition can be adjusted by adjusting a positional relationship between different layers on the partition.

In some embodiments, at least one of a position, shape, distribution, or area of the outlet 108-21 is adjustable. In some embodiments, the position of the outlet 108-21 includes an axial position of the outlet 108-21 and a radial position of the outlet 108-21. In some embodiments, the shape of the outlet 108-21 is a cross-sectional shape. In some embodiments, the distribution of the outlet 108-21 is a distribution position and/or a distribution density of the outlet 108-21 on the partition 108-2. In some embodiments, the area of the outlet 108-21 is a cross-sectional area of a single outlet 108-21 or a sum of cross-sectional areas of a plurality of outlets 108-21.

In some embodiments, a chamber lid is mounted on a slide rail, and a relative position between the chamber lid and the outlet 108-21 is adjusted through the slide rail. In some embodiments, a cover plate is mounted on the outlet 108-21 to adjust the shape, distribution, or area of the outlet 108-21 by opening or closing the cover.

In some embodiments, as a crystal grows, the feedstock is gradually consumed, a top surface of the feedstock gradually decreases, and a thickness of the crystal gradually increases, and in an aim to maintain a distance between a crystal growth surface and the outlet 108-21 to stabilize the growth of the crystal, the axial position of the outlet 108-21 can be adjusted so that the outlet 108-21 is gradually moved downward.

In some embodiments, as the crystal grows, a radial temperature gradient may exist on a surface of the seed crystal, resulting in a different growth rate at various points on the seed crystal growth surface. To ensure that the growth rate is the same or similar at all points on the growth surface, and to achieve a relatively smooth or appropriately convex surface, the radial position of the outlet 108-21 can be adjusted to maintain a consistent or similar growth rate across radial regions of the growth surface.

In some embodiments, the shape, distribution, and/or area of the outlet 108-21 can be adjusted by opening and closing the cover plate to maintain a steady flow of discharge amount as well as a steady growth rate of the growth surface.

In some embodiments, it is also possible to adjust, based on crystal growth data collected during a previous process of growing a crystal, a relative position between the chamber lid and the outlet 108-21 during a next process of growing a crystal can be adjusted, or the shape, distribution, or area of the outlet 108-21 can be adjusted.

In some embodiments, if a radial temperature gradient exists on the surface of the seed crystal during the previous process of growing the crystal, which results in a different growth rate at various points on the seed crystal growth surface, to make the growth rate at various points on the seed crystal growth surface be the same or similar and to achieve a relatively smooth or appropriately convex surface, the radial position of the outlet 108-21 can be adjusted during the next process of growing the crystal to maintain a consistent or similar growth rate across the radial regions of the growth surface.

In some embodiments, if vapor phase components are concentrated in some positions during the previous process of growing the crystal, which results in a higher concentration in some positions within the growth chamber and a lower concentration in the rest of the positions, in order to make a concentration of vapor phase components at various points below the seed crystal growth surface the same or similar, and to grow a crystal with a relatively flat or suitable convexity, the radial position of the outlet 108-21 during the next process of growing the crystal can be adjusted to maintain a consistent or similar growth rate across the radial regions of the growth surface.

In some embodiments, if a thickness of the crystal is less than a thickness threshold (e.g., 3 mm, 5 mm, or 8 mm) or the growth rate is less than a rate threshold (e.g., 0.1 mm/h, 0.3 mm/h, or 0.5 mm/h) during the previous process of growing the crystal, the axial position of the outlet 108-21 can be adjusted to allow for a rise in the outlet 108-21 during the next process of growing the crystal, or the shape, distribution or area of the outlet 108-21 is adjusted by opening the cover plate to increase the growth rate of the crystal.

More descriptions regarding adjusting at least one of the position, shape, distribution, or area of the outlet can be found elsewhere in the present disclosure (e.g., FIG. 20 to FIG. 22 and their related descriptions) and will not be repeated herein.

In some embodiments, the first heating assembly 108-31 is configured to heat the material zone 108-12 to sublimate the feedstock Y into the vapor phase component required for growing the crystal. For example, as shown in FIG. 16A and FIG. 16B, the first heating assembly 108-31 is a resistance heating assembly. As another example, as shown in FIG. 16C, the first heating assembly 108-31 is an induction heating assembly.

In some embodiments, the power of the first heating assembly 108-31 is compensated and adjusted with a carbonization degree of the feedstock during the process of growing the crystal to maintain a transport rate of the vapor phase component at the outlet 108-21.

In some embodiments, the second heating assembly 108-32 is arranged on an outer side of the partition 108-2 for heating the vicinity of the partition 108-2 to maintain the discharge rate of the vapor phase component via the at least one outlet 108-21. For example, the second heating assembly 108-32 is an electrical resistance heating assembly, as shown in FIG. 16A and FIG. 16B. As another example, as shown in FIG. 16C, the second heating assembly 108-32 is an induction heating assembly.

In some embodiments, the power of the second heating assembly 108-32 is maintained at a constant or minimally reduced power level during the process of growing the crystal to control the transport rate of the vapor phase component at a substantially constant rate.

In some embodiments, the third heating assembly 108-33 is configured to heat the growth zone 108-11. For example, as shown in FIG. 16A, FIG. 16B, and FIG. 16C, the third heating assembly 108-33 is a resistance heating assembly.

In some embodiments, a radial temperature gradient of the crystal is made as small as possible by controlling the power of the third heating assembly 108-33 during the process of growing the crystal and causing the temperature gradient to remain constant throughout the entire growth process.

In some embodiments, the third heating assembly 108-33 includes a plurality of sub-heating assemblies disposed around a periphery of the growth zone 108-11 at different axial heights. In some embodiments, heating parameters of the plurality of sub-heating assemblies are controlled independently of each other for independent control of temperatures at different axial heights. For example, if a localized axial temperature gradient increases, the localized axial temperature gradient may be reduced by individually controlling the heating parameter of the plurality of sub-heating assemblies. In some embodiments, the plurality of sub-heating assemblies are a plurality of annular induction coils disposed at different heights along an axial direction, with the annular induction coils being connected in parallel to form the third heating assembly. In some embodiments, the plurality of annular induction coils can be controlled independently and separately according to an axial temperature gradient, so that the axial temperature gradient is less than a preset gradient threshold value, which lowers the thermal stress of the crystal, avoids cracking of the crystal, and thereby leading to a high-quality crystal.

In some embodiments, the third heating assembly 108-33 includes a plurality of sub-heating assemblies disposed around the top of the growth zone 108-11 at different radial diameters. In some embodiments, the heating parameter of the plurality of sub-heating assemblies can be independently controlled separately for independent control of temperatures at different radial diameters. For example, if a localized radial temperature gradient increases, the localized radial temperature gradient may be reduced by individually controlling the heating parameter of the plurality of sub-heating assemblies. In some embodiments, the plurality of sub-heating assemblies are a plurality of annular heating resistance components that gradually decrease in dimension along a radial direction, the annular heating resistance components being connected in parallel to form the third heating assembly. In some embodiments, the plurality of annular heating resistance components can be controlled independently and separately based on the radial temperature gradient, so that the radial temperature gradient is less than the preset gradient threshold, which reduces the thermal stress of the crystal and avoids cracking of the crystal, thereby leading to a high-quality crystal. In some embodiments, the third heating assembly is located above the chamber lid or at a periphery of a chamber where the chamber lid is located.

In some embodiments, the crystal growth device 108 further includes the insulation assembly 108-4. In some embodiments, the insulation assembly 108-4 is located between the material zone 108-11 and the growth zone 108-12 for isolating the heat exchange between the growth zone 108-11 and the material zone 108-12, thereby separately controlling the temperature of the growth zone 108-11 and the material zone 108-12. In some embodiments, a plurality of holes are provided in the insulation assembly 108-4, thereby allowing the vapor phase component to be transported to the growth zone 108-11 via the plurality of holes.

In some embodiments, the crystal growth device 108 further includes the temperature measurement assembly 103 for obtaining a plurality of temperatures associated with the growth chamber 108-1. More can be found in FIG. 18 and its related description.

In some embodiments, the crystal growth device 108 further includes the monitoring assembly 104 for monitoring a situation of growing the crystal. More descriptions regarding the monitoring assembly 104 can be found in FIG. 19A and FIG. 19B and their related descriptions.

In some embodiments, the crystal growth device 108 further includes a control assembly (not shown in FIG. 16A to FIG. 16C). In some embodiments, the control assembly is implemented by the processing device 101 and/or the control device 102.

In some embodiments, the control assembly obtains temperature information within the growth chamber 108-1 and adjusts at least one of a position, shape, distribution, or area of at least one outlet based on the temperature information. In some embodiments, the temperature information is determined based on a plurality of temperatures through modeling. In some embodiments, the temperature information includes temperature information of a crystal growth surface. In some embodiments, the control assembly obtains temperature information within the growth chamber 108-1 during a previous process of growing the crystal, and adjusts at least one of a position, shape, distribution, or area of at least one outlet during a next process of growing a crystal based on temperature information during the previous process of growing the crystal. More descriptions regarding adjusting at least one of the position, shape, distribution, or area of the at least one outlet based on the temperature information or adjusting at least one of the positions, shape, distribution, or area of the at least one outlet during the next process of growing the crystal based on temperature information during the previous process of growing the crystal can be found in other parts of the present disclosure (e.g., FIG. 20 and its related descriptions), and will not be repeated herein.

In some embodiments, the control assembly obtains a distribution of the vapor phase component required for growing the crystal within the growth chamber 108-1; and based on the distribution, adjusts at least one of the position, shape, distribution, or area of the at least one outlet. In some embodiments, the control assembly obtains a distribution of a vapor phase component required for growing a crystal within the growth chamber 108-1 during a previous process of growing a crystal; and based on the distribution during the previous process of growing the crystal, adjusts at least one of a position, shape, distribution, or area of the at least one outlet during a next process of growing a crystal. More descriptions regarding adjusting at least one of the position, shape, distribution, or area of the at least one outlet based on the distribution or adjusting at least one of the position, shape, distribution, or area of the at least one outlet during the next process of growing the crystal based on the distribution during the previous process of growing the crystal can be found elsewhere in the present disclosure (e.g., FIG. 21 and its related description), and will not be repeated herein.

In some embodiments, the control assembly further adjusts at least one of the heating parameter of the heating assembly 108-3 and/or the position, shape, distribution, or area of the at least one outlet 108-21 based on the situation of growing the crystal. In some embodiments, the control assembly further adjusts, based on a situation of growing a crystal during a previous process of growing a crystal, the heating parameter of the heating assembly 108-3 and/or the position, shape, distribution, or area of the at least one outlet 108-21 during a next process of growing a crystal. In some embodiments, the situation of growing the crystal includes at least one of a thickness, a growth rate, or a defect of a growing crystal. More descriptions regarding adjusting the heating parameter of the heating assembly and/or the position, shape, distribution, or area of the at least one outlet or about adjusting the heating parameter of the heating assembly and/or the position, shape, distribution, or area of the at least one outlet during the next process of growing the crystal can be found in other parts of the present disclosure (e.g., FIG. 22 and its related descriptions), and will not be repeated herein.

FIG. 18 is a schematic diagram illustrating an exemplary arrangement of a temperature measurement assembly according to some embodiments of the present disclosure.

In some embodiments, the temperature measurement assembly 103 includes a plurality of temperature sensors 103-1. In some embodiments, as shown in FIG. 18, side walls and/or top of the growth chamber 108-1 include an insulation layer 103-2, and the temperature sensors 103-1 are disposed on the side walls and/or top of the growth chamber 108-1 by passing through the insulation layer 103-2.

In some embodiments, the temperature sensor 103-1 includes a thermocouple, an infrared pyrometer, a thermistor, etc., or any combination thereof.

In some embodiments, a position and count of the temperature sensor 103-1 are set and adjusted as needed for monitoring. In some embodiments, the plurality of temperature sensors 103-1 are arranged axially on the side walls of the growth chamber 108-1, or the plurality of temperature sensors 103-1 are arranged radially on the top of the growth chamber 108-1.

In some embodiments, the temperature sensors 103-1 are symmetrically distributed. For example, four temperature sensors 103-1 are arranged axially on the left side wall of the growth chamber 108-1 and four temperature sensors 103-1 are arranged axially on the right side wall of the growth chamber 108-1. By symmetrically distributing the temperature sensors 103-1, the overall temperature distribution within the growth chamber 108-1 can be monitored. The uniformly distributed apertures ensure the symmetry of the temperature field, preventing any adverse effects on the crystal growth.

In some embodiments, the temperature sensors 103-1 are asymmetrically distributed on the growth chamber 108-1. For example, four temperature sensors 103-1 are arranged axially on the left side wall of the growth chamber 108-1 and three temperature sensors 103-1 are arranged axially on the right side wall of the growth chamber 108-1. By setting the temperature sensors 103-1 asymmetrically distributed, it is possible to focus on detecting a localized temperature condition within the growth chamber 108-1 with greater flexibility.

In some embodiments, an axial temperature gradient or a radial temperature gradient within the growth chamber 108-1 is obtained using the temperature sensor 103-1.

In some embodiments, to avoid inaccurate temperature measurement due to deposition of volatiles within the growth chamber at a temperature measurement port, a cooling assembly 103-3 is provided between the plurality of temperature sensors 103-1 and the top and/or side walls of the growth chamber 108-1. In some embodiments, if the temperature sensors 103-1 are infrared pyrometers, a cold trap is provided between the temperature sensors 103-1 and the top and/or side walls of the growth chamber 108-1. In some embodiments, the cold trap is a hollow cylindrical structure (e.g., a hollow cylinder, a hollow quadrilateral, etc.), with one end of the hollow cylindrical structure connected to the chamber and unsealed, and another end sealed by the optical glass. The temperature measurement point of the temperature sensor 103-1 is located along the axis of the cold trap and outside the optical glass. Side walls of the cold trap may be of a hollow structure, and the temperature of the inner wall may be reduced by passing cooling water.

In some embodiments, the cooling assembly 103-3 may be one or more. In some embodiments, the cooling assembly 103-3 is provided in correspondence with the plurality of temperature sensors 103-1. For example, one cooling assembly 103-3 is provided corresponding to each temperature sensor 103-1. By providing the cooling assembly 103-3 between the temperature sensor 103-1 and the top and/or side walls of the growth chamber 108-1, volatiles (e.g., vapor phase components) inside the growth chamber 108-1 can be cooled and attached to the side walls of the cooling assembly 103-3, preventing them from reaching the temperature sensor 103-1 and affecting its detection accuracy.

A cooling assembly is arranged between the temperature sensor and the top of the growth chamber, with the temperature measurement assembly located above the cooling assembly. Since the temperature at the cooling assembly is lower, volatiles will adhere to the side walls of the cooling assembly during evaporation, preventing them from reaching the temperature measurement assembly above, thereby avoiding the attachment of volatiles to the measurement assembly and ensuring the accuracy of its measurements.

FIG. 19A is a schematic diagram illustrating an exemplary structure of a monitoring assembly according to some embodiments of the present disclosure. FIG. 19B is a schematic diagram illustrating an exemplary structure of a monitoring assembly according to some embodiments of the present disclosure. In the figures, Z denotes a seed crystal.

In some embodiments, the monitoring assembly 104 includes a contact monitoring assembly or a non-contact monitoring assembly. For example, FIG. 19A is the contact monitoring assembly and FIG. 19B is the non-contact monitoring assembly.

In some embodiments, the monitoring assembly 104 is the contact monitoring assembly, as shown in FIG. 19A. The monitoring assembly 104 includes an ultrasonic thickness gauge 104-1, a cooling device 104-2, and a graphite rod 104-3. In some embodiments, the ultrasonic thickness gauge 104-1 includes an ultrasonic probe 104-11. In some embodiments, the graphite rod 104-3 is integrally molded with the chamber lid 108-111. The ultrasonic probe 104-11 can emit ultrasound waves and reflect them via the growing crystal Z, which in turn allows for the determination of a thickness of the growing crystal Z based on the propagation time of the ultrasound waves. Further, a growth rate of the crystal can also be calculated based on thickness information at multiple time points.

Due to the specific temperature requirements of the ultrasonic probe 104-11, excessively high temperatures may cause damage. Therefore, it is necessary to reduce the temperature at a contact point of the ultrasonic probe 104-11 to below 500° C. In some embodiments, the temperature at the contact point of the ultrasonic probe 104-11 can be reduced by increasing the length of the graphite rod 104-3. In some embodiments, the temperature at the contact point of the ultrasonic probe 104-11 can be reduced by providing a cooling device 104-2 at an upper portion of the graphite rod 104-3. In some embodiments, the cooling device 104-2 is an air-cooling device. Specifically, the cooling device 104-2 is a sealed graphite cylinder, and the ultrasonic probe 104-11 is disposed from the upper portion of the cooling device 104-2 into the interior of the cooling device 104-2 and placed on the graphite rod 104-3, inert gas is passed into the cooling device 104-2 to cool the ultrasonic probe 104-11. It should be noted that both the cooling device 104-2 and the growth chamber 108-1 are sealed, and gases in the two do not circulate with each other.

If the thickness of the graphite rod 104-3 is too thick, the conduction of the ultrasonic pulse will be affected, thus affecting the measurement results of the ultrasonic thickness gauge 104-1; if the thickness of the graphite rod 104-3 is too thin, it will not provide adequate cooling, and the temperature at the contact point of the ultrasonic probe 104-11 is too high, which potentially damages the ultrasonic probe 104-11. Therefore, it is necessary to set the thickness of graphite rod 104-3 in the appropriate range.

In some embodiments, the thickness of the graphite rod 104-3 is in a range of 5 cm to 30 cm. In some embodiments, the thickness of the graphite rod 104-3 is in a range of 8 cm to 27 cm. In some embodiments, the thickness of the graphite rod 104-3 is in a range of 11 cm to 24 cm. In some embodiments, the thickness of the graphite rod 104-3 is in a range of 14 cm to 21 cm. In some embodiments, the thickness of the graphite rod 104-3 is in a range of 17 cm to 18 cm. In some embodiments, the thickness of the graphite rod 104-3 is in a range of 17.3 cm to 18.7 cm.

In some embodiments, a coupling agent (e.g., a polymer hydrogel) is used at the contact point of the ultrasonic probe 104-11 of the contact monitoring assembly 104 with the graphite rod 104-3 to fill the tiny gaps between the contact point of the graphite rod 104-3 and the ultrasonic probe 104-11, preventing the slight air gaps from affecting the measurement results. In some embodiments, the ultrasonic probe 104-11 is spaced apart at a fixed position for a certain time to take measurements or moved along a specific trajectory to take rapid measurements, thereby obtaining a growth rate of a crystal at the fixed position or thickness distribution data in a certain region.

In some embodiments, the monitoring assembly 104 is the non-contact monitoring component as shown in FIG. 19B. In some embodiments, the non-contact monitoring assembly 104 includes air-coupled ultrasonic non-destructive testing, electromagnetic acoustic transducer (EMAT) non-destructive testing, electrostatic-coupled ultrasonic non-destructive testing, laser ultrasonic non-destructive testing, or the like.

Since there is no need for contact between the ultrasonic probe 104-11 of the non-contact monitoring assembly 104 and the chamber lid 108-111, the risk of damage to the ultrasonic probe 104-11 from contacting the high-temperature object being measured can be avoided.

FIG. 20 is a flowchart illustrating a process of a crystal growth method according to some embodiments of the present disclosure. In some embodiments, a process 2000 is performed by a processing device (e.g., the processing device 101) and/or a control device (e.g., the control device 102). For example, the process 2000 is stored in a storage device (e.g., a storage unit of a storage device, a processing device, and/or a control device) in the form of a program or instructions, and the process 2000 is implemented when the processor 202 executes the program or instructions. In some embodiments, the process 2000 is accomplished utilizing one or more of the additional operations not described below, and/or not by one or more of the operations discussed below. Additionally, the order of the operations shown in FIG. 20 is not limiting.

In step 2010, obtaining temperature information within a growth chamber.

In some embodiments, the temperature information is temperature values, temperature gradients, or temperature distributions at various positions within the growth chamber. In some embodiments, the temperature information includes temperature information of the growth surface of a crystal.

In some embodiments, the processing device and/or the control device obtain a plurality of temperatures associated with the growth chamber using a temperature measurement assembly. In some embodiments, the temperature measurement assembly includes a plurality of temperature sensors. More descriptions regarding the temperature measurement assembly can be found elsewhere in the present disclosure (e.g., FIG. 18 and its associated description) and will not be repeated herein.

In some embodiments, the processing device and/or the control device determines temperature information within the growth chamber based on a plurality of temperatures by modeling. In some embodiments, the processing device and/or the control device obtains positional information between a plurality of temperature measurement assemblies (e.g., the temperature sensors 103-1 shown in FIG. 18) as well as positional information between the temperature measurement assemblies and the crystal growth surface. In some embodiments, the processing device and/or the control device determines the positional information (e.g., distance, angle) between the plurality of temperature measurement assemblies based on structural parameters of a crystal growth device (e.g., a dimension of the crystal growth device) as well as positions of the temperature measurement assemblies on the growth device of the crystal. In some embodiments, the processing device and/or the control device obtains the thickness of the crystal using the monitoring assembly 104 (e.g., the monitoring assembly 104 in FIG. 19A and FIG. 19B), and determines the positional information (e.g., distance, angle) between the temperature measurement assemblies and the crystal growth surface based on the thickness of the crystal, the structural parameters of the crystal growth device (e.g., the dimension of the crystal growth device), and the positions of the temperature measurement assemblies on the growth device of the crystal. In some embodiments, the processing device and/or the control device inputs the plurality of temperatures, the positional information between the plurality of temperature measurement assemblies, and the positional information between the plurality of temperature measurement assemblies and the crystal growth surface into a temperature model, and the temperature model outputs the temperature information within the growth chamber. In some embodiments, the temperature model is obtained through pre-training based on a plurality of historical temperatures, historical positional information between the plurality of temperature measurement assemblies, and historical positional information and historical temperature information between the plurality of temperature measurement assemblies and the crystal growth surface. The plurality of historical temperatures, the historical positional information between the plurality of temperature measurement assemblies, and the historical positional information between the plurality of temperature measurement assemblies and the crystal growth surface are training data, and the historical temperature information is a training label.

In further embodiments, the processing device and/or the control device obtain pressure information within the growth chamber using a pressure sensor. In some embodiments, the pressure information includes at least one pressure value. In some embodiments, the processing device and/or the control device inputs the plurality of temperatures, the pressure information, and the structural parameters of the crystal growth device into simulation software, and the simulation software outputs the temperature information within the growth chamber. In some embodiments, the simulation software includes virtual reactor software.

In step 2020, adjusting at least one of a position, shape, distribution, or area of at least one outlet based on the temperature information.

In some embodiments, the processing device and/or the control device adjusts at least one of the position, shape, distribution, or area of at least one outlet during a current process of growing a crystal or a next process of growing a crystal based on the temperature information.

In some embodiments, the temperature information may be a temperature gradient, and if the temperature gradient in a vicinity of the crystal growth surface is not uniformly distributed, resulting in a large temperature gradient at some positions near the crystal growth surface and a small temperature gradient at remaining positions, in order to make temperature gradients at various places below a seed crystal growth surface the same or similar, and to grow a crystal with a relatively flat or suitable convexity, a radial position of the outlet 108-21 can be adjusted during the current process of growing the crystal or the next process of growing the crystal, so as to make the outlet 108-21 shift. Furthermore, the shape of at least one outlet 108-21 can also be adjusted by opening and closing a cover; and the distribution of the at least one outlet 108-21 can also be adjusted by opening and closing the cover, so that some of the at least one outlets 108-21 are opened or closed; or it is also possible to open or close some of the at least one outlet 108-21 by opening and closing the cover plate to adjust an area of the at least one outlet 108-21. In some embodiments, the temperature gradient in the vicinity of the crystal growth surface may be a radial temperature gradient on the crystal growth surface, or an axial temperature gradient along a vertical direction in the vicinity of the crystal growth surface.

By adjusting the position, shape, distribution, or area of the outlet during the current process of growing the crystal or the next process of growing the crystal based on temperature information, the current or the next process of growing the crystal can be stabilized, the defects of crystal growth can be reduced, and the quality of a crystal can be improved.

FIG. 21 is a flowchart illustrating an exemplary crystal growth method according to some embodiments of the present disclosure. In some embodiments, a process 2100 is performed by a processing device (e.g., the processing device 101) and/or a control device (e.g., the control device 102). For example, the process 2100 is stored in a storage device (e.g., a storage unit of a storage device, a processing device, and/or a control device) in the form of a program or instruction, and the process 2100 may be implemented when the processor 202 executes the program or instruction. In some embodiments, the process 2100 is accomplished utilizing one or more of the additional operations not described below, and/or not by one or more of the operations discussed below. Additionally, the order of the operations as shown in FIG. 21 is not limiting.

In step 2110, obtaining a distribution of a vapor phase component required for growing a crystal within a growth chamber.

In some embodiments, the distribution of the vapor phase component within the growth chamber is a distribution of a concentration of the vapor phase component within the growth chamber or at various positions within the growth chamber.

In some embodiments, the processing device and/or the control device obtain temperature information within the growth chamber using a temperature measurement assembly. In some embodiments, the processing device and/or the control device obtains a current state of an outlet and determines relevant information of the outlet based on the current state of the outlet. In some embodiments, the relevant information of the outlet includes at least one of the position, shape, distribution, or area of the outlet.

Further, the processing device and/or the control device simulate and determine the distribution of the vapor phase component within the growth chamber based on the temperature information within the growth chamber and the relevant information of the outlet. Specifically, the temperature information within the growth chamber and the relevant information of the outlet are input into simulation software, and the simulation software outputs the distribution of the vapor phase component within the growth chamber. In some embodiments, the simulation software includes virtual reactor software.

In step 2120, adjusting at least one of a position, shape, distribution, or area of at least one outlet based on the distribution.

In some embodiments, the processing device and/or the control device adjusts, based on the distribution of the vapor phase component within the growth chamber, a position, shape, distribution, or area of at least one outlet during a current process of growing a crystal or during a next process of growing a crystal.

In some embodiments, if the vapor phase component is concentrated in some positions, resulting in a higher concentration in some positions within the growth chamber and a lower concentration in remaining positions, to make a concentration of the vapor phase component at each position below a seed crystal growth surface the same or similar, and to grow a relatively flat crystal, a radial position of the outlet 108-21 can be adjusted during the current process of growing the crystal or during the next process of growing the crystal, so that the outlet 108-21 is shifted. Further, the shape of the at least one outlet 108-21 can also be adjusted by opening and closing a cover plate; and distribution of the at least one outlet 108-21 can also be adjusted by opening and closing the cover plate to open or close some of the at least one outlet 108-21; or an area of the at least one outlet 108-21 can also be adjusted by opening or closing the cover plate to open or close some of the at least one outlet 108-21.

By adjusting the position, shape, distribution, or area of the outlet during the current process of growing the crystal or the next process of growing the crystal based on the distribution of the vapor phase component, the vapor phase component on the crystal growth surface during the current process of growing the crystal or during the next process of growing the crystal can be distributed more uniformly, resulting in flatter crystal and reducing the defects of crystal growth, and improve the quality of the crystal.

FIG. 22 is a flowchart illustrating an exemplary crystal growth method according to some embodiments of the present disclosure. In some embodiments, a process 2200 is performed by a processing device (e.g., the processing device 101) and/or a control device (e.g., the control device 102). For example, the process 2200 is stored in a storage device (e.g., a storage unit of a storage device, a processing device, and/or a control device) in the form of a program or instruction, and the process 2200 may be implemented when the processor 202 executes the program or instruction. In some embodiments, the process 2200 is accomplished utilizing one or more of the additional operations not described below, and/or not by one or more of the operations discussed below. Additionally, the order of the operations shown in FIG. 22 is not limiting.

In step 2210, monitoring a situation of growing a crystal during a process of growing the crystal.

In some embodiments, the situation of growing the crystal includes at least one of a thickness, a growth rate, or a defect of a growing crystal.

In some embodiments, the processing device and/or the control device monitor the situation of growing the crystal using a monitoring assembly (e.g., the ultrasonic thickness gauge 104-1). More descriptions regarding monitoring the situation of growing the crystal using the monitoring assembly can be found elsewhere in the present disclosure (e.g., FIG. 19A and FIG. 19B and their related descriptions) and will not be repeated herein.

In some embodiments, the processing device and/or the control device also inputs obtained temperature information, pressure information, the thickness of the crystal, or the like into simulation software, and the simulation software outputs the situation of growing the crystal and/or a situation of feedstock consumed within a growth chamber, thereby online monitoring a process of growing the crystal. In some embodiments, the situation of feedstock consumed includes at least one of a weight of the crystal, an amount of sublimation of the feedstock, an amount of remaining feedstock, or the like.

In step 2220, adjusting at least one of a heating parameter of a heating assembly and/or a position, shape, distribution, or area of at least one outlet based on the situation of growing the crystal.

In some embodiments, the processing device and/or the control device adjusts the heating parameter of the heating assembly during a current process of growing a crystal or during a next process of growing a crystal based on the situation of growing the crystal. In some embodiments, if the thickness of the crystal is less than a thickness threshold (e.g., 3 mm, 5 mm, or 8 mm) or the growth rate is less than a rate threshold (e.g., 0.1 mm/h, 0.3 mm/h, or 0.5 mm/h), in order to increase the growth rate of the crystal, the heating power of a first heating assembly and/or a second heating assembly during the current process of growing the crystal or the next process of growing the crystal is adjusted to so that a sublimation rate of the feedstock is increased as well as the driving force for diffusion of a vapor phase component to a seed crystal is increased. In some embodiments, if a defect density of the crystal is greater than a density threshold, to improve the quality of the crystal growth, the heating power of a third heating assembly during the current process of growing the crystal or during the next process of growing the crystal is adjusted to reduce a radial temperature gradient of the seed crystal. In some embodiments, the defect density of the crystal is a porosity density. In some embodiments, the density threshold is 8/cm², 10/cm², or 15/cm².

In some embodiments, the processing device and/or the control device adjusts at least one of a position, shape, distribution, or area of the at least one outlet during the current process of growing the crystal or the next process of growing the crystal based on the situation of growing the crystal.

In some embodiments, if the thickness of the crystal is less than the thickness threshold (e.g., 3 mm, 5 mm, or 8 mm) or the growth rate is less than the rate threshold (e.g., 0.1 mm/h, 0.3 mm/h, or 0.5 mm/h), an axial position of the outlet 108-21 can be adjusted to allow for a rise in the outlet 108-21 during the current process of growing the crystal or the next process of growing the crystal, or by opening or closing a cover plate to adjust the shape, distribution or area of the outlet 108-21 to increase the growth rate of the crystal. In some embodiments, if the defect density (e.g., porosity density) of the crystal is greater than the density threshold (e.g., 8/cm², 10/cm², or 15/cm²), a radial position of the outlet 108-21 can be adjusted during the current process of growing the crystal or the next process of growing the crystal to improve the quality of the crystal growth, or adjust the shape, distribution, or area of the outlet 108-21 by opening or closing the cover.

By adjusting the heating parameter of the heating assembly and/or the position, shape, distribution, or area of the outlet during the current process of growing the crystal or the next process of growing the crystal based on the situation of growing the crystal, it is possible to improve the growth rate of the crystal and improve the quality of crystal growth.

In the process of growing a silicon carbide crystal by a physical vapor transport (PVT) manner, the silicon carbide powder is not fully utilized after the growth is complete, and the remaining unused portion often forms into porous silicon carbide polycrystalline blocks. Due to the high cost of high-purity silicon carbide powder, it is necessary to recycle the residual of the feedstock after crystal growth to conserve resources and reduce costs.

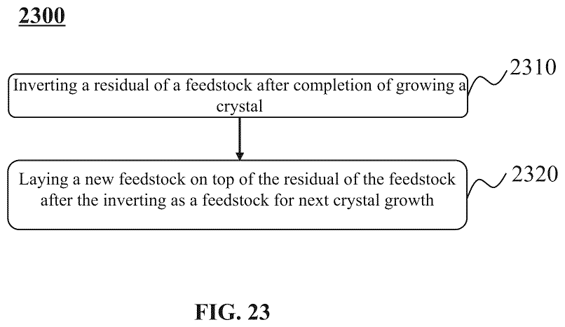

FIG. 23 is a flowchart illustrating a process of recovering a residual of a feedstock according to some embodiments of the present disclosure. In some embodiments, a process 2300 is performed by a processing device (e.g., the processing device 101) and/or a control device (e.g., the control device 102). For example, the process 2300 is stored in a storage device (e.g., a storage unit of a storage device, a processing device, and/or a control device) in the form of a program or instruction, and the process 2300 may be implemented when the processor 202 executes the program or instruction. In some embodiments, the process 2300 is accomplished utilizing one or more of the additional operations not described below, and/or not by one or more of the operations discussed below. Additionally, the order of the operations shown in FIG. 23 is not limiting.

In step 2310, inverting a residual of a feedstock after completion of growing a crystal.

In some embodiments, the residual of the feedstock is a feedstock that is left over after growing the crystal is completed.

In the process of growing a silicon carbide crystal by a physical vapor transport manner, the feedstock is not all decomposed into vapor phase components at the same time but is decomposed first at higher temperatures close to side walls of a growth chamber, and then decomposed later at lower temperatures in the middle of the growth chamber. During a sublimation and decomposition process, the products of a SiC feedstock after being heated, decomposed, and sublimated primarily include gaseous Si, Si₂C, SiC₂, and solid carbon particles. Si evaporates before C (with the sublimation temperature of silicon around 1400° C. and that of carbon around 2877° C.). A portion of the Si moves upward from a vicinity of side walls of a growth chamber, while another portion moves toward the center of the feedstock. As the reaction progresses, carbon produced at the bottom of the feedstock and around the side walls of the growth chamber forms a carbon shell (carbon-rich zone), encapsulating the undecomposed feedstock in the middle. The top of the feedstock is generally silicon-rich. The carbon shell is relatively porous and has a lower thermal conductivity compared to the original silicon carbide, which hinders heat conduction. The carbon shell also creates resistance to the transport of vapor phase components generated during the decomposition of the feedstock in the middle. After growing the crystal is complete, this results in the entire bottom of and side walls of the residual of the feedstock being carbon-rich, and silicon-rich in the middle and upper portions.

In some embodiments, in order to minimize the effect of the carbon-rich portion on the residual of the feedstock, the carbon-rich portion (carbon residue) is removed from the edge of the residual of the feedstock before the residual of the feedstock is inverted. In some embodiments, the residual of the feedstock can be inverted manually. Inverting manually is flexible in operation, simple in equipment, and low cost. In some embodiments, the residual of the feedstock is inverted by controlling a robotic arm through the processing device and/or the control device. In some embodiments, the robotic arm automatically picks up the residual of the feedstock according to a set program to invert the residual of the feedstock. Inverting the residual of the feedstock by the robotic arm reduces labor costs and is easy to manipulate.

In step 2320, laying a new feedstock on top of the residual of the feedstock after the inverting as a feedstock for next crystal growth.

In some embodiments, the new feedstock is an unreacted raw material required for growing a crystal. In some embodiments, the new feedstock includes silicon carbide powder. In some embodiments, the feedstock for the next crystal growth is a feedstock for the next growth of a silicon carbide crystal, i.e., the feedstock in step 310. In some embodiments, the new feedstock and the residual of the feedstock are laid down in a certain ratio. In some embodiments, the certain ratio is a mass ratio.

In some embodiments, the mass ratio of the new feedstock to the residual of the feedstock is in a range of 0.01 to 1. In some embodiments, the mass ratio of the new feedstock to the residual of the feedstock is in a range of 0.1 to 0.9. In some embodiments, the mass ratio of the new feedstock to the residual of the feedstock is in a range of 0.2 to 0.8. In some embodiments, the mass ratio of the new feedstock to the residual of the feedstock is in a range of 0.3 to 0.7. In some embodiments, the mass ratio of the new feedstock to the residual of the feedstock is in a range of 0.4 to 0.6. In some embodiments, the mass ratio of the new feedstock to the residual of the feedstock is in a range of 0.45 to 0.55. In some embodiments, the mass ratio of the new feedstock to the residual of the feedstock is in a range of 0.45 to 0.50.

By inverting the residual of the feedstock and laying the new feedstock thereon as the feedstock for the next crystal growth, it is possible to make full use of the residue and improve an utilization rate of the feedstock. In addition, since a larger proportion of the new feedstock is laid down, it can play a role in balancing the residual of the feedstock, and the silicon-rich nature of the residual of the feedstock is conducive to the control of the crystalline shape, and thus does not have an effect on the quality of the next crystal growth.

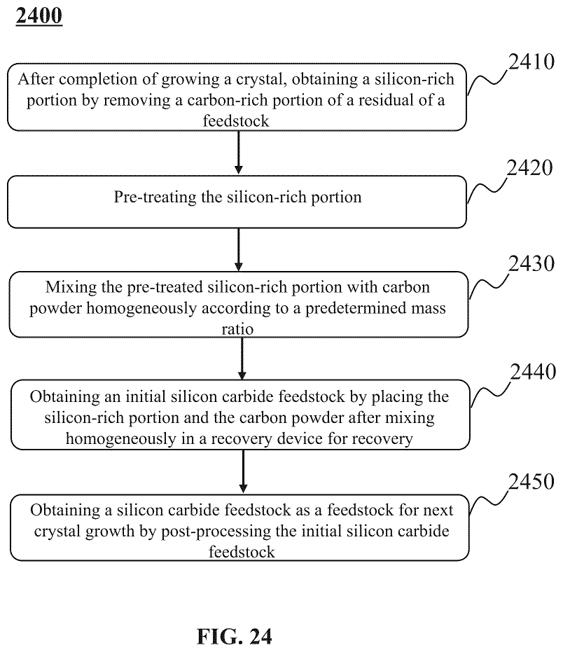

FIG. 24 is a flowchart illustrating a process of a crystal growth method according to some embodiments of the present disclosure. In some embodiments, a process 2400 is performed by a processing device (e.g., the processing device 101) and/or a control device (e.g., the control device 102). For example, the process 2400 is stored in a storage device (e.g., a storage unit of a storage device, a processing device, and/or a control device) in the form of a program or instruction, and the process 2400 may be implemented when the processor 202 executes the program or instruction. In some embodiments, the process 2400 is accomplished utilizing one or more of the additional operations not described below, and/or not by one or more of the operations discussed below. Additionally, the order of the operations as shown in FIG. 24 is not limiting.

In step 2410, after completion of growing a crystal, obtaining a silicon-rich portion by removing a carbon-rich portion of a residual of a feedstock.

In some embodiments, the carbon-rich portion is a carbon residue portion at an edge of the residual of the feedstock, as described in conjunction with FIG. 23. In some embodiments, the silicon-rich portion is composed of a portion of the residual of the feedstock that consists of the Si solid solution structure in SiC at an upper portion of the residual of the feedstock.

Since the carbon-rich portion is a low-hardness non-crystalline carbon slag, which is easy to detach from the residual of the feedstock, in a recovery process, only the silica-rich portion in the middle can be selected.

In step 2420, pre-treating the silicon-rich portion.

In some embodiments, the silicon-rich portion can be pretreated to allow the recovered silicon-rich portion to mix homogeneously with newly-added carbon powder. In some embodiments, the silicon-rich portion can be pre-treated by ball milling. Specifically, the silicon-rich portion is contained in a container (e.g., a polytetrafluoroethylene drum) of a ball mill, and a ball milling medium (e.g., a 10 mm×10 mm×10 mm block of silicon carbide single crystals) is added to the container, and the silica-rich portion is ball milled by the ball mill under a certain ball milling condition, and the pre-treated silicon-rich portion after ball mining is obtained.

In some embodiments, the ball milling condition includes a ball milling rotational speed and a ball milling time.

In some embodiments, the ball milling rotational speed is in a range of 100 r/min to 300 r/min. In some embodiments, the ball milling rotational speed is in a range of 150 r/min to 250 r/min. In some embodiments, the ball milling rotational speed is in a range of 200 r/min to 230 r/min.

In some embodiments, the ball milling time is in a range of 60 min to 200 min. In some embodiments, the ball milling time is in a range of 80 min to 180 min. In some embodiments, the ball milling time is in a range of 100 min to 150 min. In some embodiments, the ball milling time is in a range of 120 min to 140 min.

In some embodiments, the pre-treated silicon-rich portion after ball milling can be sieved to select a certain particle size of silicon carbide powder. In some embodiments, the particle size of the silicon carbide powder is in a range of 8 mesh to 200 mesh. In some embodiments, the particle size of the silicon carbide powder is in a range of 10 mesh to 180 mesh. In some embodiments, the particle size of the silicon carbide powder is in a range of 20 mesh to 150 mesh. In some embodiments, the particle size of the silicon carbide powder is in a range of 30 mesh to 120 mesh. In some embodiments, the particle size of the silicon carbide powder is in a range of 40 mesh to 100 mesh. In some embodiments, the particle size of the silicon carbide powder is in a range of 50 mesh to 90 mesh. In some embodiments, the particle size of the silicon carbide powder is in a range of 60 mesh to 80 mesh. In some embodiments, the particle size of the silicon carbide powder is in a range of 70 mesh to 75 mesh.

In step 2430, mixing the pre-treated silicon-rich portion with the carbon powder homogeneously according to a predetermined mass ratio.

Since the carbon to silicon molar ratio in the feedstock is 1 or close to 1, it is necessary to mix a certain amount of carbon powder in the pre-treated silicon-rich portion to ensure the quality of the feedstock in the next crystal growth.

In some embodiments, the predetermined mass ratio is in a range of 3:1 to 6:1. In some embodiments, the predetermined mass ratio is in a range of 3.5:1 to 5.5:1. In some embodiments, the predetermined mass ratio is in a range of 4:1 to 5:1. In some embodiments, the predetermined mass ratio is in a range of 4.2:1 to 4.8:1. In some embodiments, the predetermined mass ratio is in a range of 3:1 to 6:1. In some embodiments, the predetermined mass ratio is in a range of 4.4:1 to 4.6:1.

In some embodiments, the silicon-rich portion and the carbon powder are homogeneously mixed using a powder mixing equipment (e.g., a twin screw conical mixer, a horizontal gravity less mixer, a horizontal plow knife mixer, and a horizontal screw belt mixer). In some embodiments, the silicon-rich portion and the carbon powder are homogeneously mixed manually using a mortar (e.g., an agate mortar).

In step 2440, obtaining an initial silicon carbide feedstock by placing the silicon-rich portion and the carbon powder after mixing homogeneously in a recovery device for recovery.

In some embodiments, the recovery device is a place where the residual of the feedstock is recovered and processed.

In some embodiments, the homogeneously mixed silicon-rich portion and the carbon powder can be placed in a crucible, and then the crucible can be placed in the recovery device to react the silicon-rich portion with the carbon powder under certain reaction conditions. In some embodiments, the reaction condition includes a reaction temperature, a reaction atmosphere, a reaction pressure, and/or a reaction time.

In some embodiments, the crucible includes a tantalum carbide crucible or a crucible with a tantalum carbide coating applied to the interior of the crucible.

In some embodiments, the reaction temperature is in a range of 1700° C. to 2500° C. In some embodiments, the reaction temperature is in a range of 1800° C. to 2400° C. In some embodiments, the reaction temperature is in a range of 1900° C. to 2300° C. In some embodiments, the reaction temperature is in a range of 2000° C. to 2200° C. In some embodiments, the reaction temperature is in a range of 2050° C. to 2150° C.

In some embodiments, the reaction atmosphere includes inert gas (e.g., helium, neon, argon, etc.).

In some embodiments, the reaction pressure is in a range of 8 kPa to 14 kPa. In some embodiments, the reaction pressure is in a range of 8.5 kPa to 13.5 kPa. In some embodiments, the reaction pressure is in a range of 9 kPa to 13 kPa. In some embodiments, the reaction pressure is in a range of 9.5 kPa to 12.5 kPa. In some embodiments, the reaction pressure is in a range of 10 kPa to 12 kPa. In some embodiments, the reaction pressure is in a range of 10.5 kPa to 11.5 kPa.

In some embodiments, the reaction time is in a range of 0.5 h to 4 h. In some embodiments, the reaction time is in a range of 0.5 h to 4 h. In some embodiments, the reaction time is in a range of 1 h to 3.5 h. In some embodiments, the reaction time is in a range of 1.5 h to 3 h. In some embodiments, the reaction time is in a range of 1.7 h to 2.8 h. In some embodiments, the reaction time is in a range of 1.9 h to 2.6 h. In some embodiments, the reaction time is in a range of 2.1 h to 2.4 h.

In some embodiments, after the reaction is completed, the reaction is cooled to a certain temperature (e.g., in a range of 1500° C. to 1600° C.), held for a certain time (e.g., 30 min), and the above reaction and cooling process is repeated at least once (e.g., 2 times, 3 times, 4 times).

In some embodiments, after repeating the reaction and cooling process is completed, the recovery unit can be cooled to room temperature by natural cooling to obtain the initial silicon carbide feedstock.

In step 2450, obtaining a silicon carbide feedstock as a feedstock for next crystal growth by post-processing the initial silicon carbide feedstock.

In some embodiments, the feedstock for the next crystal growth is a feedstock for the next growth of a silicon carbide crystal, i.e., the feedstock in step 310.

In some embodiments, the post-processing includes treatments such as sieving, washing, carbon removal, or the like. In some embodiments, the initial silicon carbide feedstock is sieved to select a certain particle size of silicon carbide powder. In some embodiments, the silicon carbide powder is washed to remove floating carbon. In some embodiments, the washed silicon carbide powder can also be placed in a carbon removal device, and oxygen is passed through the device at a certain temperature to remove the carbon, and the silicon carbide feedstock is obtained.

In some embodiments, the particle size of the silicon carbide powder is in a range of 8 mesh to 40 mesh. In some embodiments, the particle size of the silicon carbide powder is in a range of 10 mesh to 35 mesh. In some embodiments, the particle size of the silicon carbide powder is in a range of 12 mesh to 33 mesh. In some embodiments, the particle size of the silicon carbide powder is in a range of 15 mesh to 30 mesh. In some embodiments, the particle size of the silicon carbide powder is in a range of 18 mesh to 28 mesh. In some embodiments, the particle size of the silicon carbide powder is in a range of 20 mesh to 25 mesh.

In some embodiments, the carbon removal device is a device that removes carbon. For example, the carbon removal device includes a muffle furnace.

In some embodiments, the temperature at which the carbon is removed is in a range of 600° C. to 1000° C. In some embodiments, the temperature at which the carbon is removed is in a range of 650° C. to 950° C. In some embodiments, the temperature at which the carbon is removed is in a range of 700° C. to 900° C. In some embodiments, the temperature at which the carbon is removed is in a range of 750° C. to 850° C. In some embodiments, the temperature at which the carbon is removed is in a range of 770° C. to 830° C. In some embodiments, the temperature at which the carbon is removed is in a range of 790° C. to 810° C.

By post-processing the initial silicon carbide feedstock, the silicon carbide feedstock obtained can be made purer, and a crystal grown as the feedstock for the next crystal growth is of better quality.

The crystal growth method will be described in detail below by means of embodiments. It is to be noted that reaction conditions, reaction materials, and a dosage of the reaction materials in the embodiments are only intended to illustrate the method of preparing a crystal, and do not limit the scope of protection of the present disclosure.

### Example 1

(1) Mixing a source material and an additive: a total weight of a required source material was determined as 10,000 g according to a volume of a tantalum crucible. The source material included carbon powder with a particle size of 0.1 μm, silicon powder with a particle size of 0.1 mm, and silicon carbide particle with a particle size of 100 mesh. The carbon powder, the silicon powder, and the additive (polytetrafluoroethylene) were mixed in a ratio of 1:2:0.2. The silicon carbide particle was added to the agate mortar in a proportion of 1% of the total weight of the carbon powder and the silicon powder, and mixed thoroughly in the agate mortar.
(2) Synthesis of an initial material: the mixture of the feedstock and the additive was added to a graphite crucible (with ash content less than 5 ppm) and reacted for 1 h with a reaction temperature of 1400° C. and pressure of 500 Pa. After a first stage (a reaction stage), a second stage (i.e., a sublimation and recrystallization stage) was carried out at a reaction temperature of 2100° C., a pressure of 10-Pa, and a reaction time of 20 h.
(3) Cooling: after the reaction is completed, high-purity argon gas was introduced to a pressure of 500 mbar, and the temperature was then lowered to 30° C. to obtain the initial material.
(4) Post-processing: the obtained initial material was subjected to post-processing, which includes crushing, sieving, carbon removal, cleaning, drying, and encapsulation of the initial material to obtain silicon carbide powder.
(5) Quality detection of a feedstock: the prepared silicon carbide powder was tested, and the results were as follows: B<0.5 ppm, Al-0.11 ppm, Mg<0.05 ppm, Ti<0.5 ppm, V<0.09 ppm, Cr<0.1 ppm, Ni<0.01 ppm, Cu<0.05 ppm, Na=0.02 ppm.

### Example 2

(1) Pre-treatment of a feedstock: firstly, 5 L of aqua regia was used for acid treatment of the feedstock; then 10 L of ultrapure water was used to clean the feedstock each time for 4 times.
(2) Treatment of a seed crystal: the following treatments are performed on a seed crystal:
a. Diameter expansion treatment: a seed crystal with a smaller diameter of 150 mm and low defect density was used to obtain a large-sized crystal ingot through diameter expansion growth, which was then sliced and processed into a large-sized seed crystal with a diameter of 153 mm.
b. Polishing treatment: diamond polishing powder with a grain size of 0.5 μm was used to polish the seed crystal for 120 minutes at a polishing pressure of 0.08 MPa and a polishing rotational speed of 30 r/min.
c. Coating treatment: the seed crystal was coated by a method illustrated in Example 3.
d. Surface inspection: whether there are microtubules on a surface of the seed crystal was inspected by X-ray diffraction, whether there are mechanical damages on the surface of the seed crystal and whether the surface of the seed crystal is clean were observed using a microscope.
(3) Quality detection of a feedstock and the seed crystal: the feedstock after pre-treatment was tested to obtain a feedstock with a purity of 5 ppm; the seed crystal after pre-treatment was tested to obtain a seed crystal with a finish of 2 μm, a total thickness deviation of 3.5 μm, a local thickness deviation of 1.6 μm, a curvature of 5 μm, and a warpage of 10 μm.

### Example 3

The seed crystal was coated using a coating device as shown in FIG. 9.
(1) Treatment of a non-coated surface: a plurality of seed crystals to be coated were selected, and a layer of polyimide film was pre-pasted on a non-coated surface of the seed crystals.
(2) Placement of the seed crystals: the plurality of seed crystals with a diameter of 150 mm, to which the polyimide film has been pasted, were placed on a coating rack inside a coating apparatus.
(3) Vacuuming and heating: the coating apparatus was vacuumed to 0.01 Pa, and a chamber of the coating apparatus was heated to a temperature of 500° C.
(4) Introduction of reaction gas: inert gas was introduced into the coating apparatus as carrier gas, with a flow rate of the inert gas being 500 mL/min, until the pressure of the chamber of the coating apparatus reached 0.05 MPa, methane was introduced into the chamber of the coating apparatus, with a flow rate of the methane being 50 mL/min, and the methane was continually introduced for 10 min and then the introduction ended, and the flow rate of the carrier gas was maintained unchanged.
(5) Cooling: the carrier gas was continually introduced, after cooling to room temperature at a cooling rate of 30° C./min, the introduction of the carrier gas ended and the seed crystals were removed.
(6) Quality detection of the seed crystals: the coated seed crystals were inspected and the average value of the thickness of the coating was 9 μm.

### Example 4

The seed crystal was bonded using the apparatus for bonding a seed crystal as shown in FIG. 11A and FIG. 11B.
(1) Application of an adhesive: an adhesive was applied to a bottom surface of a chamber lid of a growth chamber.
(2) Placement of the chamber lid: the chamber lid covered with the adhesive was placed inside a bonding apparatus.
(3) Air evacuation treatment: an air evacuation treatment was performed on the bonding apparatus using a vacuum pump, the pressure of the bonding apparatus after the air evacuation treatment was 0.1 Pa.
(4) Bonding of the seed crystal: the seed crystal was bonded and fixed to a suction cup of a pressing assembly through a high-temperature traceless adhesive. The pressing assembly was controlled to move up and down to bring the seed crystal into contact with the chamber lid and a pressure of 0.2 MPa was further applied to bond the seed crystal and the chamber lid. During the pressing process, a vacuum was drawn to 0.1 Pa, and a chamber of the bonding apparatus was heated at a temperature of 1000° C. for 120 mins.
(5) Quality detection of the seed crystal: after the completion of the bonding, an ultrasonic detection apparatus was used to inspect the seed crystal after bonding. Usually, porosities are mostly concentrated around 30 mm from the edge of the seed crystal, with sizes ranging from 0.01mm² to 30mm², varying in shape, and a porosity density of 3 per cm². After bonding, the porosities are mostly concentrated along the edge of the seed crystal, with small sizes and low porosity density, indicating good bonding quality.

### Example 5

The seed crystal is bonded using an apparatus for bonding a seed crystal as shown in FIG. 12A and FIG. 12B.
(1) Application of an adhesive: an adhesive was applied to a bottom surface of a chamber lid of a growth chamber.
(2) Placement of the chamber lid: the chamber lid covered with adhesive was placed inside a bonding apparatus.
(3) Air evacuation treatment: the air evacuation treatment was performed on the bonding apparatus using a vacuum pump, the pressure of the bonding apparatus after the air evacuation treatment was 0.1 Pa.
(4) Bonding of the seed crystal: the seed crystal was bonded and fixed to a suction cup of a pressing assembly through a high-temperature traceless adhesive. The pressing assembly was controlled to move up and down to bring the seed crystal, the buffer layer H, and the chamber lid into contact, and a further pressure of 0.5 MPa was applied to bond the seed crystal, the buffer layer H, and the chamber lid. During the pressing process, a vacuum was drawn to 0.1 Pa, and the chamber of the bonding apparatus was heated at a heating temperature of 1000° C. for 120 mins.
(5) Quality detection of the seed crystal after bonding: after the completion of the bonding, an ultrasonic detection apparatus was used to inspect the seed crystal after bonding. Usually, porosities are mostly concentrated around 15 mm from the edge of the seed crystal, with sizes ranging from 0.01 mm² to 30 mm², varying in shape, and a porosity density of 2 per cm². After bonding, the porosities are mostly concentrated along the edge of the seed crystal, with small sizes and low porosity density, indicating good bonding quality.

### Example 6

The seed crystal is bonded through a rolling operation as shown in FIG. 14A and FIG. 14B.
(1) Placement of the seed crystal and a buffer layer: a bottom surface of a buffer layer, which is larger than a dimension of a seed crystal, and a top surface of the seed crystal were covered with an adhesive, and the buffer layer and seed crystal were stacked on a bonding table.
(2) Bonding of the seed crystal and the buffer layer: a first angle between a pressure roller and an uncontacted portion between a buffer layer and the seed crystal is 0.1°, a first pressure exerted by the pressure roller was 0.5 kPa, and a first movement speed of the pressure roller was 0.5 mm/s. A rolling operation was performed so that the seed crystal was bonded with the buffer layer.
(3) Placement of a chamber lid, the seed crystal, and the buffer layer: the bottom surface of the buffer layer and a top surface of the chamber lid were coated with adhesive, and the seed crystal and the buffer layer after bonding, and the chamber lid were stacked on the bonding table.
(4) Bonding of the seed crystal and the buffer layer after bonding with the chamber lid: a second angle between the pressure roller and an uncontacted portion between the buffer layer and the chamber lid is 0.1°, a second pressure exerted by the pressure roller was 0.5 kPa, and a second movement speed of the pressure roller was 0.5 mm/s. A rolling operation was performed so that the seed crystal and the buffer layer after bonding were bonded with the chamber lid.
(5) Quality detection of the seed crystal after bonding: after the completion of the bonding, an ultrasonic detection apparatus was used to inspect the seed crystal after bonding. Usually, porosities are mostly concentrated around 5 mm from the edge of the seed crystal, with sizes ranging from 0.01 mm² to 30 mm², varying in shape, and a porosity density of 1 per cm². After bonding, the porosities are mostly concentrated along the edge of the seed crystal, with small sizes and low porosity density, indicating good bonding quality.

### Example 7

A crystal grows using the crystal growth device as shown in FIG. 16A and the temperature measurement assembly as shown in FIG. 18.
(1) Placement of a feedstock: a feedstock was placed in a material zone of a growth chamber.
(2) Placement of a seed crystal: the seed crystal after bonding was placed in a growth zone of the growth chamber.
(3) Heating of the material zone: the material zone was heated using a first heating assembly (e.g., a resistance heating assembly) to raise the temperature to 2500° C. within 5 hours to sublimate the feedstock into a vapor phase component required for growing the crystal.
(4) Heating of a vicinity of a partition: a second heating assembly (e.g., resistance heating component) heated the region 5 mm above or below the partition. Within 5 hours, the temperature was increased to 2400° C. to maintain a discharge rate of a vapor phase component via at least one outlet.
(5) Heating of the growth zone: the growth zone was heated using a third heating assembly (e.g., a resistance heating assembly), which raises the temperature to 2300° C. within 5 hours.
(6) Crystal growth control: a plurality of temperatures associated with the growth chamber were obtained using a temperature measurement assembly. Then, based on the plurality of temperature information obtained using the temperature measurement assembly, the upper-level computer issued an adjustment instruction, and a programmable logic controller (PLC) received the adjustment instruction and output a control signal to control the heating power of the first heating assembly, the second heating assembly, or the third heating assembly, and/or control the opening or closing of an upper cover plate of the outlet 108-21 to control at least one of a position, shape, distribution, or area of the at least one outlet, thereby regulating a growth rate of the crystal and stabilizing the growth rate of the crystal. For example, as shown in FIG. 16A, when the temperature near a chamber lid is measured to be less than a growth temperature, a crystallization rate of the crystal will be accelerated, and at that time the temperature in the growth zone will be made to rise by adjusting the power of the third heating assembly, and the temperature in the material zone will be made to reduce by adjusting the power of the first heating assembly and the second heating assembly to reduce a flow rate of the vapor phase component passing through the partition, thereby decreasing the growth rate of the crystal. In some embodiments, it is also possible to change a size or shape of the outlet on the partition by adjusting the position between different layers on the partition or by adjusting the opening or closing of a cover plate on the outlet. This allows vapor phase components in a heating zone to pass through the partition at a rate required for growing the crystal, thereby reducing the growth rate of the crystal. In some embodiments, the temperature adjustment range of the second heating assembly is in a range of 2300° C. to 2600° C.
(7) Quality detection of the crystal: Threading Screw Dislocation (TSD)≤300 cm⁻², Threading Edge Dislocation (TED)≤5069 cm⁻², Basal Plane Dislocation (BPD)≤1380 cm⁻².

### Example 8

A crystal grows using the crystal growth device as shown in FIG. 16A.
(1) Placement of a feedstock: place a feedstock in a material zone of a growth chamber.
(2) Placement of the seed crystal: the seed crystal after bonding was placed in a growth zone of the growth chamber.
(3) Heating of the material zone: the material zone was heated by a first heating assembly (e.g., a resistance heating component), which raises the temperature to 2350° C. within 5 hours to sublimate the feedstock into a vapor phase component required for growing a crystal.
(4) Heating of a vicinity of a partition: a second heating assembly (e.g., a resistance heating component) heated the region 5 mm above or below the partition. Within 5 hours, the temperature was increased to 2000° C. to maintain a discharge rate of the vapor phase component through at least one outlet.
(5) Heating of the growth zone: the growth zone was heated using a third heating assembly (e.g., a resistance heating component), which raises the temperature to 2250° C. within 5 hours.
(6) Crystal growth control: a distribution of a vapor phase component required for growing a crystal within the growth chamber was obtained through virtual reactor software. Then, based on the distribution of the vapor phase component in the growth chamber, an upper-level computer issued an adjustment instruction, and the PLC received the adjustment instruction and output a control signal to control the opening or closing of a cover plate on the outlet 108-21, or to adjust positions of different layers on the partition, so as to control at least one of a position, shape, distribution, or area of the at least one outlet, thereby realizing that the vapor phase component in a heating zone passes through the partition according to a transport rate required for growing the crystal, adjusting the growth rate of the crystal and stabilizing the growth rate of the crystal.
(7) Quality detection of the crystal: TSD≤230 cm⁻², TED≤4000 cm⁻², BPD≤1207 cm⁻².

### Example 9

A crystal grows using the crystal growth device as shown in FIG. 16A and the monitoring assembly as shown in FIG. 19A.
(1) Placement of a feedstock: a feedstock was placed in a material zone of a growth chamber.
(2) Placement of the seed crystal: the seed crystal after bonding was placed in a growth zone of the growth chamber.
(3) Heating of the material zone: the material zone was heated using a first heating assembly (e.g., a resistance heating component), which raises the temperature to 2300° C. within 5 hours to sublimate the feedstock into a vapor phase component required for growing a crystal.
(4) Heating of a vicinity of a partition: a second heating assembly (e.g., a resistance heating component) heated the region 5 mm above or below the position of the separator. Within 5 hours, the temperature was increased to 2250° C. to maintain a discharge rate of a vapor phase component via at least one outlet.
(5) Heating of the growth zone: the growth zone was heated using a third heating assembly (e.g., a resistance heating component), which raises the temperature to 2200° C. within 5 hours.
(6) Crystal growth control: a situation of growing a crystal was monitored using a monitoring assembly. Then, based on the situation of growing the crystal, an upper-level computer issued an adjustment instruction, and the PLC received the adjustment instruction and then output a control signal to adjust a heating parameter of the first heating assembly, the second heating assembly, or the third heating assembly, and/or to control the opening or closing of a cover plate on the outlet 108-21 to control at least one of a position, shape, distribution, or area of the at least one outlet, thereby regulating the growth rate of the crystal and stabilizing the growth rate of the crystal. In some embodiments, the temperature adjustment range of the second heating assembly is in a range of 2200° C. to 2400° C.
(7) Quality detection of the crystal: TSD≤100 cm⁻², TED≤3000 cm⁻², BPD≤900 cm⁻².

### Example 10

A crystal grows using the crystal growth device as shown in FIG. 16B and the temperature measurement assembly as shown in FIG. 18.
(1) Placement of a feedstock: a feedstock was placed in a material zone of a growth chamber.
(2) Placement of the seed crystal: the seed crystal after bonding was placed in a growth zone of the growth chamber.
(3) Heating of the material zone: the material zone was heated using a first heating assembly (e.g., a resistance heating assembly), which raises the temperature to 2,500° C. within 4 hours to sublimate the feedstock into a vapor phase component required for growing a crystal.
(4) Heating of a vicinity of a partition: a second heating assembly (e.g., a resistance heating component) heated the region 5 mm above or below the partition. Within 5 hours, the temperature was increased to 2400° C. to maintain a discharge rate of the vapor phase component via at least one outlet.
(5) Heating of the growth zone: the growth zone was heated using a third assembly (e.g., a resistance heating component), which raises the temperature to 2300° C. within 4 hours.
(6) Crystal growth control: a plurality of temperatures associated with the growth chamber were obtained using a temperature measurement assembly. Then, based on the plurality of temperature information obtained by the temperature measurement assembly, an upper-level computer issued an adjustment instruction, and the PLC received the adjustment instruction and then output a control signal for controlling the heating power of the first heating assembly, the second heating assembly, or the third heating assembly, and/or controlling the opening or closing of an upper cover plate of the outlet 108-21 to control at least one of a position, shape, distribution, or area of the at least one outlet, so as to regulate a growth rate of the crystal and stabilize the growth rate of the crystal.

In some embodiments, shown in FIG. 16B, a crystallization rate of the crystal is accelerated when the temperature near a chamber lid is measured to be less than a growth temperature, at which point the temperature in the growth zone is increased by adjusting the power of the third heating assembly, and the temperature in the material zone is decreased by adjusting the power of the first heating assembly or the power of the second heating assembly to slow down a flow rate of the vapor phase component passing through the partition, thereby reducing the growth rate of the crystal. In some embodiments, it is also possible to change the size or shape of the outlet on the partition by adjusting a position between different layers on the partition or by adjusting the opening or closing of a cover plate on the outlet, so as to a vapor phase component in a heating zone can pass through the partition at rate required for growing the crystal, thereby reducing the growth rate of the crystal. In some embodiments, the temperature adjustment range of the second heating assembly is in a range of 2300° C. to 2600° C.
(7) Quality detection of the crystal: TSD≤350 cm⁻², TED≤6000 cm⁻², BPD≤1540 cm⁻².

### Example 11

A crystal grows using the crystal growth device as shown in FIG. 16C and the temperature measurement assembly as shown in FIG. 18.
(1) Placement of a feedstock: a feedstock was placed in a material zone of a growth chamber.
(2) Placement of the seed crystal: the seed crystal after bonding was placed in a growth zone of the growth chamber.
(3) Heating of the material zone: the material zone was heated using a first heating assembly (e.g., an induction heating component), which raises the temperature to 2130° C. within 5 hours to sublimate the feedstock into a vapor phase component required for growing a crystal.
(4) Heating of a vicinity of a partition: a second heating assembly (e.g., an induction heating component) heated the region 5 mm above (not shown in FIG. 16C) or below the partition. Within 5 hours, the temperature was increased to 2130° C. to maintain a discharge rate of a vapor phase components via at least one outlet.
(5) Heating of the growth zone: the growth zone was heated using a third heating assembly (e.g., a resistance heating component) to raise the temperature to 2090° C. within 5 hours.
(6) Crystal growth control: a plurality of temperatures associated with the growth chamber were obtained using a temperature measurement assembly. Then, based on the plurality of temperature information obtained by the temperature measurement assembly, an upper-level computer issued a temperature field adjustment instruction, and the PLC received the instruction and output a control signal to control the heating power of the first heating assembly, the second heating assembly, or the third heating assembly, and/or control the opening or closing of an upper cover plate of the outlet 108-21 to control at least one of a position, shape, distribution, or area of the at least one outlet, so as to regulate a growth rate of the crystal and stabilize the growth rate of the crystal.
(7) Quality detection of the crystal: TSD≤208 cm⁻², TED≤7000 cm⁻², BPD≤1200 cm⁻².

### Example12

After crystal growth is completed, a residual of a feedstock is recovered as a residue.
(1) Inverting treatment: after the crystal growth is completed, a carbon-rich portion (carbon residue) on the edge of the residual of the feedstock was first removed manually, and then the residual of the feedstock was inverted.
(2) Laying of a new feedstock: a new feedstock was laid on the residual of the feedstock after the inverting treatment as a feedstock for a next crystal growth, in which a mass ratio of new feedstock to the residual of the feedstock is 3:7.
(3) Next crystal growth: the residual of the feedstock was used after the treatment for crystal growth.
(4) Quality inspection on a crystal after the next crystal growth is completed: the crystal shows no phase transition, has polycrystals at the positioning edges, with the thickness of 16 mm, and TSD≤450 cm⁻², TED≤7500 cm⁻², and BPD≤1600 cm⁻².

Beneficial effects that may be brought about by the embodiments of the present disclosure include, but are not limited to the following. (1) The material zone and the growth zone are separated by the partition, and the temperatures in the material zone, near the partition, and in the growth zone are individually controlled, which can significantly reduce the thermal stress during growing the crystal and effectively regulate the growth rate. (2) By using the first heating assembly to heat the material zone, the second heating assembly to heat the region near the partition, and the third heating assembly to heat the growth zone, the sublimation rate of the feedstock can be controlled, ensuring a stable discharge rate at the outlet. This also maintains the stable growth of the crystal surface, reduces thermal stress during growing the crystal, lowers the probability of dislocation, minimizes crystal defects, and improves the quality of the grown crystal. (3) By adjusting the position, shape, distribution, or area of at least one outlet on the partition, the carbon to silicon molar ratio, transport path, and transport speed of the vapor phase components of the feedstock can be controlled. This effectively regulates the interface of the crystal growth, significantly reduces the probability of dislocation, minimizes crystal defects, and improves the quality of the grown crystal. (4) The process of preparing the feedstock is divided into two stages. In the first stage, small silicon carbide particles are generated, and in the second stage, these particles undergo sublimation and recrystallization on the surface of the silicon carbide particles, resulting in larger feedstock particles. This avoids the use of small silicon carbide particles for crystal growth, which could cause crystal defects, thereby improving the quality of the crystals. (5) By applying a coating treatment to the back surface of the seed crystal, the evaporation process of the back surface of the seed crystal during the silicon carbide crystal growth is suppressed. This effectively eliminates the planar hexagonal defects caused by evaporation at the back surface of the seed crystal, improving both the quality and yield of the grown silicon carbide crystals. (6) By using a vapor deposition manner to simultaneously grow carbon films on the back surfaces of a plurality of seed crystals, the coating efficiency is high, and the uniformity of the coating is good, which improves the consistency of the grown crystal. (7) By evacuating the porosities inside the adhesive through vacuuming, it ensures that all porosities are removed before the bonding process. Alternatively, the buffer layer and the adhesive can be processed into an integrally-molded shape to avoid uneven spreading of the liquid adhesive or formation of porosities during the spreading process. Then, under vacuum, pressure, and heat are applied to bond the seed crystals, further preventing the formation of new porosities during the bonding process, which helps avoid defects such as micro-tubes and hexagonal voids in the silicon carbide crystals, thereby improving quality. (8) The ultrasonic detection apparatus is used to detect the seed crystals after bonding, so as to screen out those with a better quality of bonding (e.g., fewer porosities) for growing a crystal, and improve the quality of the subsequently grown crystals. (9) Recovery of the residual of the feedstock can be carried out in a simple and efficient way, making full use of the residual and improving the quality of the subsequently grown crystals.

It should be noted that the beneficial effects that may be produced by different embodiments are different, and the beneficial effects that may be produced in different embodiments may be a combination of any one or more of the above, or any other beneficial effect that may be obtained.

The basic concepts have been described above, and it is apparent to those skilled in the art that the foregoing detailed disclosure is intended as an example only and does not constitute a limitation of the present disclosure. While not expressly stated herein, a person skilled in the art may make various modifications, improvements, and amendments to the present disclosure. Those types of modifications, improvements, and amendments are suggested in the present disclosure, so those types of modifications, improvements, and amendments remain within the spirit and scope of the exemplary embodiments of the present disclosure.

Also, the present disclosure uses specific words to describe embodiments of the specification, such as “an embodiment”, “one embodiment”, and/or “some embodiments” means a feature, structure, or characteristic associated with at least one embodiment of the present disclosure. Accordingly, it should be emphasized and noted that “an embodiment” or “one embodiment” or “an alternative embodiment” referred to in different places in the present disclosure do not necessarily refer to the same embodiment. In addition, certain features, structures, or characteristics of one or more embodiments of the present specification may be suitably combined.

Furthermore, unless expressly stated in the claims, the order of the processing elements and sequences, the use of numerical letters, or the use of other names as described in the present disclosure are not intended to qualify the order of the processes and methods of the present disclosure. While some embodiments of the invention that are currently considered useful are discussed in the foregoing disclosure by way of various examples, it should be appreciated that such details serve only illustrative purposes, and that additional claims are not limited to the disclosed embodiments, rather, the claims are intended to cover all amendments and equivalent combinations that are consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be noted that in order to simplify the presentation of the present disclosure, and thereby aid in the understanding of one or more embodiments of the invention, the foregoing descriptions of embodiments of the present disclosure sometimes group multiple features together in a single embodiment, accompanying drawings, or in a description thereof. However, this method of disclosure does not imply that the objects of the present disclosure require more features than those mentioned in the claims. Rather, claimed subject matter may lie in less than all features of a single foregoing disclosed embodiment.

Some embodiments use numbers describing the number of components, attributes, and it should be understood that such numbers used in the description of embodiments are modified in some examples by the modifiers “approximately”, “nearly”, or “substantially”. Unless otherwise noted, the terms “approximately,” “nearly,” or “substantially” indicate that a ±20% variation in the stated number is allowed. Correspondingly, in some embodiments, the numerical parameters used in the present disclosure and claims are approximations, which can change depending on the desired characteristics of individual embodiments. In some embodiments, the numerical parameters should consider the specified number of valid digits and employ general place-keeping. While the numerical domains and parameters used to confirm the breadth of their ranges in some embodiments of the present disclosure are approximations, in specific embodiments, such values are set to be as precise as possible within a feasible range.

For each of the patents, patent applications, patent application disclosures, and other materials cited in the present disclosure, such as articles, books, specification sheets, publications, documents, and the like, are hereby incorporated by reference in their entirety into the present disclosure. Application history documents that are inconsistent with or conflict with the contents of the present disclosure are excluded, as are documents (currently or hereafter appended to the present disclosure) that limit the broadest scope of the claims of the present disclosure. It should be noted that in the event of any inconsistency or conflict between the descriptions, definitions, and/or use of terms in the materials appended to the present disclosure and those set forth herein, the descriptions, definitions, and/or use of terms in the present disclosure shall prevail.

Finally, it should be understood that the embodiments described herein are only used to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

What is claimed is:

1. A crystal growth method, comprising:
placing a feedstock in a material zone of a growth chamber;
placing a seed crystal in a growth zone of the growth chamber, wherein the material zone and the growth zone are separated by a partition, and the partition includes at least one outlet; and
growing a crystal based on the seed crystal and the feedstock by a physical vapor transport (PVT) manner, wherein a temperature in a vicinity of the partition is higher than a temperature of the material zone or a temperature of the growth zone.

2. The method of claim 1, wherein the feedstock includes silicon carbide powder, and the silicon carbide powder is prepared by:
mixing a source material and an additive, the source material includes carbon powder, silicon powder, and a preset percentage of silicon carbide particles; and
obtaining an initial material by placing the homogeneously mixed source material and the additive in a pre-synthesis device and performing a feedstock synthesis operation, wherein the feedstock synthesis operation includes a first stage and a second stage, the first stage is a reaction stage, and the second stage is a sublimation and recrystallization stage; and
obtaining the silicon carbide powder by post-processing the initial material.

3. The method of claim 1, further comprising:
before growing the crystal,
acid treating and/or washing the feedstock; or
performing at least one of polishing, coating, surface inspection, or diameter expansion on the seed crystal.

4. The method of claim 1, further comprising:
coating the seed crystal before growing the crystal, wherein the coating includes:
performing sandblasting treatment on a back surface of the seed crystal;
performing heating pre-treatment on the seed crystal after the sandblasting treatment; and
coating the seed crystal with a film material after the heating pre-treatment.

5. The method of claim 4, wherein the sandblasting treatment is configured so that a roughness of the seed crystal after the sandblasting treatment is in a range of 10 μm to 50 μm.

6. The method of claim 1, further comprising:
coating the seed crystal before growing the crystal, wherein the coating includes:
placing a plurality of seed crystals including the seed crystal on a plurality of coating racks of a coating apparatus; and
introducing coating gas into the coating apparatus and growing a carbon film on a back surface of the plurality of seed crystals simultaneously by vapor deposition.

7. The method of claim 1, wherein the placing the seed crystal in the growth zone of the growth chamber includes:
applying an adhesive to a bottom surface of a chamber lid of the growth chamber;
placing the chamber lid covered with the adhesive in a bonding apparatus;
evacuating air from the bonding apparatus; and
bonding the seed crystal to the chamber lid, during which air evacuation and heating are performed simultaneously.

8. The method of claim 1, wherein the placing the seed crystal in the growth zone of the growth chamber includes:
stacking the seed crystal and a buffer layer on a bonding table, wherein a contact surface of the buffer layer and the seed crystal is covered with an adhesive;
bonding the seed crystal to the buffer layer by performing a rolling operation using a pressing assembly;
stacking a chamber lid of the growth chamber, and the buffer layer and the seed crystal after bonding, on the bonding table, wherein the buffer layer is located between the chamber lid and the seed crystal, and a contact surface of the buffer layer and the chamber lid is covered with the adhesive; and
bonding the seed crystal to the chamber lid by performing the rolling operation using the pressing assembly.

9. The method of claim 1, wherein
the placing the seed crystal in the growth zone of the growth chamber includes:
bonding the seed crystal to a chamber lid of the growth chamber;
the method further comprising:
performing porosity detection on the bonding of the seed crystal using an ultrasonic detection apparatus, wherein a result of the porosity detection includes at least one of a porosity position, a porosity size, a porosity shape, or a porosity density.

10. The method of claim 1, wherein the growing the crystal based on the seed crystal and the feedstock by the physical vapor transport manner includes:
heating the material zone using a first heating assembly to sublimate the feedstock into a vapor phase component required for growing the crystal;
heating the vicinity of the partition using a second heating assembly to maintain a discharge rate of the vapor phase component via the at least one outlet; and
heating the growth zone using a third heating assembly.

11. The method of claim 1, wherein the growing the crystal based on the seed crystal and the feedstock by the physical vapor transport manner includes:
adjusting a position of the at least one outlet along an axial direction or a radial direction during growing the crystal.

12. The method of claim 1, wherein the growing the crystal based on the seed crystal and the feedback by the physical vapor transport manner includes:
obtaining temperature information within the growth chamber; and
adjusting at least one of a position, shape, distribution, or area of the at least one outlet based on the temperature information.

13. The method of claim 12, wherein the obtaining the temperature information within the growth chamber includes:
obtaining a plurality of temperatures associated with the growth chamber using a temperature measurement assembly; and
determining, based on the plurality of temperatures, the temperature information within the growth chamber by modeling, the temperature information including temperature information of a crystal growth surface.

14. The method of claim 13, wherein the temperature measurement assembly includes a plurality of temperature sensors, the plurality of temperature sensors are located on a side wall and/or at a top of the growth chamber, and a cooling assembly is arranged between the plurality of temperature sensors and the top of the growth chamber.

15. The method of claim 1, wherein the growing the crystal based on the seed crystal and the feedstock by the physical vapor transport manner includes:
obtaining a distribution of a vapor phase component required for growing the crystal within the growth chamber; and
adjusting at least one of a position, shape, distribution, or area of the at least one outlet based on the distribution.

16. The method of claim 15, wherein the obtaining a distribution of a vapor phase component required for growing the crystal within the growth chamber includes:
obtaining temperature information within the growth chamber;
determining relevant information of the at least one outlet, the relevant information of the at least one outlet including at least one of a position, shape, distribution, or area of the at least one outlet; and
simulating and determining the distribution of the vapor phase component within the growth chamber based on the temperature information of the growth chamber and the relevant information of the at least one outlet.

17. The method of claim 1, wherein the growing the crystal based on the seed crystal and the feedstock by the physical vapor transport manner includes:
monitoring a situation of growing the crystal during growing the crystal;
adjusting at least one of a heating parameter of a heating assembly and/or a position, shape, distribution, or area of the at least one outlet based on the situation of growing the crystal.

18. The method of claim 1, further comprising:
inverting a residual of the feedstock after completion of growing the crystal; and
laying a new feedstock on top of the residual of the feedstock after the inverting as a feedstock for next crystal growth.

19. The method of claim 1, further comprising:
after completion of growing the crystal, obtaining a silicon-rich portion by removing a carbon-rich portion of a residual of the feedstock;
pre-treating the silicon-rich portion;
mixing the pre-treated silicon-rich portion with carbon powder homogeneously according to a predetermined mass ratio;
obtaining an initial silicon carbide feedstock by placing the silicon-rich portion and the carbon powder after mixing homogeneously in a recovery device for recovery; and
obtaining a silicon carbide feedstock as a feedstock for next crystal growth by post-processing the initial silicon carbide feedstock.

20. A crystal growth device, comprising:
a growth chamber, including a material zone and a growth zone, wherein
the material zone is configured to place a feedstock,
the growth zone is configured to place a seed crystal, and
the material zone and the growth zone are separated by a partition, and the partition includes at least one outlet; and
a heating assembly configured to heat the growth chamber for growing a crystal based on the seed crystal and the feedstock by a physical vapor transport (PVT) manner.
